(19) United States
(12) Patent Application Publication
(10) Pub. No.: US 2026/0096121 A1
(43) Pub. Date: Apr. 2, 2026

(54) SEMICONDUCTOR DEVICE AND METHODS OF FORMATION

(71) Applicant: Taiwan Semiconductor Manufacturing Company, Ltd., Hsinchu (TW)

(72) Inventor: Tzu-Ging LIN, Kaohsiung City (TW)

(21) Appl. No.: 18/901,495

(22) Filed: Sep. 30, 2024

(51) Int. Cl. H01L 29/66; H01L 29/06; H01L 29/423; H01L 29/775; H01L 29/786

(52) U.S. Cl. CPC H10D 30/014; H10D 30/43; H10D 30/6735; H10D 30/6757; H10D 62/121; H10D 64/017; H10D 64/018

(57) ABSTRACT

Sacrificial semiconductor layers are removed from a layer stack of a semiconductor device prior to formation of inner spacers and source/drain regions of a nanostructure transistor of the semiconductor device. The sacrificial semiconductor layers may be removed along with intermixing layers that may have formed due to intermixing between the materials of the sacrificial semiconductor layers and semiconductor channel layers. The sacrificial semiconductor layers and intermixing layers may be replaced with sacrificial dielectric layers. The sacrificial dielectric layers may then be etched to form cavities in which the inner spacers are formed.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A-4C are diagrams of an example implementation of a sacrificial dielectric layer formation process described herein.

FIG. 5 is a diagram of an example implementation of an inner spacer formation process described herein.

FIGS. 6A and 6B are diagrams of an example implementation of a source/drain region formation process described herein.

FIGS. 7A and 7B are diagrams of an example implementation of an interlayer dielectric formation process described herein.

FIGS. 8A-8D are diagrams of an example implementation of a replacement gate process described herein.

FIGS. 9A-9D are diagrams of an example implementation of forming a semiconductor device described herein.

FIGS. 10A-10D are diagrams of an example implementation of forming a semiconductor device described herein.

FIGS. 11A-11D are diagrams of an example implementation of forming a semiconductor device described herein.

FIGS. 12A-12C are diagrams of an example implementation of forming a semiconductor device described herein.

FIGS. 13A-13C are diagrams of an example implementation of forming a semiconductor device described herein.

FIGS. 14A-14F are diagrams of an example implementation of forming a semiconductor device described herein.

FIG. 15 is a diagram of an example implementation of a semiconductor device described herein.

FIG. 16 is a diagram of an example implementation of a semiconductor device described herein.

FIG. 17 is a flowchart of an example process associated with forming a semiconductor device described herein.

FIG. 18 is a flowchart of an example process associated with forming a semiconductor device described herein.

FIGS. 19A-19F are diagrams of an example implementation of forming the semiconductor device 105 described herein.

FIGS. 20A-20F are diagrams of an example implementation of forming the semiconductor device 105 described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, the nanostructure channels of a nanostructure transistor (e.g., a nanowire transistor, nanosheet transistor, gate-all-around (GAA) transistor, multi-bridge channel transistor, nanoribbon transistor, and/or other types of nanostructure transistor) may be formed by forming a layer stack (sometimes referred to as a superlattice) that includes a plurality of alternating sacrificial layers and channel layers, and etching the layer stack to define the nanostructure channels. The sacrificial layers are included to define the vertical spacing between the nanostructure channels, and are subsequently removed and replaced with a gate structure of the nanostructure transistor. However, the inclusion of the sacrificial layers may result in formation of various types of defects in the nanostructure transistor and/or may result in reduced performance for the nanostructure transistor.

For example, the nanostructure transistor may include inner spacers between a source/drain region and a gate structure, and intermixing between the material of the nanostructure channels and the material of the sacrificial layers may result in the formation of defects in the inner spacers, such as corner rounding of the inner spacers. The corner rounding may occur when cavities for the inner spacers are to be formed for a nanostructure transistor, and the corner rounding may occur due to reduced etch selectivity between the nanostructure channels and the sacrificial layers because of the intermixing. The inner spacers may be included to provide various process and/or performance benefits, such as electrical isolation between the source/drain region and the gate structure, and/or protections of the source/drain region from being etched during a replacement gate operation to replace sacrificial nanostructure layers with the gate structure. However, the corner rounding may result in the inner spacers providing less of an etch buffer or etch stop when the replacement gate operation is performed, and etching through the inner spacers and into the source/drain region may occur. Etching of the source/drain region may result in damage to the crystal structure of the source/drain region and/or may result in electrical shorting between the source/drain region and the gate structure. This may lead to failure of the nanostructure transistor, and may lead to reduced yield of nanostructure transistors on a semiconductor device.

As another example, the sacrificial layers may support the nanostructure channels during formation of the source/drain region. While the support provided by the sacrificial layers reduces the likelihood of buckling and/or thinning of the nanostructure channels that might otherwise occur due to stresses exerted on the nanostructure channels during source/drain formation, the high stiffness of the sacrificial layers may actually absorb too much of the stress exerted on the nanostructure channels, which limits the strain that can be induced in the nanostructure channels. Some amount of strain in the nanostructure channels may be beneficial in that the strain can alter the crystal structure of the nanostructure channels so as to achieve higher charge carrier mobility in the nanostructure channels. Thus, the limited amount of strain that can be induced in the nanostructure channels due to the high stiffness of the sacrificial layers may limit the improvement to charge carrier mobility that can be induced in the nanostructure channels during formation of the source/drain region.

In some implementations described herein, sacrificial semiconductor layers are removed from a layer stack of a semiconductor device prior to formation of inner spacers and source/drain regions of a nanostructure transistor of the semiconductor device. The sacrificial semiconductor layers may be removed along with intermixing layers that may have formed due to intermixing between the materials of the sacrificial semiconductor layers and semiconductor channel layers, and the sacrificial semiconductor layers and intermixing layers may be replaced with sacrificial dielectric layers. The sacrificial dielectric layers may then be etched to form cavities in which the inner spacers are formed.

The sacrificial dielectric layers provide greater etch selectivity between the sacrificial dielectric layers and the semiconductor channel layers, compared to the selectivity between the sacrificial semiconductor layers and the semiconductor channel layers, which enables increased control over etching of the cavities to be achieved. The increased etching control, along with the removal of the intermixing layers, enables the cavities to be formed with sharp corners so that the cavities have approximately square or right-angle corners. The sharpness of the corners of the cavities, and the inner spacers that are subsequently formed in the cavities, provide greater protection against etching of the source/drain regions, which reduces the likelihood of damage to the source/drain regions. Moreover, epitaxial regions having a high dopant concentration may be formed on the inner spacers prior to formation of the source/drain regions to further protect the source/drain regions from etching.

Additionally and/or alternatively, the dielectric material of the sacrificial dielectric layers may have smaller elasticity than the material of the sacrificial semiconductor layers. The smaller elasticity of the sacrificial dielectric layers enables the sacrificial dielectric layers to deform instead of absorbing stresses exerted on the nanostructure channels of the transistor structure during formation of the source/drain regions, which enables the stresses to induce strain in the nanostructure channels for charge carrier mobility enhancement.

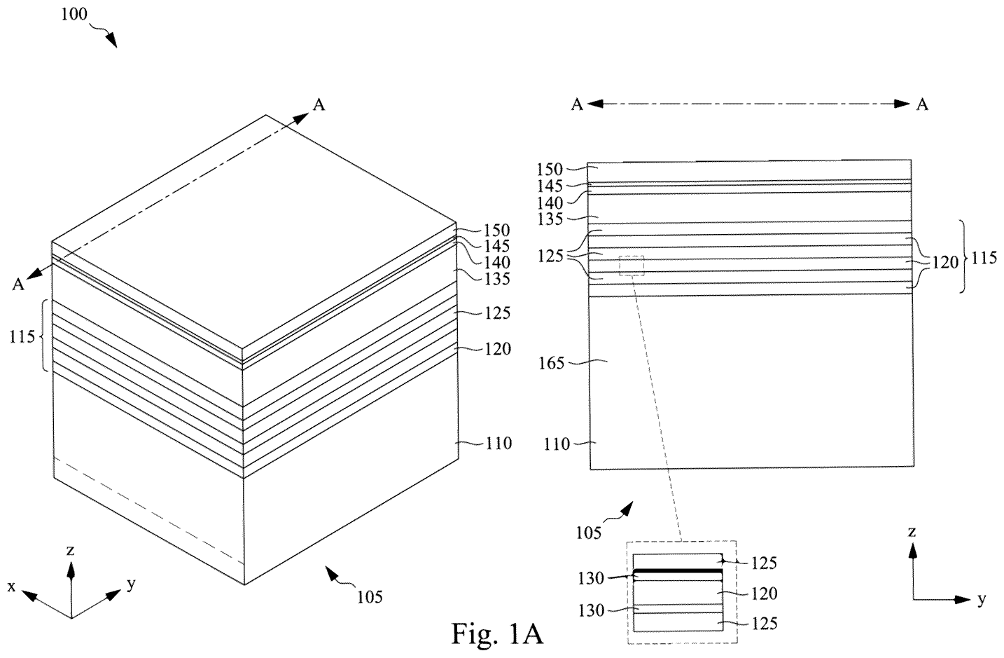

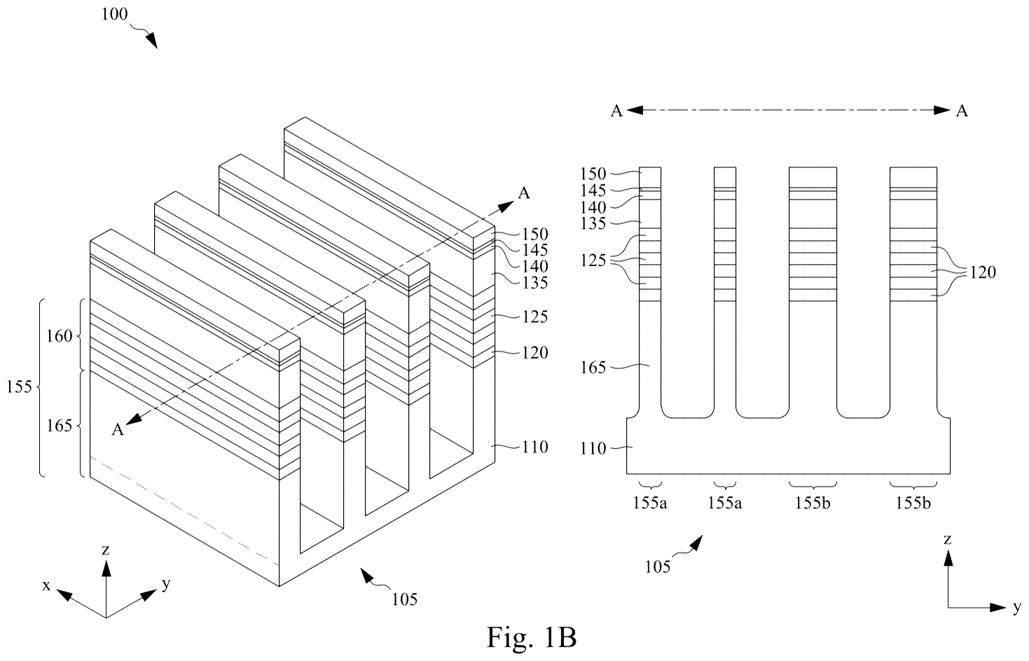

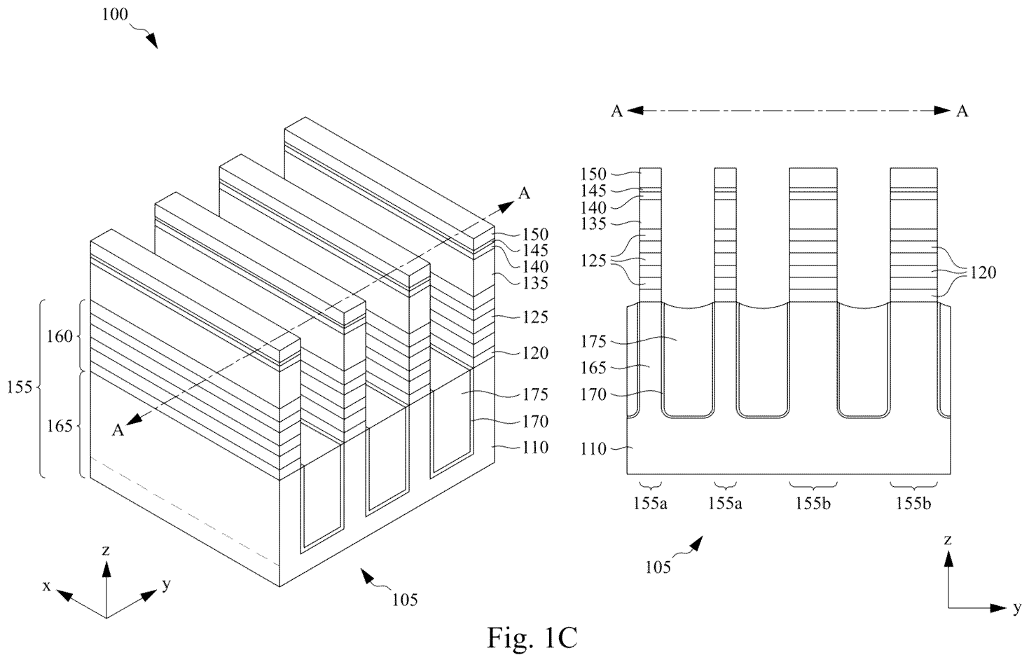

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIGS. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial semiconductor layers 120 and semiconductor channel layers 125 above the semiconductor substrate 110. The quantity of the sacrificial semiconductor layers 120 and the quantity of the semiconductor channel layers 125 illustrated in FIG. 1A are examples, and other quantities of the sacrificial semiconductor layers 120 and the semiconductor channel layers 125 are within the scope of the present disclosure.

The sacrificial semiconductor layers 120 and the semiconductor channel layers 125 may be “nanostructure” layers or “nanoscale” layers in that the sacrificial semiconductor layers 120 and the semiconductor channel layers 125 may each have a z-direction thickness that is on the order of nanometers. For example, the sacrificial semiconductor layers 120 and the semiconductor channel layers 125 may each have a z-direction thickness that is approximately 10 nanometers or less. However, other values for the z-direction thicknesses of the sacrificial semiconductor layers 120 and the semiconductor channel layers 125 are within the scope of the present disclosure.

The sacrificial semiconductor layers 120 enable a vertical distance to be defined between adjacent nanostructure channels that are formed from the semiconductor channel layers 125, and serve as placeholder layers for subsequently-formed gate structures of the transistors of the semiconductor device 105 that are formed around the nanostructure channels. The sacrificial semiconductor layers 120 include a first material composition, and the semiconductor channel layers 125 include a second material composition. In some implementations, the first material composition and the second material composition are the same material composition. In some implementations, the first material composition and the second material composition are different material compositions. As an example, the sacrificial semiconductor layers 120 may include silicon germanium (SiGe) and the semiconductor channel layers 125 may include silicon (Si). This enables the sacrificial semiconductor layers 120 and/or the semiconductor channel layers 125 to be selectively etched (e.g., enables the sacrificial semiconductor layers 120 and not the semiconductor channel layers 125 to be etched, enables the semiconductor channel layers 125 and not the sacrificial semiconductor layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial semiconductor layers 120 and/or the semiconductor channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial semiconductor layers 120 and/or the semiconductor channel layers 125 may be deposited by chemical vapor deposition (CVD), physical vapor deposition (PVD), atomic layer deposition (ALD), and/or another suitable deposition technique.

As shown in a close-up view in FIG. 1A of a portion of the layer stack 115, intermixing between two or more nanostructure layers in the layer stack 115 may occur. For example, intermixing may occur between a sacrificial semiconductor layer 120 and a vertically adjacent semiconductor channel layer 125. The intermixing may result in interdiffusion of silicon (Si) and/or germanium (Ge) between the sacrificial semiconductor layer 120 and the semiconductor channel layer 125. Thus, intermixing layers 130 may be included between the sacrificial semiconductor layers 120 and the semiconductor channel layers 125. The intermixing layers 130 may include a region of silicon germanium (SiGe) having a greater concentration of silicon (Si) (e.g., due to the diffusion of silicon from the semiconductor channel layers 125 into the sacrificial semiconductor layers 120) than the concentration of germanium (Ge) in the intermixing layers 130. The interdiffusion of silicon (Si) and/or germanium (Ge) between the sacrificial semiconductor layer 120 and the semiconductor channel layer 125 may occur due to the high-temperature processes that are used to form the layer stack 115. The sacrificial semiconductor layer 120 and the semiconductor channel layer 125 of the layer stack 115 may be formed by epitaxial growth, in which processing temperatures can exceed 1000 degrees Celsius in some implementations. Higher temperatures may lead to increased crystalline quality. However, low temperature processes are within the scope of the present disclosure. The high processing temperatures during the formation of the layer stack 115 can cause material in the sacrificial semiconductor layer 120 and/or materials in the semiconductor channel layer 125 to migrate and to intermix between the sacrificial semiconductor layer 120 and the semiconductor channel layer 125, resulting in formation of the intermixing layers 130.

One or more masking layers may be formed (e.g., using one or more deposition tools) on the layer stack 115. The masking layer(s) may include a hard mask (HM) layer 135, a capping layer 140, an oxide layer 145, and/or a nitride layer 150. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 155 that extend above the semiconductor substrate 110. The fin structures 155 may extend in an x-direction in the semiconductor device 105 and may be arranged in an y-direction in the semiconductor device 105. A fin structure 155 includes a portion 160 of the layer stack 115 over and/or on a fin portion 165 above the semiconductor substrate 110. The fin structures 155 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 155 may be formed to have different widths for different types of nanostructure transistors. As an example, a first subset of fin structures 155a may be formed for p-type nanostructure transistors (e.g., p-type metal oxide semiconductor (PMOS) nanostructure transistors), and a second subset of fin structures 155b may be formed for n-type nanostructure transistors (e.g., n-type metal oxide semiconductor (NMOS) nanostructure transistors). As another example, a first subset of fin structures 155a may be formed for nanostructure transistors that are configured to operate at lower voltages, and a second subset of fin structures 155b may be formed for nanostructure transistors that are configured to operate at higher voltages.

As shown in FIG. 1C, a liner 170 and STI regions 175 are formed between adjacent fin portions 165 of the fin structures 155. The liner 170 and the STI regions 175 may each include a dielectric material such as a silicon oxide (SiOₓ), a silicon nitride (SiₓN_{y}), a silicon oxynitride (SiON), fluoride-doped silicate glass (FSG), undoped silicate glass (USG), a low dielectric constant (low-k) dielectric material (e.g., a dielectric material having a dielectric constant of approximately 3.9 or less), and/or another suitable insulating material.

A deposition tool may be used to conformally deposit the liner 170 (e.g., using ALD or another conformal deposition technique), and may deposit a dielectric layer (e.g., using CVD, PVD, a ALD, and/or another suitable deposition technique) on the liner 170 such that the dielectric layer fully fills in the spaces between the fin structures 155 and extends above the tops of the fin structures 155. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 150. The nitride layer 150 functions as a CMP stop layer in the planarization operation. An etch tool may be used to then etch the dielectric layer to form the STI regions 175 such that the top surfaces of the STI region 175 are approximately co-planar with or below the bottom-most sacrificial semiconductor layer 120.

In some implementations, a hard mask layer (not shown) maybe formed on top of the STI regions 175 between the fin structures 155 to protect the STI regions 175 in subsequent processes. The hard mask layer may include a nitride, such as silicon nitride (SiₓN_{y}), silicon oxynitride, silicon carbide (SiC), silicon carbonitride (SiCN), and/or silicon oxycarbonitride (SiOCN), among other examples. The hard mask layer may be deposited using a suitable process, such as CVD, plasma-enhanced CVD (PECVD), ALD, or the like. Material of the mask layer deposited on the sidewalls of the fin structures 155 may be removed by any suitable etch processes, such as a dry etch or wet etch.

As indicated above, FIGS. 1A-1C are provided as an example. Other examples may differ from what is described with regard to FIGS. 1A-1C.

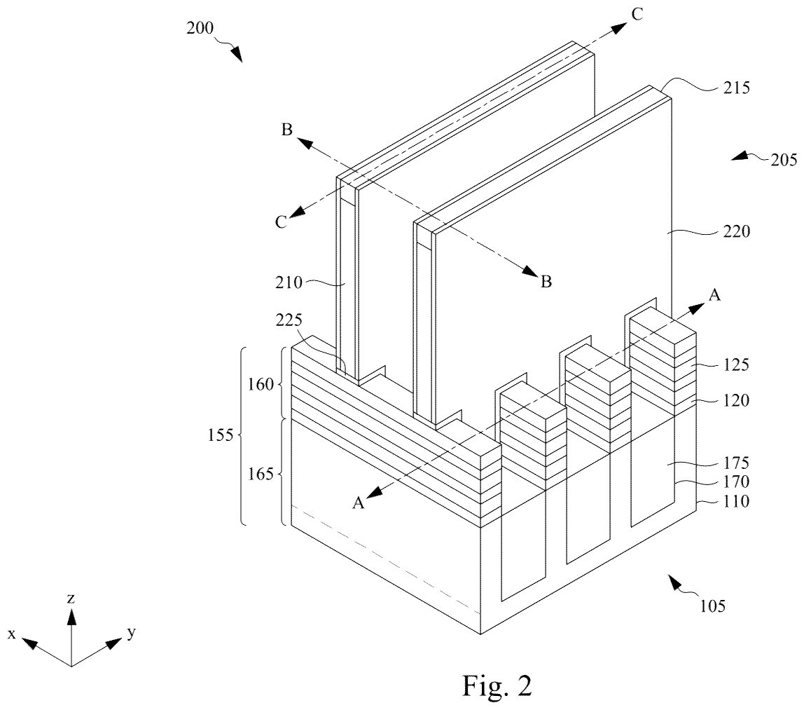

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 200 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 155 and portions of the STI regions 175. The dummy gate structures 205 extend in the y-direction and are arranged in the x-direction such that the dummy gate structures 205 are approximately perpendicular to the fin structures 155. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 155.

A dummy gate structure 205 may include a gate electrode layer 210, a capping layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The capping layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an y-z plane (referred to as a x-cut) across the fin structures 155 in the source/drain areas of the semiconductor device 105. Cross-section B-B is in a x-z plane (referred to as an y-cut) perpendicular to the cross-section A-A, and is across the dummy gate structures 205 and along an underlying fin structure 155. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

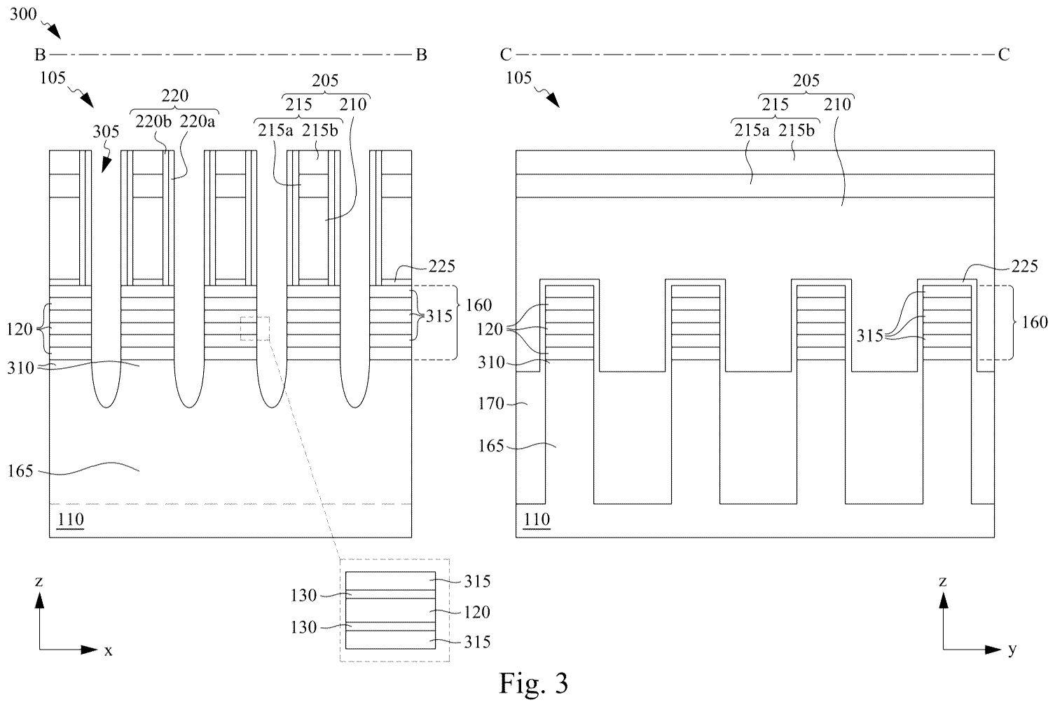

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane B-B in FIG. 2 and the perspective of the cross-sectional plane C-C in FIG. 2. In some implementations, the operations described in connection with the example implementation 300 are performed after the processes described in connection with FIGS. 1A-2.

As shown in the cross-section B-B and in the cross-section C-C in FIG. 3, the capping layer 215 of the dummy gate structures 205 may include a multiple-layer stack. The multiple-layer stack may include a capping layer 215a on the gate electrode layer 210, and a capping layer 215b on the capping layer 215a. The capping layers 215a and 215b may include different materials to provide etch selectivity and/or to enable multiple planarization operations to be performed while the capping layers 215a and 215b protect the gate electrode layers 210 from being removed. In some implementations, the capping layer 215a includes a nitride-containing material such as a silicon nitride (SiₓN_{y} such as Si₃N₄), and the capping layer 215b includes an oxide-containing material such as a silicon oxide (SiOₓ such as SiO₂). However, other combinations of materials for the capping layers 215a and 215b are within the scope of the present disclosure.

As further shown in the cross-section B-B and in the cross-section C-C in FIG. 3, a plurality of spacer layers 220 may be included on the sidewalls of the dummy gate structures including spacer layers 220a on the sidewalls of the dummy gate structures 205, and spacer layers 220b on the spacer layers 220a. The spacer layers 220a and 220b may include different materials to provide etch selectivity for protecting the dummy gate structures 205 from being etched when forming the source/drain recesses 305. In some implementations, the spacer layer 220a includes a low-k dielectric material such as a silicon oxide (SiOₓ such as SiO₂), and the spacer layer 220b includes a high-k dielectric material such as a silicon nitride (SiₓN_{y} such as Si₃N₄). However, other combinations of materials for the spacer layers 220a and 220b are within the scope of the present disclosure.

As further shown in the cross-section B-B in FIG. 3, the source/drain recesses 305 are formed through portions 160 of a fin structure 155 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

In some implementations, the source/drain recesses 305 also extend into a portion of the fin portion 165 of the fin structure 155. In particular, the source/drain recesses 305 may extend into mesa regions 310 in the fin structure 155. The sidewalls of the portions of each source/drain recess 305 below the layer stack 115 correspond to sidewalls of mesa regions 310. A mesa region 310 (also referred to as a pedestal or fin pedestal) refers to a region of the fin portion 165 of the fin structure 155 that extends above the top surface of the STI regions 175.

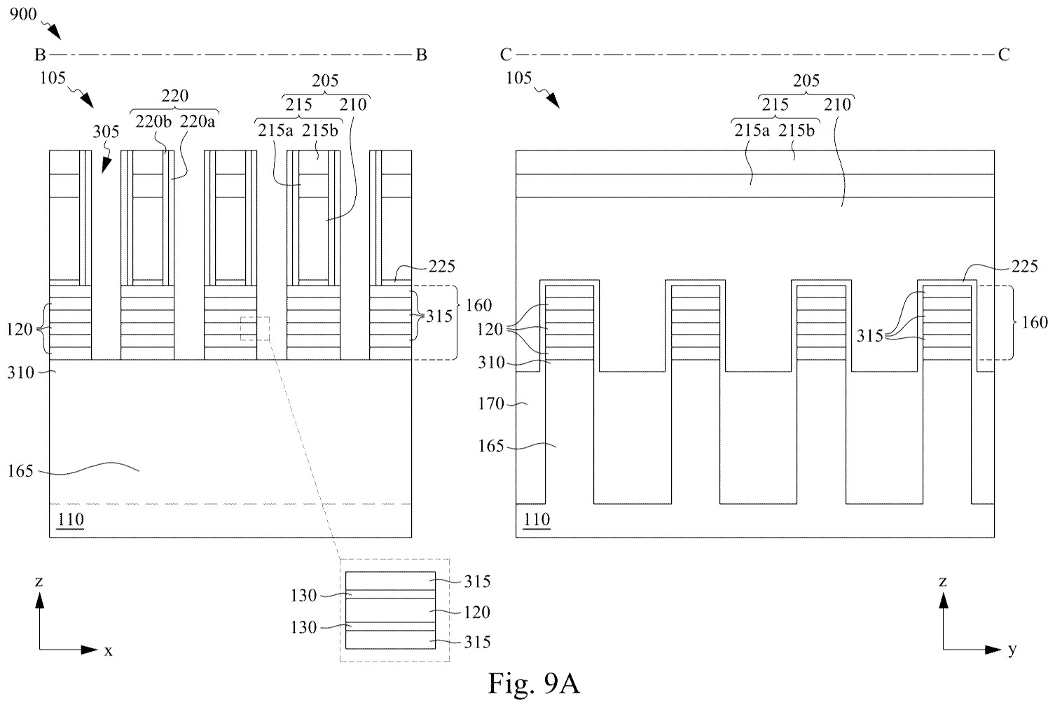

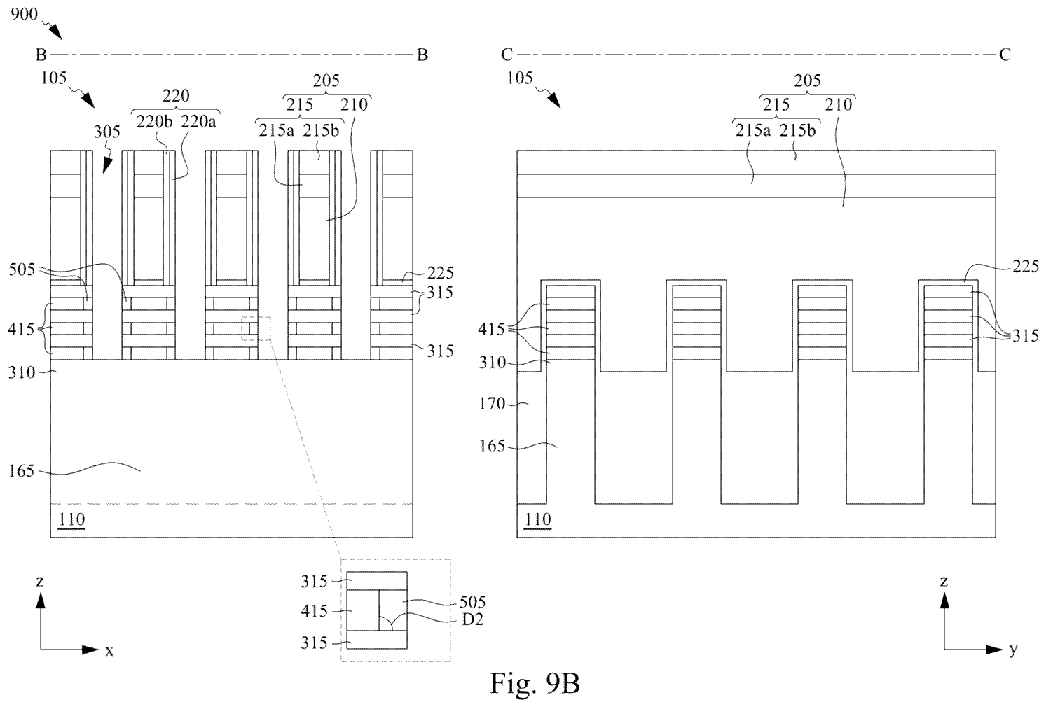

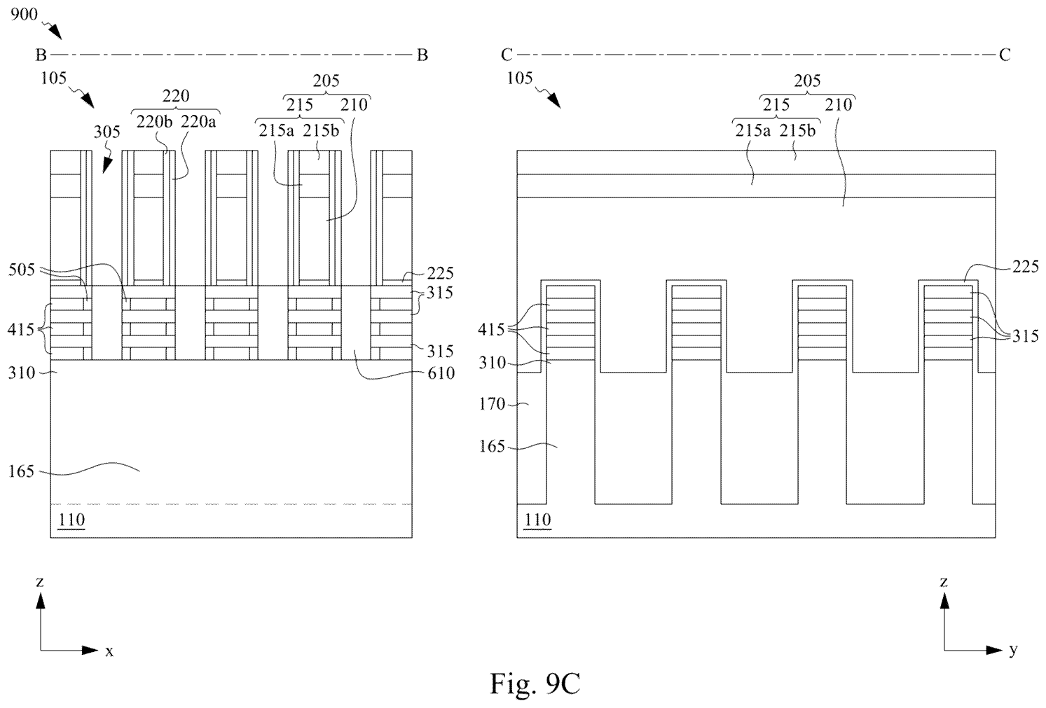

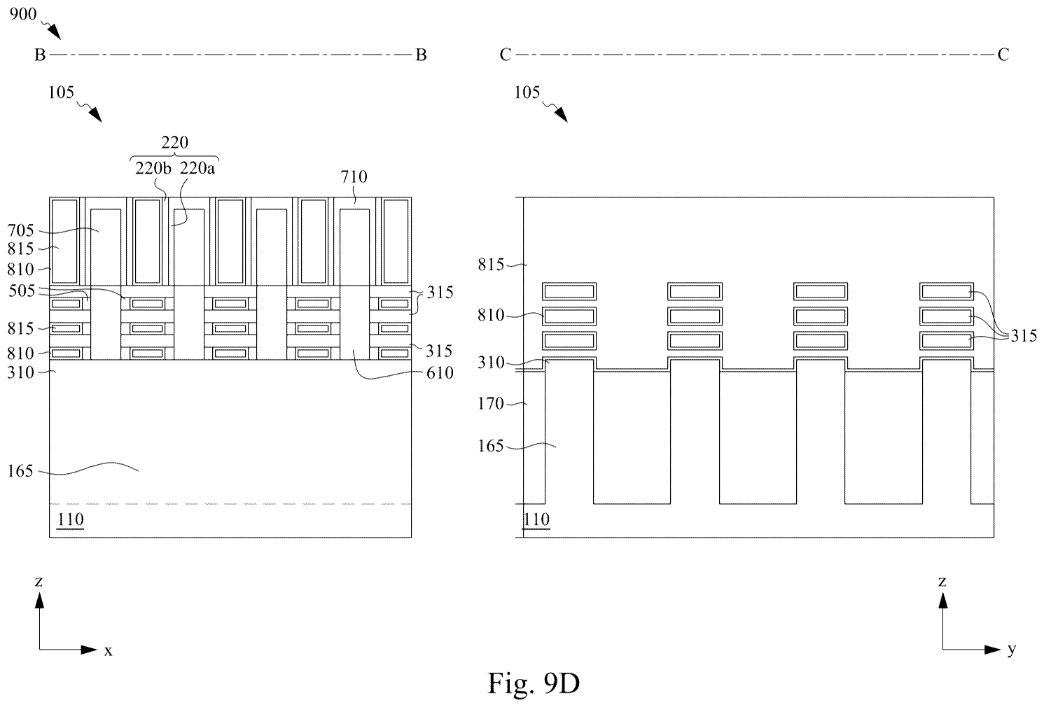

Alternatively, and as described in connection with FIGS. 9A-9D, the source/drain recesses 305 may be formed such that the bottoms of the source/drain recesses 305 do not extend downward (e.g., in the z-direction) into the mesa regions 310 below the bottom-most sacrificial semiconductor layer 120. In these implementations, the bottoms of the source/drain recesses 305 may be approximately co-planar with the bottom surface of the bottom-most sacrificial semiconductor layer 120, or may be located at a higher vertical (z-direction) height in the semiconductor device 105 than the bottom surface of the bottom-most sacrificial semiconductor layer 120. This may reduce the amount and/or likelihood of current leakage from source/drain regions that are to be formed in the source/drain recesses 305, where the current leakage might otherwise occur through the mesa regions 310.

Formation of the source/drain recesses 305 defines nanostructure channels 315 (e.g., of nanostructure transistor structures) of the semiconductor device 105. The nanostructure channels 315 extend between adjacent source/drain recesses 305 and are located under the dummy gate structure 205 between the adjacent source/drain recesses 305. The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon (Si), doped silicon, silicon germanium (SiGe), and/or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As further shown in the cross-section B-B in FIG. 3, ends of the sacrificial semiconductor layers 120, ends of the intermixing layers 130, and ends of the nanostructure channels 315 are exposed in the source/drain recesses 305.

As indicated above, FIG. 3 is provided as an example. Other examples may differ from what is described with regard to FIG. 3.

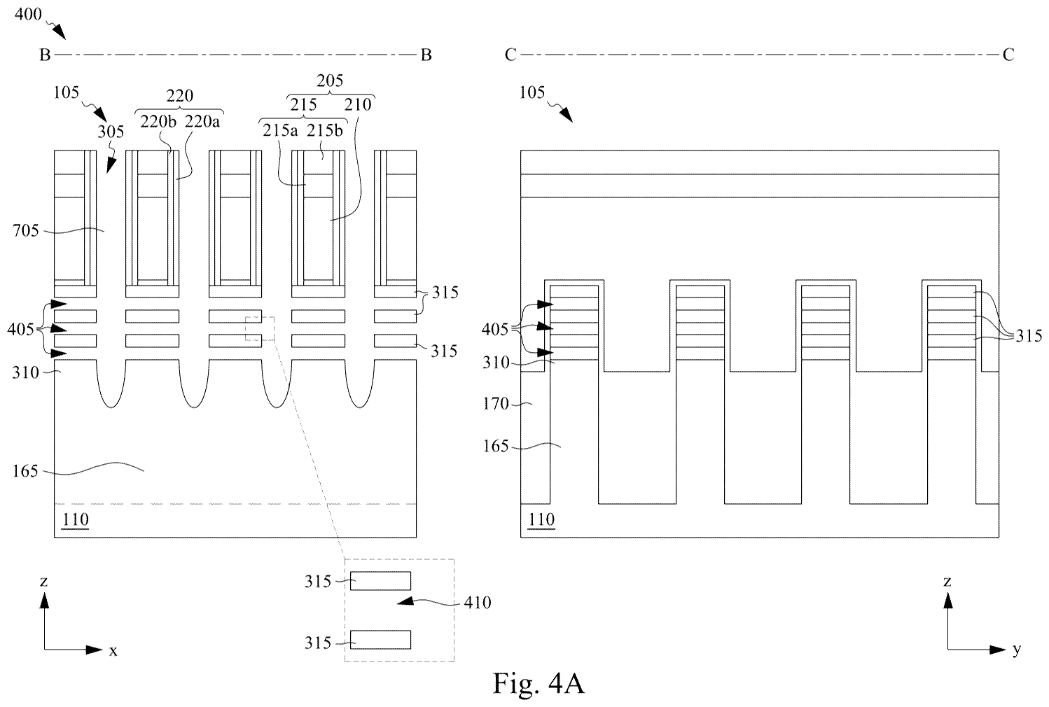

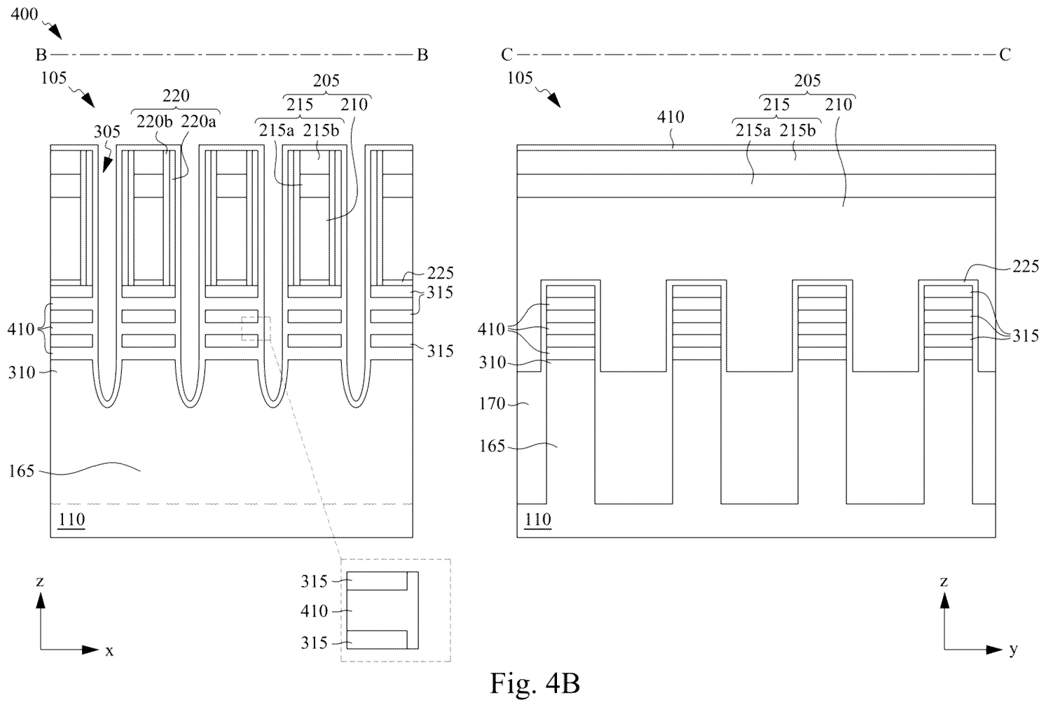

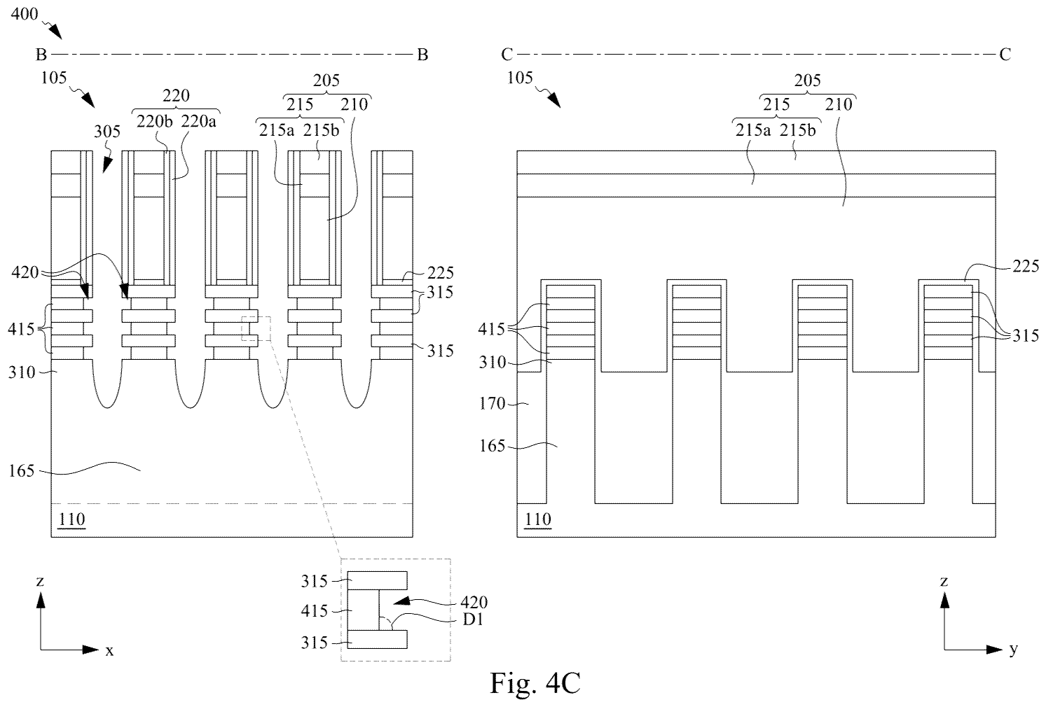

FIGS. 4A-4C are diagrams of an example implementation 400 of a sacrificial dielectric layer formation process described herein. The example implementation 400 includes an example of replacing the sacrificial semiconductor layers 120 with sacrificial dielectric layers. FIGS. 4A-4C are each illustrated from the perspective of the cross-sectional plane B-B and the cross-sectional plane C-C in FIG. 2. In some implementations, the operations described in connection with the example implementation 400 are performed after the processes described in connection with FIGS. 1A-3.

As shown in the cross-section B-B and in the cross-section C-C in FIG. 4A, the remaining portions of the sacrificial semiconductor layers 120 may be removed from between the nanostructure channels 315. In some implementations, the remaining portions of the sacrificial semiconductor layers 120 are etched and removed through the source/drain recesses 305. As further shown in FIG. 4A, the intermixing layers 130 may also be removed from the semiconductor device 105 during removal of the remaining portions of the sacrificial semiconductor layers 120. Since the intermixing layers 130 include material that is also included in the remaining portions of the sacrificial semiconductor layers 120 (e.g., a percentage of silicon germanium (SiGe)), an etchant that is used to etch the sacrificial semiconductor layers 120 also etches the intermixing layers 130. Some etching of the nanostructure channels 315 may also occur during removal of the remaining portions of the sacrificial semiconductor layers 120. Removal of the remaining portions of the sacrificial semiconductor layers 120 results in spaces 405 between vertically adjacent nanostructure channels 315 that were previously occupied by the remaining portions of the sacrificial semiconductor layers 120.

In some implementations, the etchant may include a gas-based etchant that includes a combination of a fluorine-based etchant (e.g., an F₂ gas) and a hydrofluoric acid etchant (e.g., an HF gas). Other gases, such as purge gases, carrier gases, and/or other reactant gases may also be provided into the processing chamber during the etch operation. Such gases may include an argon (Ar) gas, an ammonia (NH₃) gas, a chlorine trifluoride (ClF₃) gas, and/or a nitrogen (N₂) gas, among other examples. The etchant may be used to etch the sacrificial semiconductor layers 120 and the intermixing layers 130 by removing silicon (Si) and germanium (Ge) from the sacrificial semiconductor layers 120 and the intermixing layers 130. The removal of silicon (Si) from the sacrificial semiconductor layers 120 and in the intermixing layers 130 may result from a reaction between the fluorine-based etchant (e.g., the F₂ gas) in the etchant and the silicon germanium (SiGe) in the sacrificial semiconductor layers 120 and in the intermixing layers 130:

$$S i G e + {F}_{2} \to G e {F}_{3} + S i {F}_{3} \to G e {F}_{2} + S i {F}_{4}$$

The fluorine-based etchant (e.g., the F₂ gas) in the etchant may attach to the silicon (Si) and the germanium (Ge) in the sacrificial semiconductor layers 120 and in the intermixing layers 130 to respectively form germanium trifluoride (GeF₃) and silicon trifluoride (SiF₃). A fluorine migration (F-migration) may occur where a fluorine (F) atom migrates from a germanium trifluoride molecule to a silicon trifluoride molecule, resulting in formation of germanium difluoride (GeF₂) and a silicon tetrafluoride (SiF₄) gas. The silicon tetrafluoride gas is removed from the semiconductor device 105, resulting in removal of silicon (Si) from the sacrificial semiconductor layers 120 and the intermixing layers 130.

The removal of germanium (Ge) from the sacrificial semiconductor layers 120 and in the intermixing layers 130 may result from a reaction between a combination of the fluorine-based etchant (e.g., the F₂ gas) and the hydrofluoric acid etchant (e.g., the HF gas) in the etchant and the silicon germanium (SiGe) in the sacrificial semiconductor layers 120 and in the intermixing layers 130:

$$S i G e + {F}_{2} + H F \to G e {H}_{2} F + S i H {F}_{2} \to G e {H}_{3} F + S i {F}_{2}$$

The fluorine (F) in the fluorine-based etchant (e.g., the F₂ gas) and/or in the hydrofluoric acid etchant (e.g., the HF gas) may attach to the silicon (Si) and the germanium (Ge) in the sacrificial semiconductor layers 120 and in the intermixing layers 130. Moreover, the hydrogen in the hydrofluoric acid etchant of the etchant may attach to the silicon (Si) and the germanium (Ge) in the sacrificial semiconductor layers 120 and in the intermixing layers 130. The fluorine and the hydrogen react with the germanium to form germanium dihydrogen fluoride (GeH₂F) and silicon hydrogen difluoride (SiHF₂). A hydrogen migration (H-migration) may occur where a hydrogen (H) atom migrates from a silicon hydrogen difluoride molecule to a germanium dihydrogen fluoride molecule, resulting in formation of a germanium trihydrogen fluoride (GeH₃F) gas and silicon difluoride (SiF₂). The germanium trihydrogen fluoride gas is removed from the semiconductor device 105, resulting in removal of germanium (Ge) from the sacrificial semiconductor layers 120 and the intermixing layers 130.

As shown in cross-sections B-B and C-C in FIGS. 4B and 4C, the sacrificial semiconductor layers 120 and the intermixing layers 130 are removed and replaced with sacrificial dielectric layers. The sacrificial semiconductor layers 120 and the intermixing layers 130 may be replaced with the sacrificial dielectric layers to achieve precise control over the size and shape of the cavities in which inner spacers of the semiconductor device 105 are to be formed. In particular, the etch selectivity between the dielectric material of the sacrificial dielectric layers and the semiconductor material of the nanostructure channels 315 (e.g., silicon (Si)) may be greater than the etch selectivity between the semiconductor material of the sacrificial semiconductor layers 120 (e.g., silicon germanium (SiGe)) and the semiconductor material of the nanostructure channels 315 (e.g., silicon (Si)). The greater etch selectivity enables the cavities to be formed with sharper corners than if the sacrificial semiconductor layers 120 and the intermixing layers 130 remained. The sharper corners of the cavities facilitate formation of inner spacers that also have sharper corners (as opposed to inner spacers that have rounded corners, which might occur if the sacrificial semiconductor layers 120 and the intermixing layers 130 remained), which reduces the likelihood of etching through the nanostructure channels 315 at the corners of the inner spacers during a replacement gate process to replace the dummy gate structures 205 with high-k/metal gate structures. Thus, replacing the sacrificial semiconductor layers 120 and the intermixing layers 130 with sacrificial dielectric layers reduces the likelihood of etching damage to source/drain regions that are to be formed in the source/drain recesses 305.

The sacrificial semiconductor layers 120 and the intermixing layers 130 may be removed and replaced with sacrificial dielectric layers, as opposed to forming the layer stack 115 with the sacrificial dielectric layers instead of the sacrificial semiconductor layers 120, to achieve higher process efficiency and higher-quality nanostructure channels 315. Since the semiconductor channel layers 125 (from which the nanostructure channels 315 were formed) are epitaxially grown, the sacrificial semiconductor layers 120 provide a semiconductor base on which the lattice structure of the semiconductor channel layers 125 can be grown. The sacrificial semiconductor layers 120 and the semiconductor channel layers 125 may have a similar lattice constant, which provides for high-quality epitaxial growth of the semiconductor channel layers 125. If the semiconductor channel layers 125 were instead grown on sacrificial dielectric layers, the lattice mismatch between the sacrificial dielectric layers and the semiconductor channel layers 125 might otherwise result in cracking and other defect formation in the semiconductor channel layers 125. Moreover, the time, complexity, and/or cost of forming the source/drain recesses 305 may be greater because of additional steps and etchants that would otherwise be needed to etch the semiconductor material of the semiconductor channel layers 125 and the dielectric material of the sacrificial dielectric layers in separate etching steps (whereas the semiconductor channel layers 125 and the sacrificial semiconductor layers 120 may otherwise be able to be etched using the same etchant in the same etching step to form the source/drain recesses 305).

As shown in the cross-section B-B and in the cross-sectional plane C-C in FIG. 4B, a dielectric layer 410 may be deposited along the bottom and along the sidewalls of the source/drain recesses 305. The dielectric layer 410 is further deposited in the spaces (or areas) 405 vertically between the nanostructure channels 315 that were previously occupied by the sacrificial semiconductor layers 120. In some implementations, a deposition tool is used to deposit the dielectric layer 410 using a CVD technique, a PVD technique, an ALD technique, and/or another deposition technique. In some implementations, a deposition tool is used to deposit the material of the dielectric layer 410 using a flowable deposition technique. For example, the material of the dielectric layer 410 may be dispensed into the source/drain recesses 305 so that the material can flow into the spaces 405 between vertically adjacent nanostructure channels 315, and a curing process may be used to cure the material to form the dielectric layer 410.

As shown in the cross-section B-B and in the cross-sectional plane C-C in FIG. 4C, excess material of the dielectric layer 410 on the sidewalls and bottom surfaces of the source/drain recesses 305 is removed so that the dielectric layer 410 remains in the spaces 405 between vertically adjacent nanostructure channels 315 as sacrificial dielectric layers 415. An etch tool may be used to trim the dielectric layer 410 using a wet etch technique, a dry etch technique, and/or another suitable etch technique.

The sacrificial dielectric layers 415 may be “nanostructure” layers or “nanoscale” layers in that the sacrificial dielectric layers 415 may each have a z-direction thickness that is on the order of nanometers. For example, the sacrificial dielectric layers 415 may each have a z-direction thickness that is approximately 10 nanometers or less. However, other values for the z-direction thicknesses of the sacrificial dielectric layers 415 are within the scope of the present disclosure.

The flowable deposition technique (and/or another low-density deposition technique) that was used to deposit the dielectric layer 410 may result in the sacrificial dielectric layers 415 having a low material density, and the low material density of the sacrificial dielectric layers 415 results in the sacrificial dielectric layers 415 having a relatively low stiffness. For example, the sacrificial dielectric layers 415 may include a low-density silicon oxide (SiOₓ) that has a Young's modulus that is less than the Young's modulus of the semiconductor material of the sacrificial semiconductor layers 120 and that is less than the Young's modulus of the semiconductor material of the nanostructure channels 315. Thus, the elasticity (e.g., the elastic modulus) of the sacrificial dielectric layers 415 is less than the elasticity of the sacrificial semiconductor layers 120 and is less than the elasticity of the nanostructure channels 315. Accordingly, the sacrificial dielectric layers 415 absorb less of the tensile and compressive stresses exerted onto the nanostructure channels 315, compared to the sacrificial semiconductor layers 120. Thus, the sacrificial dielectric layers 415 may support the nanostructure channels 315 during subsequent stress-inducing process (e.g., source/drain formation) in a manner that prevents or reduces the likelihood of permanent deformation (e.g., buckling, thinning) of the nanostructure channels 315 while still enabling the crystal lattice of the nanostructure channels 315 to be strained for increased carrier mobility in the nanostructure channels 315.

In some implementations, the Young's modulus of the material of the sacrificial dielectric layers 415 is included in a range of approximately 43 to approximately 92. In some implementations, the Young's modulus of the material of the sacrificial semiconductor layers 120 is included in a range of approximately 100 to approximately 190. In some implementations, the Young's modulus of the material of the nanostructure channels 315 is included in a range of approximately 130 to approximately 188. However, other values and ranges for the Young's modulus of the materials of the sacrificial dielectric layers 415, the sacrificial semiconductor layers 120, and the nanostructure channels 315 are within the scope of the present disclosure.

As further shown in the cross-section B-B in FIG. 4C, the ends of the sacrificial dielectric layers 415 that are exposed in the source/drain recesses 305 are laterally etched (e.g., in the x-direction that is approximately parallel to a length of the sacrificial semiconductor layers 120) in one or more first etch operations, thereby forming cavities 420 between the ends of the nanostructure channels 315 that are exposed in the source/drain recesses 305. In particular, an etch tool may be used to laterally etch the ends of the sacrificial dielectric layers 415 under the dummy gate structures 205 through the source/drain recesses 305 to form the cavities 420 between ends of the nanostructure channels 315.

As shown in a close-up view in FIG. 4C, the cavities 420 may have sharp inner corners where the sidewalls of the cavities 420 and the inner surface of the cavities 420 are approximately orthogonal. As indicated above, the etch selectivity between the dielectric material of the sacrificial dielectric layers 415 and the semiconductor material of the nanostructure channels 315, in combination with removal of the intermixing layers 130, enables the sharp inner corners to be formed for the cavities 420. In some implementations, an angle of the inner corners of the cavities 420 (indicated in FIG. 4C as dimension D1) may be greater than 80 degrees and may be included in a range of approximately 85 degrees to approximately 90 degrees. However, other angles for the inner corners are within the scope of the present disclosure.

As indicated above, FIGS. 4A-4C provided as an example. Other examples may differ from what is described with regard to FIGS. 4A-4C.

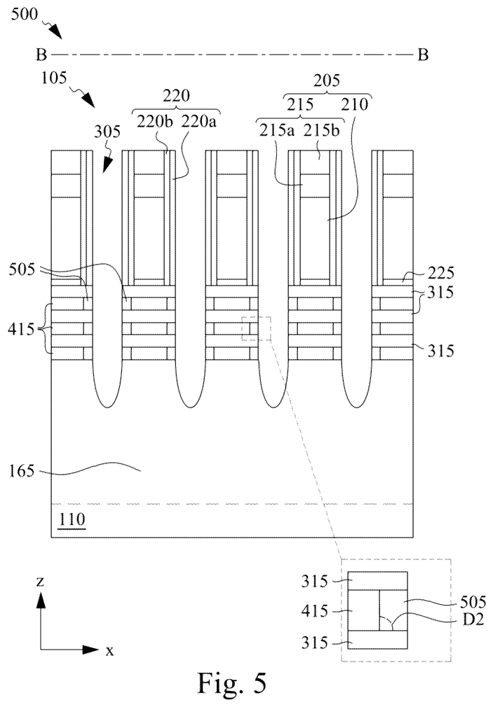

FIG. 5 is a diagram of an example implementation 500 of an inner spacer formation process described herein. The example implementation 500 includes an example of forming inner spacers between ends of the nanostructure channels 315 that are exposed in the source/drain recesses 305. FIG. 5 is illustrated from the perspective of the cross-sectional plane B-B in FIG. 2. In some implementations, the operations described in connection with the example implementation 500 are performed after the processes described in connection with FIGS. 1A-4C.

As shown in FIG. 5, inner spacers 505 are formed in the cavities 420 between the ends of vertically adjacent nanostructure channels 315 in the source/drain recesses 305. The inner spacers 505 are included to reduce parasitic capacitance in the nanostructure transistors and to protect source/drain regions (that are subsequently formed in the source/drain recesses 305) from being etched in a nanosheet release operation to remove the sacrificial dielectric layers 415 between the nanostructure channels 315. The inner spacers 505 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 505, a deposition tool may be used to deposit a layer of dielectric material in the cavities 420 and along the sidewalls and bottom surface of the source/drain recesses. A CVD technique, a PVD technique, an ALD technique, and/or another deposition technique may be used to deposit the layer of dielectric material. An etch tool is used to subsequently remove excess material of the layer of dielectric material from the source/drain recesses such that remaining portions correspond to the inner spacers 505 in the cavities 420.

As shown in a close-up view in FIG. 5, the inner spacers 505 may have sharp inner corners that are approximately orthogonal between the sidewalls of the inner spacers 505 and the inner surface of the inner spacers 505. The sharp inner corners may be achieved as a result of the techniques described above that are used to replace the sacrificial semiconductor layers 120 and the intermixing layers 130, and to form the cavities 420 in the sacrificial dielectric layers 415. In some implementations, an angle of the inner corners of the inner spacers 505 (indicated in FIG. 5 as dimension D2) may be greater than 80 degrees and may be included in a range of approximately 85 degrees to approximately 90 degrees. However, other angles for the inner corners are within the scope of the present disclosure.

As indicated above, FIG. 5 is provided as an example. Other examples may differ from what is described with regard to FIG. 5.

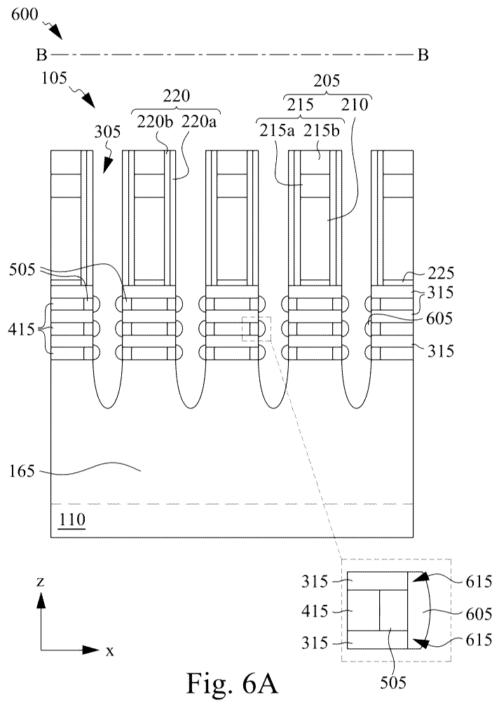

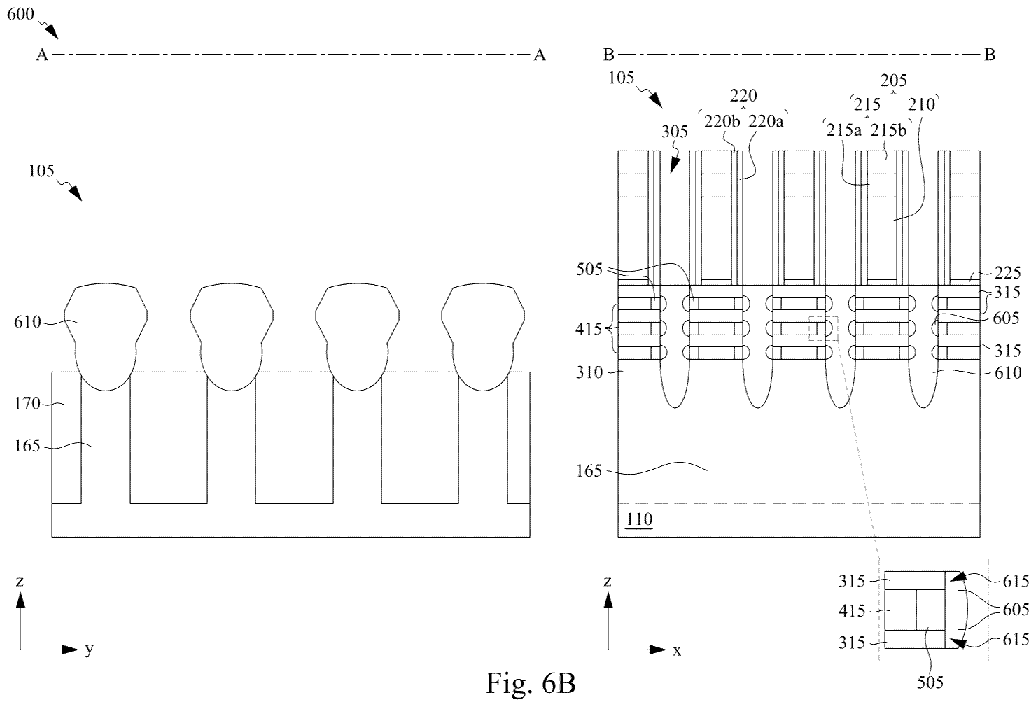

FIGS. 6A and 6B are diagrams of an example implementation 600 of a source/drain region formation process described herein. The example implementation 600 includes an example of forming the source/drain regions of the nanostructure transistors of the semiconductor device 105. FIGS. 6A and 6B are illustrated from a plurality of perspectives illustrated in FIG. 2, including the perspective of the cross-sectional plane A-A in FIG. 2 and the perspective of the cross-sectional plane B-B in FIG. 2. In some implementations, the operations described in connection with the example implementation 600 are performed after the processes described in connection with FIGS. 1A-5.

As shown in the cross-section B-B in FIG. 6A, a plurality of non-contiguous epitaxial regions 605 are formed on the sidewalls in the source/drain recesses 305. The epitaxial regions 605 are non-contiguous in that the epitaxial regions 605 are discrete regions of material that are not touching each other. However, in some implementations, two or more epitaxial regions 605 may be in physical contact.

In the example illustrated in a close-up view in FIG. 6A, the non-contiguous epitaxial regions 605 are formed on the ends of the inner spacers 505 that are exposed in the source/drain recesses 305. An epitaxial region 605 may continuously span across an end of an inner spacer 505 and portions of the ends of nanostructure channels 315 on vertically opposing sides of the inner spacer 505. Thus, overlap regions 615 occur where the epitaxial region 605 partially overlaps the portions of the ends of nanostructure channels 315 on vertically opposing sides of the inner spacer 505. The epitaxial region 605 in the overlap regions 615 protects against etching through the interface between the inner spacer 505 and the nanostructure channels 315 (which might otherwise result in etching of a source/drain region formed in the source/drain recess 305) during the replacement gate process for the semiconductor device 105.

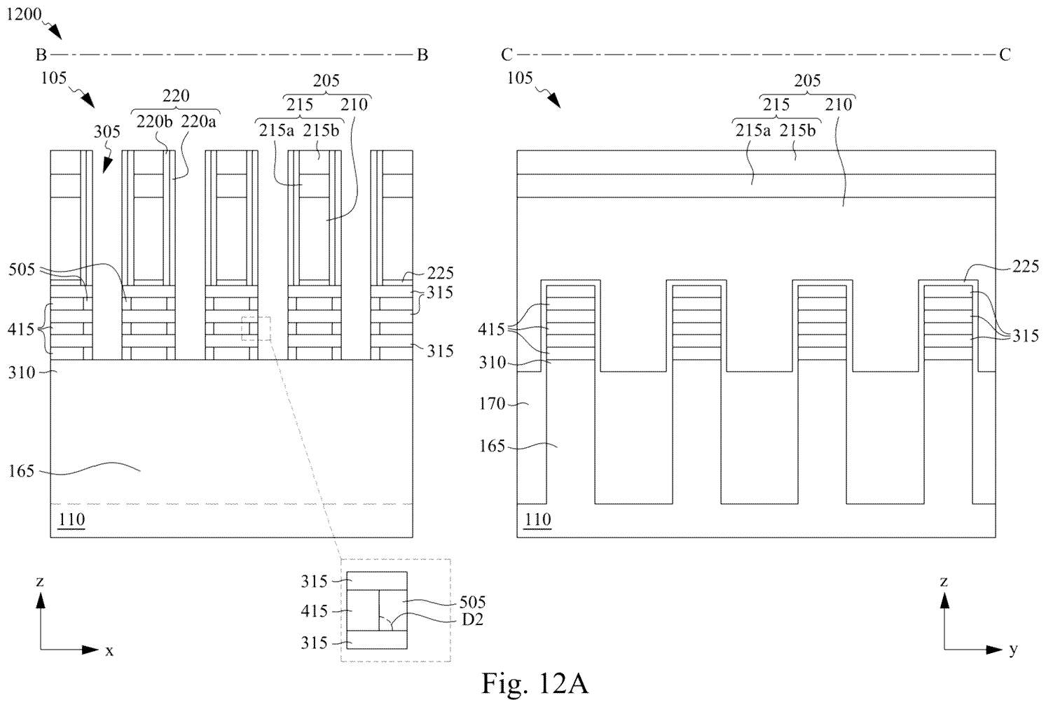

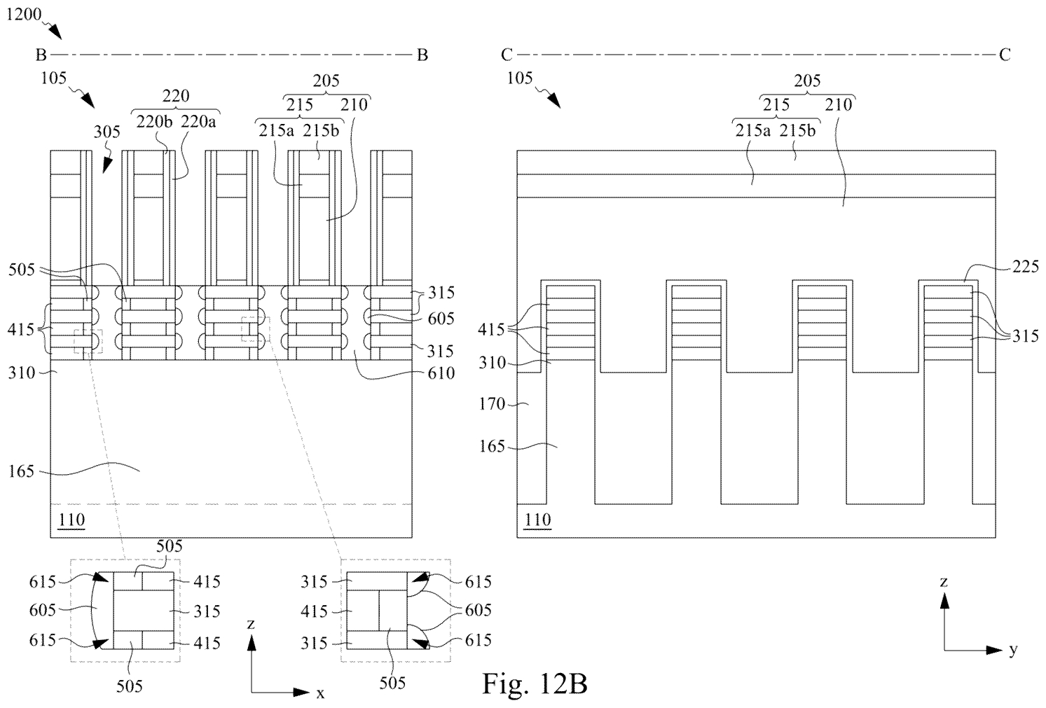

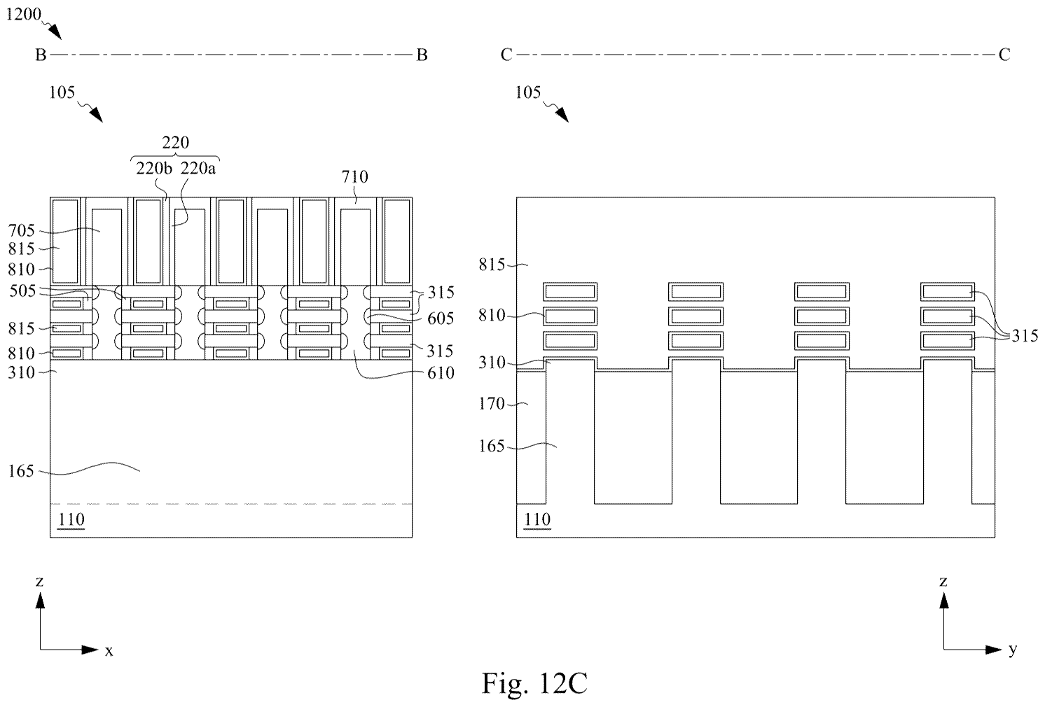

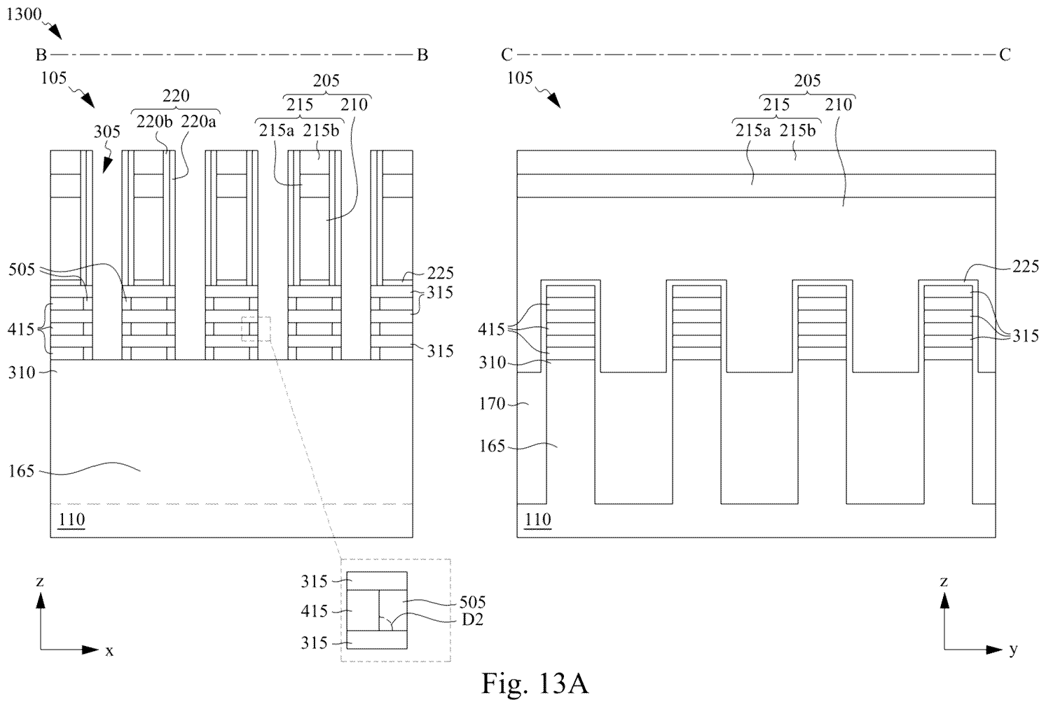

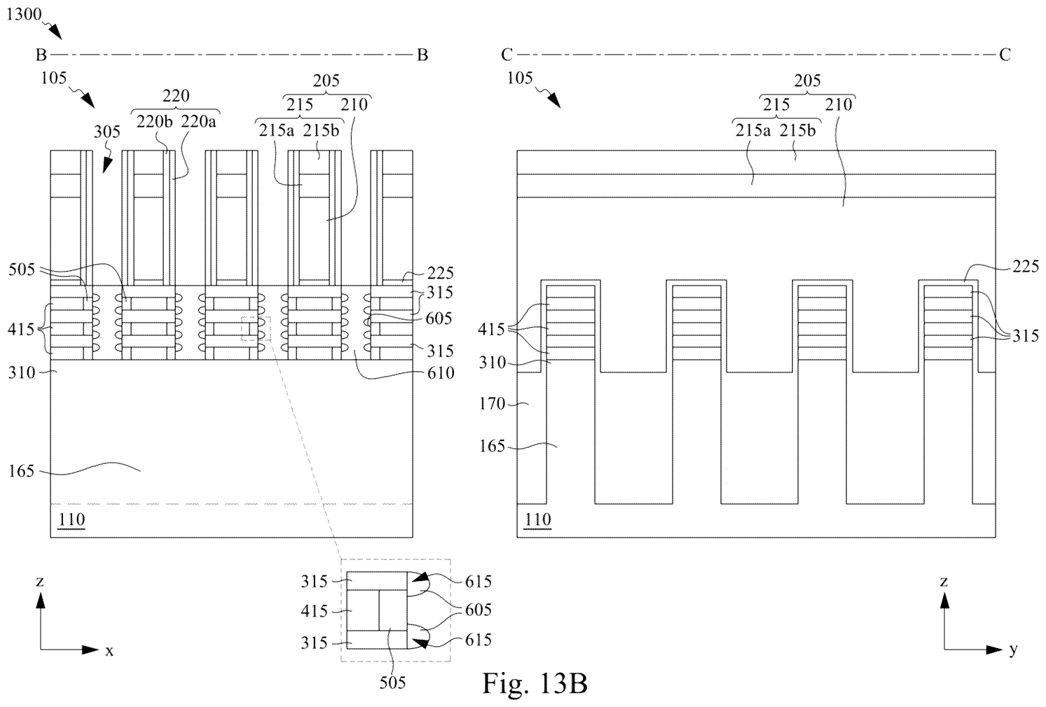

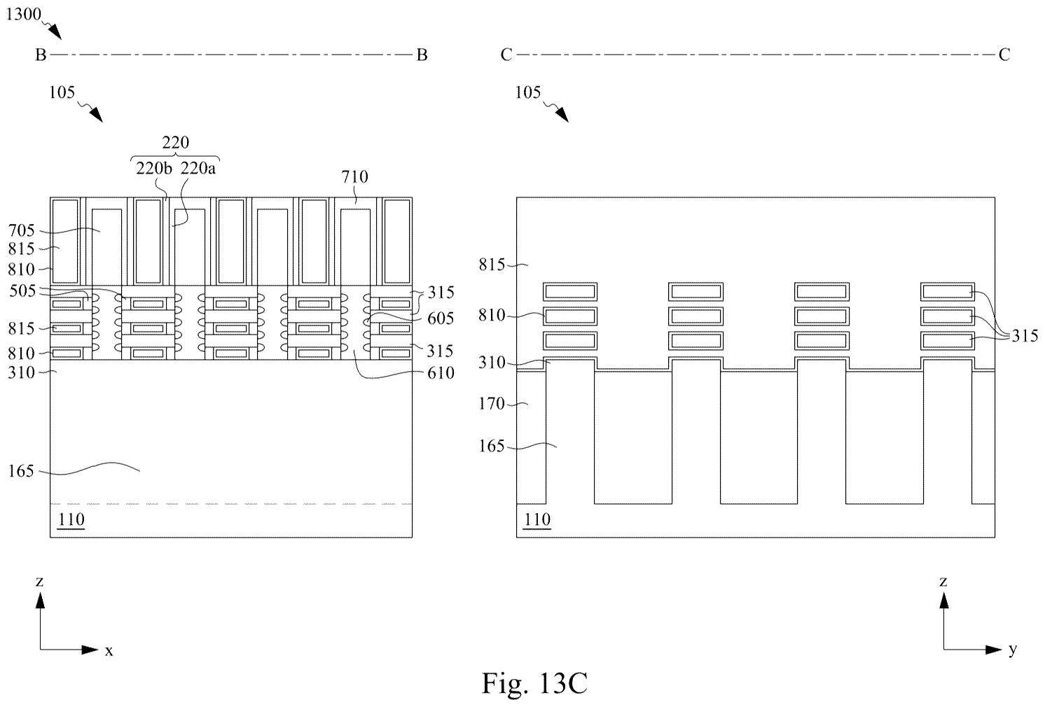

The location of the non-contiguous epitaxial regions 605 illustrated in FIG. 6A is an example, and other locations for the non-contiguous epitaxial regions 605 are within the scope of the present disclosure. Other examples of locations of the non-contiguous epitaxial regions 605 are illustrated in connection with FIGS. 12A-12C and 13A-13C.

To enable the non-contiguous epitaxial regions 605 to withstand etching during the replacement gate process for the semiconductor device 105, the non-contiguous epitaxial regions 605 may include semiconductor material (e.g., silicon (Si)) that is doped with a higher dopant concentration than the dopant concentration in the source/drain regions 610.

For p-type source/drain regions, the non-contiguous epitaxial regions 605 may be doped with p-type dopants such as boron (B) and/or gallium (Ga), among other examples. The p-type dopants increase the energy needed to remove electrons from the non-contiguous epitaxial regions 605 (e.g., from approximately 3.55 electron-volts to approximately 4.1 electron-volts), thus requiring greater energy to remove material from the non-contiguous epitaxial regions 605, compared to the source/drain regions. The dopant concentration of p-type dopants in the non-contiguous epitaxial regions 605 may be included in a range of approximately 1×10¹⁹ atoms per cubic centimeter in the non-contiguous epitaxial regions 605 to approximately 1×10²² atoms per cubic centimeter in the non-contiguous epitaxial regions 605, to provide sufficient etch resistance to halogen-based etchants. However, other values and ranges for the dopant concentration of p-type dopants in the non-contiguous epitaxial regions 605 are within the scope of the present disclosure. Increasing the concentration of p-type dopants may increase the etch resistance of the non-contiguous epitaxial regions 605.

For n-type source/drain regions, the non-contiguous epitaxial regions 605 may be doped with carbon (C) and/or another suitable dopant. The carbon doping increases the etch resistance of the non-contiguous epitaxial regions 605 without negatively impacting the n-type doping of the n-type source/drain regions. The dopant concentration of carbon doping in the non-contiguous epitaxial regions 605 may be included in a range of approximately 1×10¹⁹ atoms per cubic centimeter in the non-contiguous epitaxial regions 605 to approximately 1×10²² atoms per cubic centimeter in the non-contiguous epitaxial regions 605, to provide sufficient etch resistance to halogen-based etchants. However, other values and ranges for the dopant concentration of carbon doping in the non-contiguous epitaxial regions 605 are within the scope of the present disclosure.

In some implementations, the non-contiguous epitaxial regions 605 may be doped with a plurality of dopants, including carbon dopants and n-type dopants such as arsenic (As) and/or phosphorous (P). In these implementations, the concentration of carbon dopants may be increased, and/or the concentration of n-type dopants may be decreased, to increase the etch resistance of the non-contiguous epitaxial regions 605.

As shown in the cross-section A-A and in the cross-section B-B in FIG. 6B, additional epitaxial material is deposited in the source/drain recesses 305 over the non-contiguous epitaxial regions 605 to form source/drain regions 610 in the source/drain recesses 305. “Source/drain region” may refer to a source region and/or a drain region, individually or collectively dependent upon the context. Source/drain regions 610 may be included on opposing sides of a dummy gate structure 205 such that the nanostructure channels 315 under the dummy gate structure 205 extend between, and are electrically coupled with, source/drain regions 610.

The source/drain regions 610 may each include epitaxially-grown silicon (Si) and/or another epitaxially-grown material. In some implementations, the source/drain regions 610 include silicon doped with one or more dopants, such as a p-type material (e.g., boron (B) or germanium (Ge), among other examples), an n-type material (e.g., phosphorous (P) or arsenic (As), among other examples), and/or another type of dopant. In these implementations, the semiconductor device 105 may include PMOS nanostructure transistors that include p-type source/drain regions, NMOS nanostructure transistors that include n-type source/drain regions, and/or other types of nanostructure transistors.

The epitaxy technique that is used to form the source/drain regions 610 may induce lateral stresses in the nanostructure channels 315. For example, the epitaxial growth (and the associated high processing temperatures) may result in tensile stresses and/or compressive stresses being induced in the nanostructure channels 315. The sacrificial dielectric layers 415 support the nanostructure channels 315 during the epitaxial growth of the source/drain regions 610 (which prevents or reduces the likelihood of buckling and/or thinning of the nanostructure channels 315) while still enabling the lateral stresses to induce straining in the nanostructure channels 315. The straining in the nanostructure channels 315 increases the charge carrier mobility in the nanostructure channels 315.

As shown in FIG. 6B, in some implementations, the epitaxial material of the source/drain regions 610 fills in the source/drain recesses 305. In some implementations, an isolation layer is formed at the bottom of the source/drain recesses 305, and the epitaxial material of the source/drain regions 610 is formed on the isolation layer. In these implementations, the bottom surfaces of the source/drain regions 610 may be approximately vertically aligned with the bottom surfaces of the lowest layer of inner spacers 505.

As indicated above, FIGS. 6A and 6B are provided as an example. Other examples may differ from what is described with regard to FIGS. 6A and 6B.

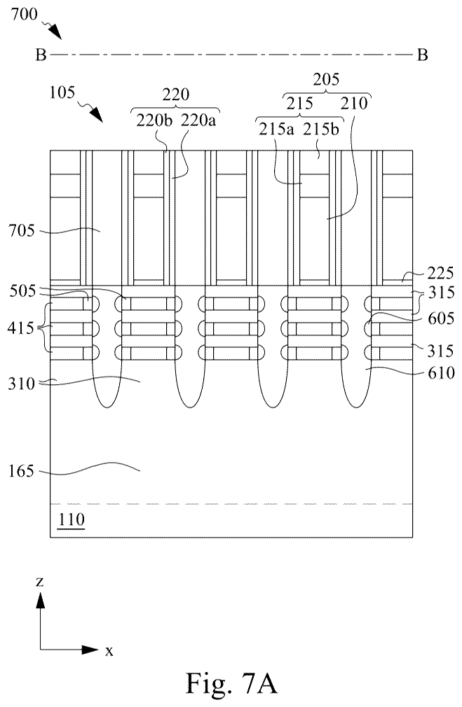

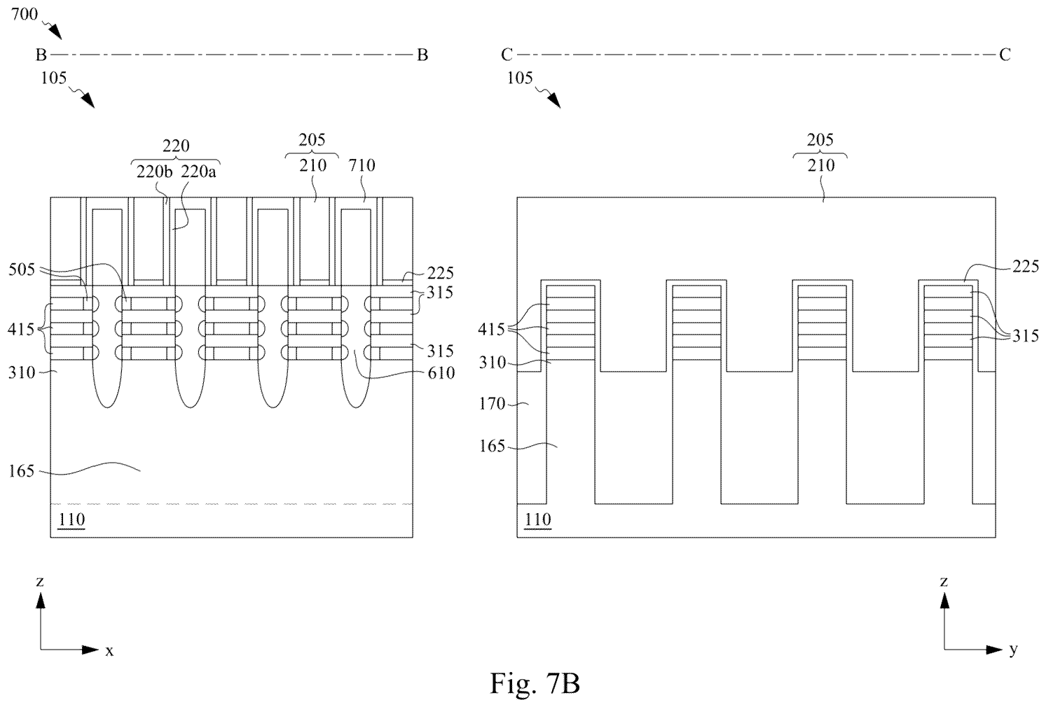

FIGS. 7A and 7B are diagrams of an example implementation 700 of an interlayer dielectric (ILD) formation process described herein. FIGS. 7A and 7B are illustrated from a plurality of perspectives illustrated in FIG. 2, including the perspective of the cross-sectional plane B-B in FIG. 2 and the perspective of the cross-sectional plane C-C in FIG. 2. In some implementations, the operations described in connection with the example implementation 700 are performed after the processes described in connection with FIGS. 1A-6B.

As shown in the cross-section B-B in FIG. 7A, a dielectric layer 705 is formed over the source/drain regions 610. The dielectric layer 705 (which may be referred to as an ILD layer) fills in areas between the dummy gate structures 205. The dielectric layer 705 may be formed to reduce the likelihood of and/or prevent damage to the source/drain regions 610 during a replacement gate process to replace the dummy gate structures 205. The dielectric layer 705 may be referred to as an ILD zero (ILD0) layer or another ILD layer. The dielectric layer 705 may include a silicon oxide (SiOₓ), USG, FSG, and/or another suitable low-k material. A deposition tool may be used to deposit the dielectric layer using a PVD technique, ALD technique, a CVD technique, and/or another suitable deposition technique. In some implementations, a contact etch stop layer (CESL) (not shown) is conformally deposited (e.g., by a deposition tool) over the source/drain regions 610 prior to formation of the dielectric layer 705.

As shown in the cross-section B-B and in the cross-section C-C in FIG. 7B, a planarization tool may be used to perform a planarization operation (e.g., a CMP operation) to planarize the semiconductor device 105. The planarization operation may result in removal of the capping layers 215a and 215b from the dummy gate structures 205, which exposes the tops of the gate electrode layer 210 of the dummy gate structures 205.

As further shown in FIG. 7B, a capping layer 710 may be formed on the dielectric layer 705 to protect the dielectric layer 705 during subsequent operations such as the replacement gate process. The capping layer 710 may include a silicon nitride (SiₓN_{y}), silicon carbon nitride (SiCN), silicon oxynitride (SiON), or a combination thereof, among other examples.

As indicated above, FIGS. 7A and 7B are provided as an example. Other examples may differ from what is described with regard to FIGS. 7A and 7B.

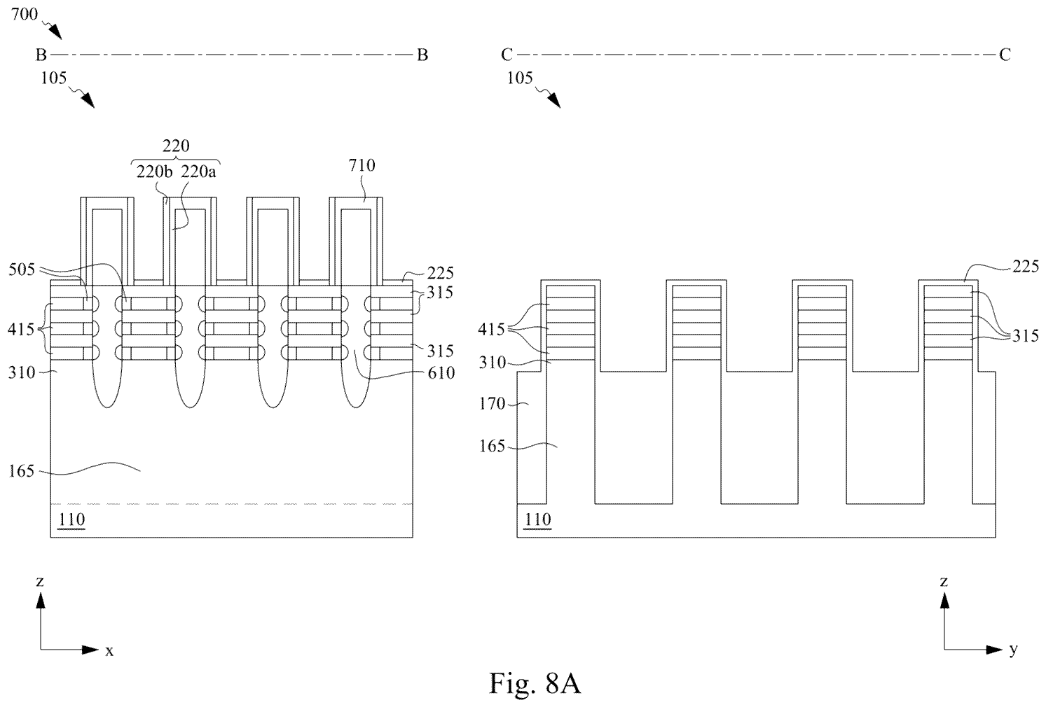

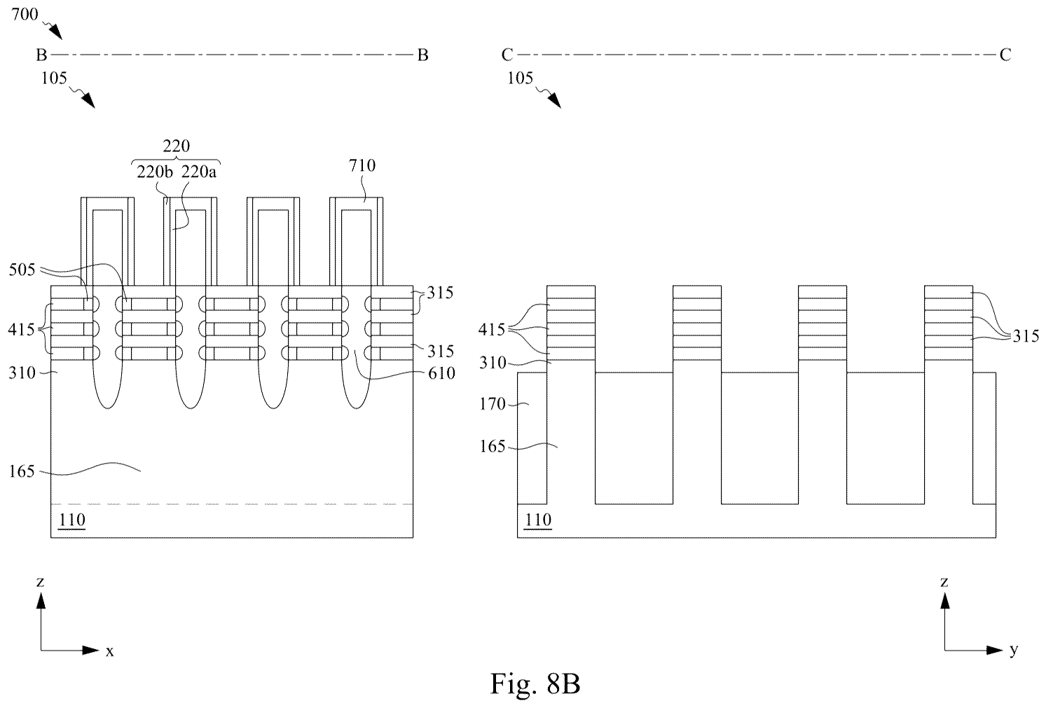

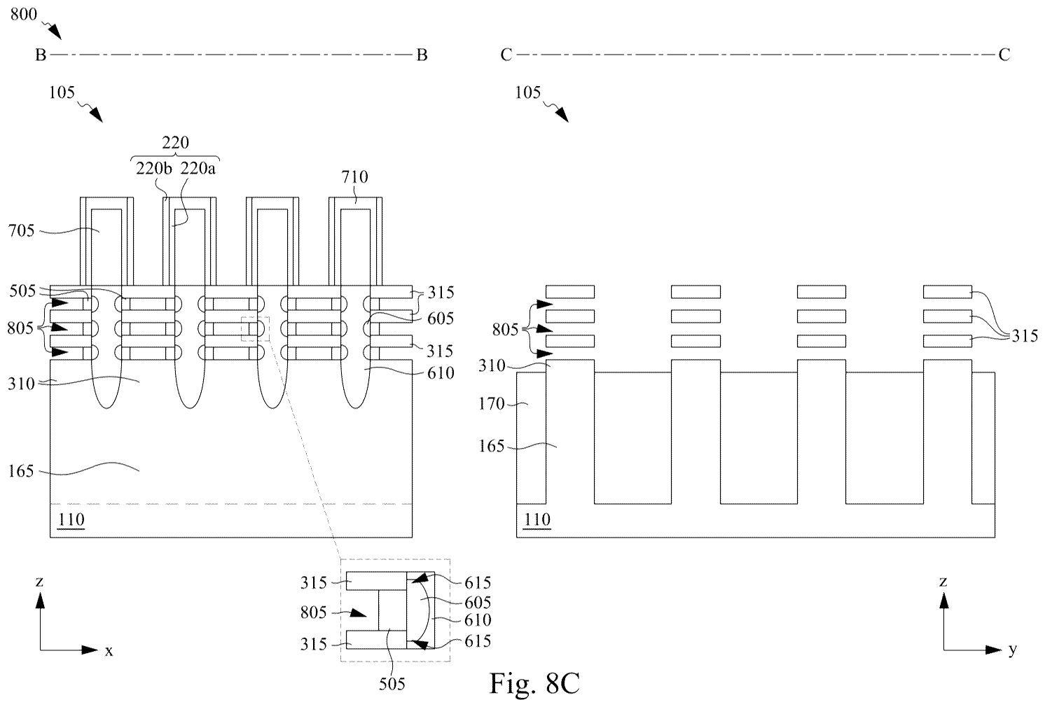

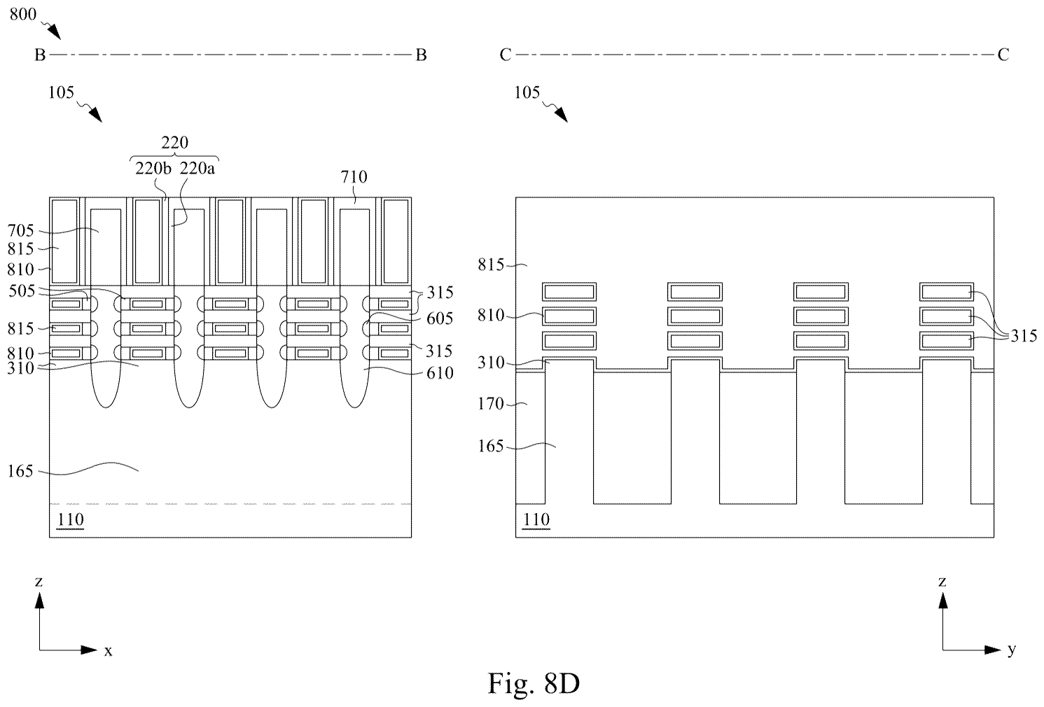

FIGS. 8A-8D are diagrams of an example implementation 800 of a replacement gate process described herein. The replacement gate process is a process in which the dummy gate structures 205 and the remaining portions of the sacrificial dielectric layers 415 are removed from the semiconductor device 105 and replaced with high-k/metal gate structures (e.g., the replacement gate structures) for the nanostructure transistors of the semiconductor device 105. FIGS. 8A-8D are each illustrated from the perspective of the cross-sectional plane B-B and the cross-sectional plane C-C in FIG. 2. In some implementations, the operations described in connection with the example implementation 800 are performed after the operations described in connection with FIGS. 1A-7B.

As shown in the cross-section B-B and in the cross-section C-C in FIG. 8A, a dummy gate removal operation may be performed. The dummy gate removal operation includes removing the dummy gate structures 205 (e.g., the gate electrode layer 210 of the dummy gate structures 205) from the semiconductor device 105. The removal of the dummy gate structures 205 leaves behind openings (or recesses) between the spacer layers 220b. The dummy gate structures 205 may be removed in one or more etch operations. Such etch operations may include a plasma etch technique, a wet chemical etch technique, and/or another type of etch technique.

As shown in the cross-section B-B and in the cross-section C-C in FIG. 8B, the gate dielectric layer 225 may be removed from the semiconductor device 105. Removal of the dummy gate structures 205 and the gate dielectric layer 225 provides access to the underlying sacrificial dielectric layers 415 for a subsequent nanosheet removal process. The gate dielectric layer 225 may be removed in one or more etch operations. Such etch operations may include a plasma etch technique, a wet chemical etch technique, and/or another type of etch technique.

As shown in the cross-section B-B and in the cross-section C-C in FIG. 8C, the nanosheet release process may include performing an etch operation to laterally etch the sacrificial dielectric layers 415 to remove the sacrificial dielectric layers 415 from between vertically adjacent nanostructure channels 315. Removal of the sacrificial dielectric layers 415 leaves behind spaces 805 between vertically adjacent nanostructure channels 315.

As shown in a close-up view in FIG. 8C, the epitaxial regions 605 in the overlap regions 615 protect against etching through the interface between the inner spacers 505 and the nanostructure channels 315 during the nanosheet release process. Additionally and/or alternatively, the sharp inner corners of the inner spacers 505 (which is achieved at least in part by replacing the sacrificial semiconductor layers 120 and the intermixing layers 130 with the sacrificial dielectric layers 415) prevent and/or reduce the likelihood of etching through the interface between the inner spacers 505 and the nanostructure channels 315 during the nanosheet release process. Thus, the sharp inner corners of the inner spacers 505 and/or the etch resistance of the epitaxial regions 605 prevent and/or reduce the likelihood of etching into (and thus, damaging) the source/drain regions 610 during the nanosheet release operation of the replacement gate process.

As shown in the cross-section B-B and in the cross-section C-C in FIG. 8D, a gate dielectric layer 810 may be formed around the nanostructure channels 315. In some implementations, the gate dielectric layer 810 is also formed on the mesa regions 310. A deposition tool may be used to deposit the gate dielectric layer 810 using a PVD technique, an ALD technique, a CVD technique, an oxidation technique, and/or another suitable deposition technique. In some implementations, the gate dielectric layer 810 is a high-k gate dielectric layer that includes one or more high-k materials (e.g., dielectric materials having a dielectric constant greater than silicon dioxide (SiO₂)-dielectric constant of approximately 3.9). Examples include lanthanum oxide (LaₓO_{y} such as La₂O₃), hafnium oxide (HfOₓ such as HfO₂), zirconium oxide (ZrOₓ such as ZrO₂), and/or aluminum oxide (AlₓO_{y} such as Al₂O₃), among other examples. Additionally and/or alternatively, silicon dioxide (SiO₂) and/or another dielectric material may be used instead of a high-k dielectric material. In some implementations, the gate dielectric layer 810 may have a thickness that is included in a range of approximately 0.5 nanometers to approximately 3 nanometers. However, other values for the range are within the scope of the present disclosure.

As further shown in FIG. 8D, a gate structure 815 of the nanostructure transistors of the semiconductor device 105 may be formed over the gate dielectric layer 810. The gate structure 815 may be formed in the spaces 805 previously occupied by the sacrificial dielectric layers 415 such that the gate structure 815 wraps around the nanostructure channels 315 on one or more sides of the nanostructure channels 315. Material of the gate structure 815 may be deposited between vertically adjacent nanostructure channels 315.

The gate structure 815 includes one or more electrically conductive metal materials, such as ruthenium (Ru), tungsten (W), cobalt (Co), copper (Cu), and/or molybdenum (Mo), among other examples. A deposition tool may be used to deposit the gate structure 815 using a CVD technique, a PVD technique, an ALD technique, an electroplating technique, and/or another suitable deposition technique. The gate structure 815 may be deposited in one or more deposition operations. In some implementations, a seed layer is first deposited, and the gate structure 815 is deposited on the seed layer. In some implementations, a planarization tool may be used to planarize the gate structure 815 after the gate structure 815 is deposited.

In some implementations, one or more work function metal layers (not shown) may be deposited on the gate dielectric layer 810, and the gate structure 815 may be deposited on the one or more work function metal layers. A work function metal layer may be included for tuning the work function of the gate structure 815.

In some implementations, the gate structure 815 is a p-type gate structure for a PMOS nanostructure transistor, and a p-type work function metal layer is formed for the gate structure 815. In these implementations, the p-type work function metal layer may include one or more p-type metals, such as tungsten (W), cobalt (Co), titanium nitride (TiN), tungsten nitride (WN), and/or another metal having a work function that is greater than approximately 4.7 eV, among other examples, for tuning the work function of the gate structure 815 such that the work function is adjusted close to the valance band (Ev) of the material of the nanostructure channels 315.

In some implementations, the gate structure 815 is an n-type gate structure for an NMOS nanostructure transistor, and an n-type work function metal layer is formed for the gate structure 815. In these implementations, the n-type work function metal layer may include one or more n-type metals, such as titanium aluminum (TiAl) and/or titanium aluminum carbon (TiAlC), among other examples, for tuning the work function of the gate structure 815 such that the work function is close to the conduction band (Ec) of the material of the nanostructure channels 315.

As indicated above, FIGS. 8A-8D are provided as an example. Other examples may differ from what is described with regard to FIGS. 8A-8D.

FIGS. 9A-9D are diagrams of an example implementation 900 of forming the semiconductor device 105 described herein. As shown in FIG. 9A, in the example implementation 900 the source/drain recess formation process may differ from the source/drain recess formation process illustrated and described in connection with FIG. 3 in that the source/drain recesses 305 are formed to a z-direction depth in the semiconductor device 105 such that the bottoms of the source/drain recesses 305 do not extend downward (e.g., in the z-direction) into the mesa regions 310 below the bottom-most sacrificial semiconductor layer 120. Instead, and as shown in FIG. 9A, the bottoms of the source/drain recesses 305 may be approximately co-planar with the bottom surface of the bottom-most sacrificial semiconductor layer 120, or may be located at a higher vertical (z-direction) height in the semiconductor device 105 than the bottom surface of the bottom-most sacrificial semiconductor layer 120.

The etching of the source/drain recesses 305 may stop at the bottom surface of the bottom-most sacrificial semiconductor layer 120. In some implementations, the bottom surface of the source/drain recesses 305 may be uneven and/or may have a concave or convex cross-sectional profile.

In some implementations, the source/drain recesses 305 may be etched into the mesa regions 310 below the bottom-most sacrificial semiconductor layer 120, and the portions of the source/drain recesses 305 below the bottom-most sacrificial semiconductor layer 120 may be filled in with a buffer layer (e.g., a silicon buffer layer, a boron-doped silicon buffer layer) so that the top surface of the buffer layer is approximately co-planar with the bottom surface of the bottom-most sacrificial semiconductor layer 120, or is located at a higher vertical (z-direction) height in the semiconductor device 105 than the bottom surface of the bottom-most sacrificial semiconductor layer 120. The buffer layer may be formed by epitaxial growth or may be deposited by CVD and/or another suitable deposition technique.

As shown in FIG. 9B, the sacrificial semiconductor layers 120 may be replaced with the sacrificial dielectric layers 415 and the inner spacers 505. The sacrificial semiconductor layers 120 may be replaced with the sacrificial dielectric layers 415 in a similar manner as described in connection with FIGS. 4A-4C, and the inner spacers 505 may be formed in a similar manner as described in connection with FIG. 5.

As shown in FIG. 9C, the source/drain regions 610 are formed in the source/drain recesses 305. The source/drain regions 610 may be formed in a similar manner as described in connection with FIGS. 6A and 6B, except that the non-contiguous epitaxial regions 605 are omitted from the semiconductor device 105 in the example implementation 900. Moreover, the source/drain regions 610 are formed such that the bottoms of the source/drain regions 610 are approximately co-planar with the bottom surface of the bottom-most sacrificial dielectric layer 415, or may be located at a higher vertical (z-direction) height in the semiconductor device 105 than the bottom surface of the bottom-most sacrificial dielectric layer 415. This may reduce the amount and/or likelihood of current leakage from source/drain regions 610, where the current leakage might otherwise occur through the mesa regions 310.

As shown in FIG. 9D, the dielectric layer 705 and the capping layer 710 may be formed in a similar manner as described in connection with FIGS. 7A and 7B. Moreover, the replacement gate process for the semiconductor device 105 may be performed in a similar manner as described in connection with FIGS. 8A-8D to replace the dummy gate structures 205 and the sacrificial dielectric layers 415 with the gate dielectric layer 810 and the gate structure 815.

As indicated above, FIGS. 9A-9D are provided as an example. Other examples may differ from what is described with regard to FIGS. 9A-9D.

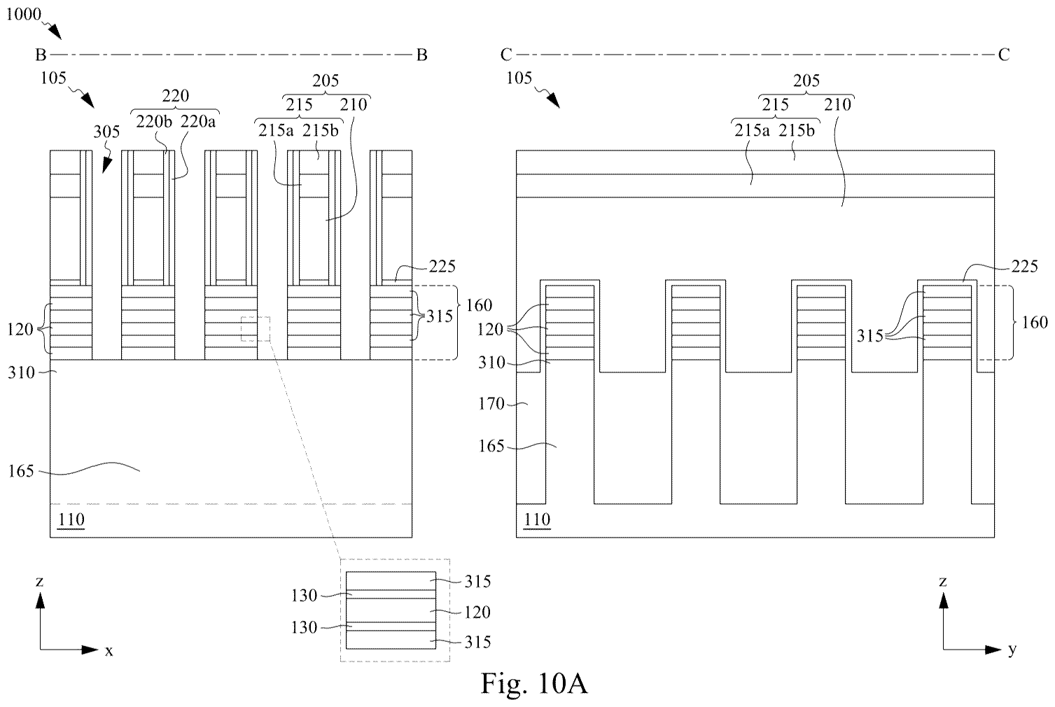

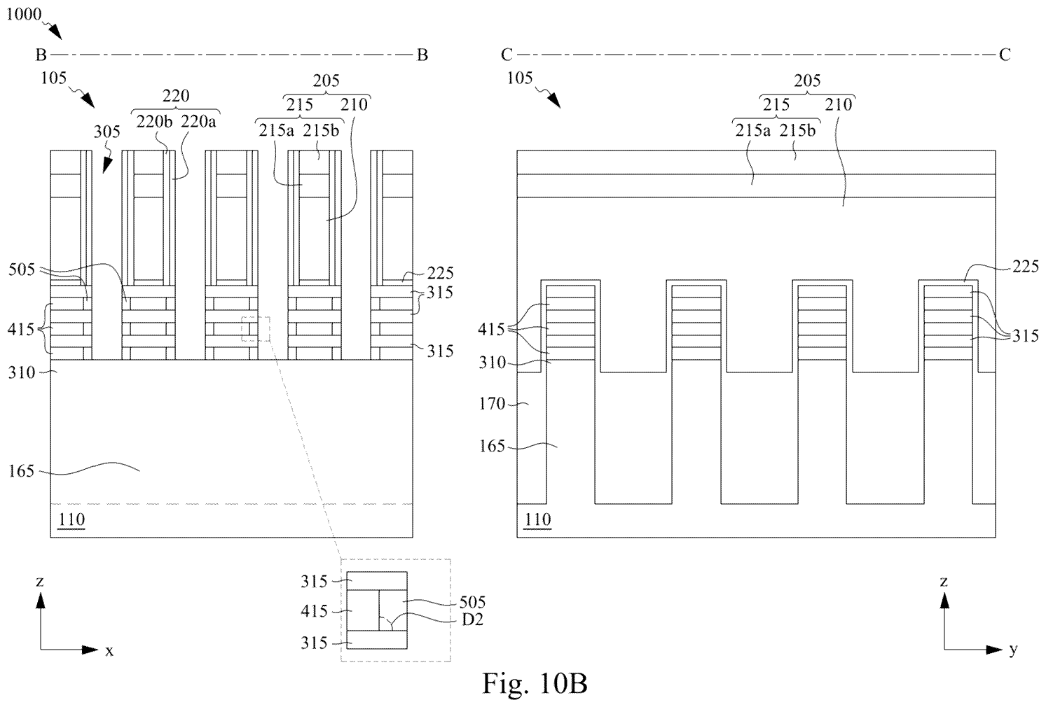

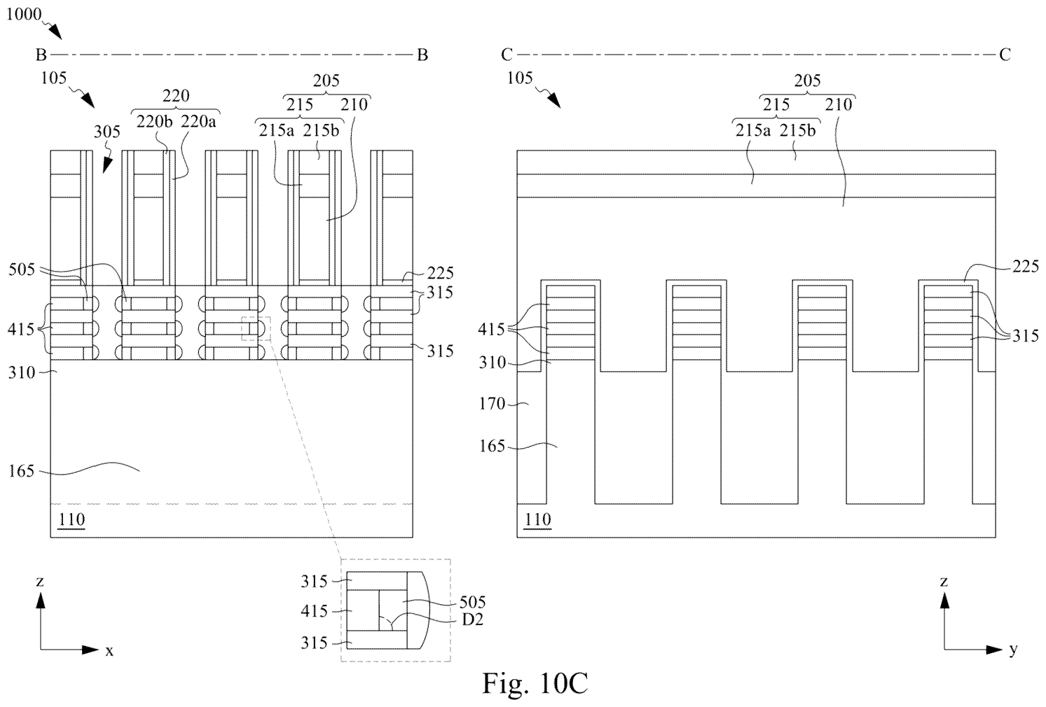

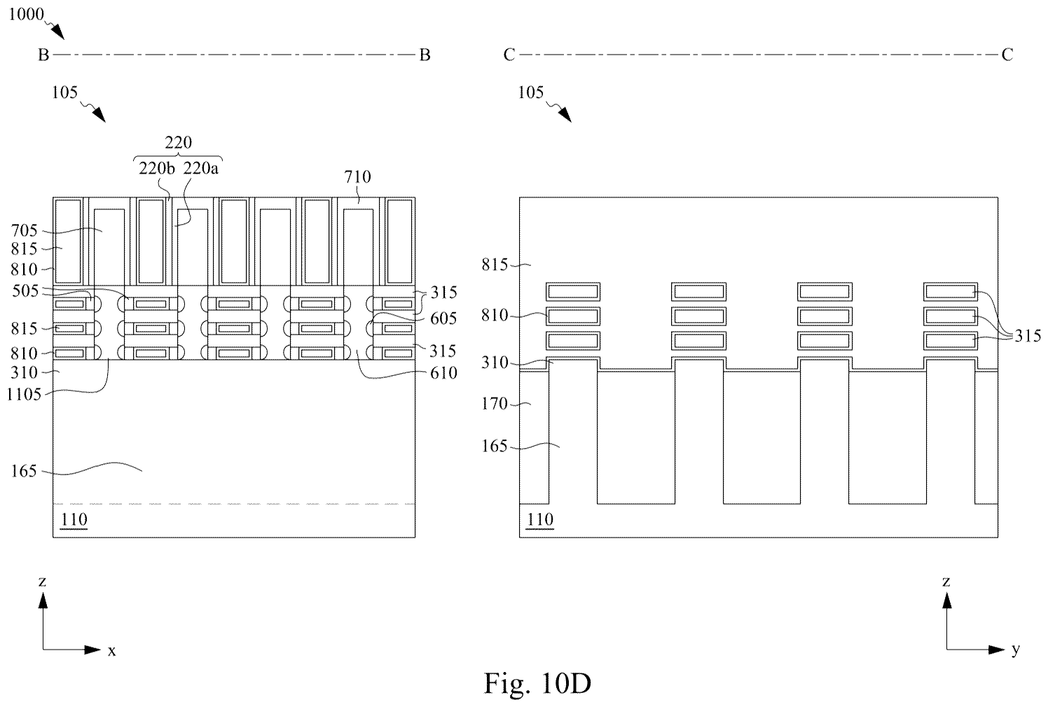

FIGS. 10A-10D are diagrams of an example implementation 1000 of forming the semiconductor device 105 described herein. As shown in FIG. 10A, in the example implementation 1000 the source/drain recess formation process may differ from the source/drain recess formation process illustrated and described in connection with FIG. 3 in that the source/drain recesses 305 are formed to a z-direction depth in the semiconductor device 105 such that the bottoms of the source/drain recesses 305 do not extend downward (e.g., in the z-direction) into the mesa regions 310 below the bottom-most sacrificial semiconductor layer 120. Instead, and as shown in FIG. 10A, the bottoms of the source/drain recesses 305 may be approximately co-planar with the bottom surface of the bottom-most sacrificial semiconductor layer 120, or may be located at a higher vertical (z-direction) height in the semiconductor device 105 than the bottom surface of the bottom-most sacrificial semiconductor layer 120.

The etching of the source/drain recesses 305 may stop at the bottom surface of the bottom-most sacrificial semiconductor layer 120. In some implementations, the bottom surface of the source/drain recesses 305 may be uneven and/or may have a concave or convex cross-sectional profile.

In some implementations, the source/drain recesses 305 may be etched into the mesa regions 310 below the bottom-most sacrificial semiconductor layer 120, and the portions of the source/drain recesses 305 below the bottom-most sacrificial semiconductor layer 120 may be filled in with a buffer layer (e.g., a silicon buffer layer, a boron-doped silicon buffer layer) so that the top surface of the buffer layer is approximately co-planar with the bottom surface of the bottom-most sacrificial semiconductor layer 120, or is located at a higher vertical (z-direction) height in the semiconductor device 105 than the bottom surface of the bottom-most sacrificial semiconductor layer 120. The buffer layer may be formed by epitaxial growth or may be deposited by CVD and/or another suitable deposition technique.

As shown in FIG. 10B, the sacrificial semiconductor layers 120 may be replaced with the sacrificial dielectric layers 415 and the inner spacers 505. The sacrificial semiconductor layers 120 may be replaced with the sacrificial dielectric layers 415 in a similar manner as described in connection with FIGS. 4A-4C, and the inner spacers 505 may be formed in a similar manner as described in connection with FIG. 5.

As shown in FIG. 10C, the non-contiguous epitaxial regions 605 and the source/drain regions 610 are formed in the source/drain recesses 305. The non-contiguous epitaxial regions 605 may be formed on the inner spacers 505, and the source/drain regions 610 may be formed in a similar manner as described in connection with FIGS. 6A and 6B. However, the source/drain regions 610 are formed such that the bottoms of the source/drain regions 610 are approximately co-planar with the bottom surface of the bottom-most sacrificial dielectric layer 415, or may be located at a higher vertical (z-direction) height in the semiconductor device 105 than the bottom surface of the bottom-most sacrificial dielectric layer 415. This may reduce the amount and/or likelihood of current leakage from source/drain regions 610, where the current leakage might otherwise occur through the mesa regions 310.

As shown in FIG. 10D, the dielectric layer 705 and the capping layer 710 may be formed in a similar manner as described in connection with FIGS. 7A and 7B. Moreover, the replacement gate process for the semiconductor device 105 may be performed in a similar manner as described in connection with FIGS. 8A-8D to replace the dummy gate structures 205 and the sacrificial dielectric layers 415 with the gate dielectric layer 810 and the gate structure 815.

As indicated above, FIGS. 10A-10D are provided as an example. Other examples may differ from what is described with regard to FIGS. 10A-10D.

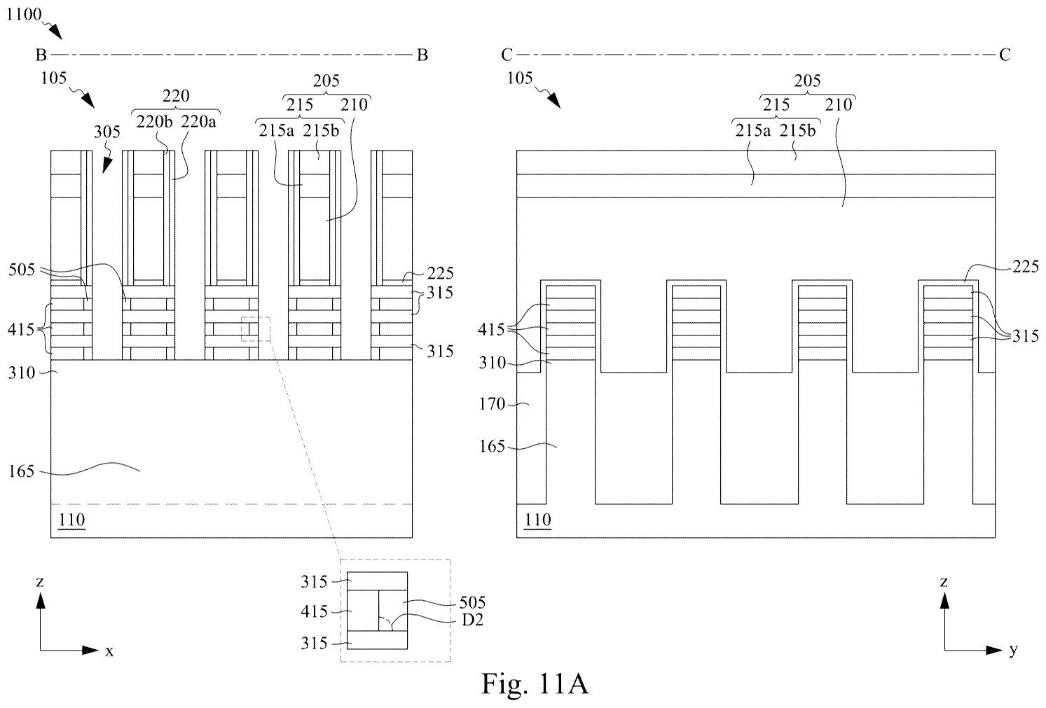

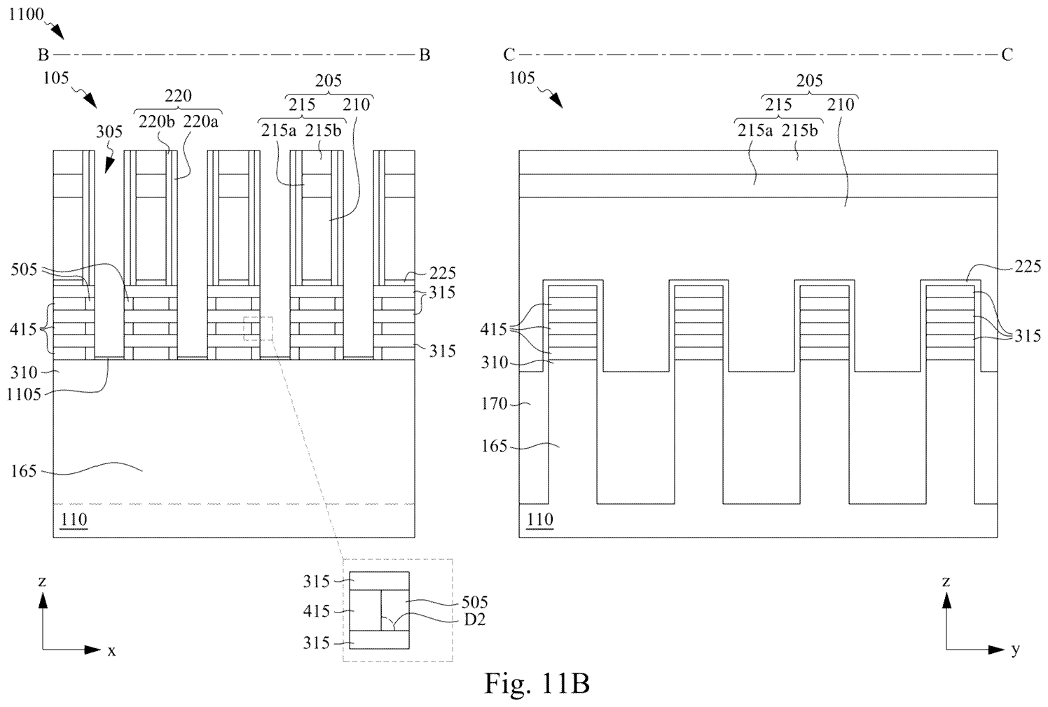

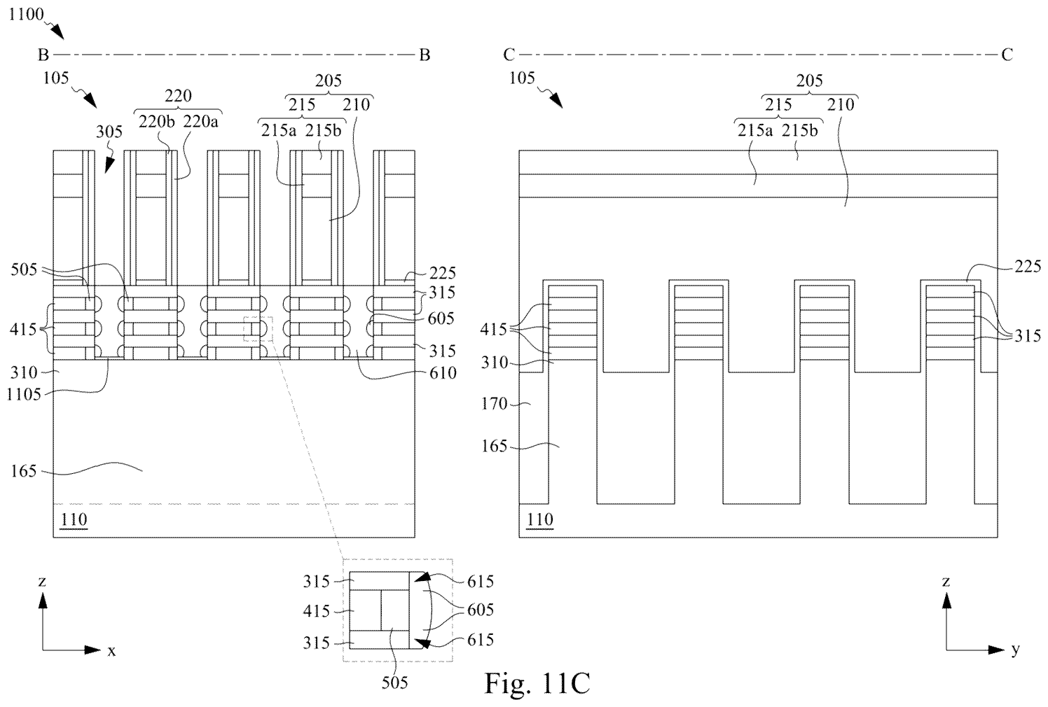

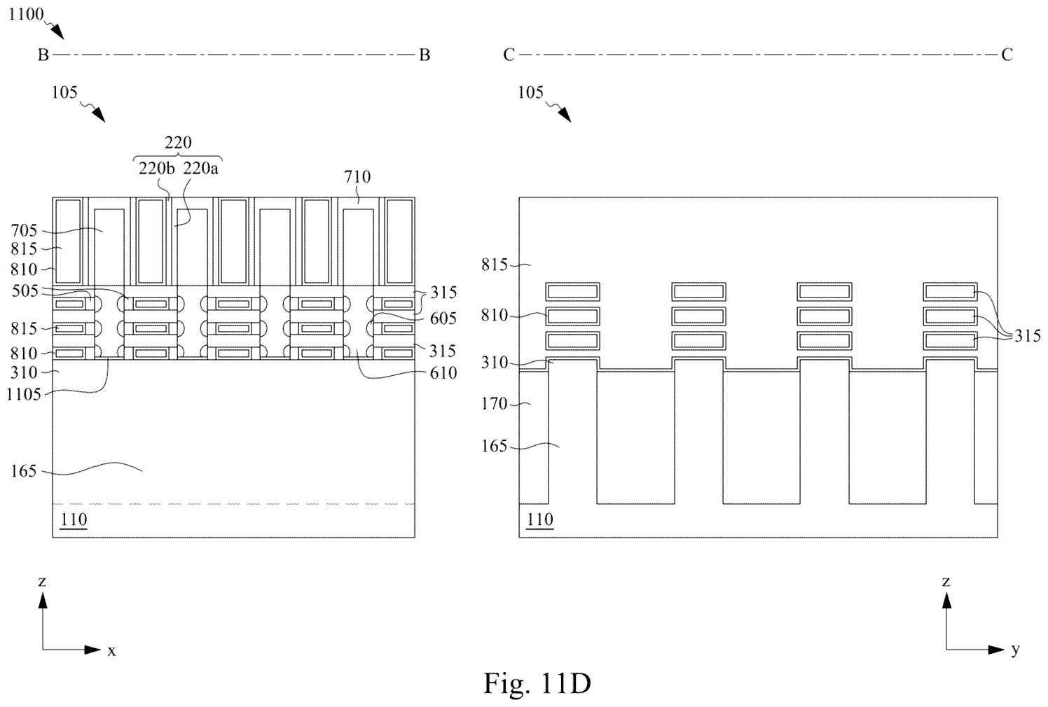

FIGS. 11A-11D are diagrams of an example implementation 1100 of forming the semiconductor device 105 described herein. In the example implementation 1100, isolation spacers 1105 are formed at the bottom of the source/drain recesses 305 to control the formation of the source/drain regions 610 in the source/drain recess 305. In particular, the isolation spacers 1105 define the position of the bottom surface of the source/drain regions 610, which enables the source/drain regions 610 to be formed such that the bottoms of the source/drain regions 610 are approximately co-planar with the bottom surface of the bottom-most sacrificial semiconductor layer 120, or may be located at a higher vertical (z-direction) height in the semiconductor device 105 than the bottom surface of the bottom-most sacrificial dielectric layer 415.

As shown in FIG. 11A, in the example implementation 1100 the source/drain recess formation process may differ from the source/drain recess formation process illustrated and described in connection with FIG. 3 in that the source/drain recesses 305 are formed to a z-direction depth in the semiconductor device 105 such that the bottoms of the source/drain recesses 305 do not extend downward (e.g., in the z-direction) into the mesa regions 310 below the bottom-most sacrificial semiconductor layer 120. Instead, and as shown in FIG. 10A, the bottoms of the source/drain recesses 305 may be approximately co-planar with the bottom surface of the bottom-most sacrificial semiconductor layer 120, or may be located at a higher vertical (z-direction) height in the semiconductor device 105 than the bottom surface of the bottom-most sacrificial semiconductor layer 120.

The etching of the source/drain recesses 305 may stop at the bottom surface of the bottom-most sacrificial semiconductor layer 120. In some implementations, the bottom surface of the source/drain recesses 305 may be uneven and/or may have a concave or convex cross-sectional profile.

In some implementations, the source/drain recesses 305 may be etched into the mesa regions 310 below the bottom-most sacrificial semiconductor layer 120, and the portions of the source/drain recesses 305 below the bottom-most sacrificial semiconductor layer 120 may be filled in with a buffer layer (e.g., a silicon buffer layer, a boron-doped silicon buffer layer) so that the top surface of the buffer layer is approximately co-planar with the bottom surface of the bottom-most sacrificial semiconductor layer 120, or is located at a higher vertical (z-direction) height in the semiconductor device 105 than the bottom surface of the bottom-most sacrificial semiconductor layer 120. The buffer layer may be formed by epitaxial growth or may be deposited by CVD and/or another suitable deposition technique.

As further shown in FIG. 11A, the sacrificial semiconductor layers 120 may be replaced with the sacrificial dielectric layers 415 and the inner spacers 505. The sacrificial semiconductor layers 120 may be replaced with the sacrificial dielectric layers 415 in a similar manner as described in connection with FIGS. 4A-4C, and the inner spacers 505 may be formed in a similar manner as described in connection with FIG. 5.

As shown in FIG. 11B, the isolation spacers 1105 are formed at the bottoms of the source/drain recesses 305. The isolation spacers 1105 may be formed such that the top surfaces of the isolation spacers 1105 are approximately co-planar with the bottom surface of the bottom-most sacrificial dielectric layer 415, or are located at a higher vertical (z-direction) height in the semiconductor device 105 than the bottom surface of the bottom-most sacrificial dielectric layer 415.

In some implementations, the isolation spacers 1105 include a dielectric material such as a silicon oxide SiOₓ) and/or a silicon nitride (SiₓN_{y}), among other examples. In these implementations, a deposition tool may be used to deposit the isolation spacers 1105 using a PVD technique, an ALD technique, a CVD technique, and/or another suitable deposition technique. In some implementations, the isolation spacers 1105 include semiconductor material (e.g., silicon (Si), germanium (Ge), silicon germanium (SiGe)) or doped semiconductor material (e.g., a semiconductor material doped with p-type dopants, a semiconductor material doped with n-type dopants, a semiconductor material doped with carbon (C)). In these implementations, a deposition tool may be used to deposit the isolation spacers 1105 using an epitaxial growth technique.

In some implementations, the isolation spacers 1105 are formed to a z-direction thickness that is less than the z-direction thickness of the inner spacers 505. In some implementations, the isolation spacers 1105 are formed to a z-direction thickness that is included in a range of approximately 1 nanometer to approximately 3 nanometers. However, other values and ranges for the z-direction thickness of the isolation spacers 1105 are within the scope of the present disclosure.

As shown in FIG. 11C, the non-contiguous epitaxial regions 605 and the source/drain regions 610 are formed in the source/drain recesses 305. The non-contiguous epitaxial regions 605 may be formed on the inner spacers 505, and the source/drain regions 610 may be formed in a similar manner as described in connection with FIGS. 6A and 6B. However, the source/drain regions 610 are formed on the isolation spacers 1105 in the source/drain recesses 305. The isolation spacers 1105 ensure that the bottoms of the source/drain regions 610 are approximately co-planar with the bottom surface of the bottom-most sacrificial dielectric layer 415, or are located at a higher vertical (z-direction) height in the semiconductor device 105 than the bottom surface of the bottom-most sacrificial dielectric layer 415. This may reduce the amount and/or likelihood of current leakage from source/drain regions 610, where the current leakage might otherwise occur through the mesa regions 310.

As shown in FIG. 11D, the dielectric layer 705 and the capping layer 710 may be formed in a similar manner as described in connection with FIGS. 7A and 7B. Moreover, the replacement gate process for the semiconductor device 105 may be performed in a similar manner as described in connection with FIGS. 8A-8D to replace the dummy gate structures 205 and the sacrificial dielectric layers 415 with the gate dielectric layer 810 and the gate structure 815.

As indicated above, FIGS. 11A-11D are provided as an example. Other examples may differ from what is described with regard to FIGS. 11A-11D.

FIGS. 12A-12C are diagrams of an example implementation 1200 of forming the semiconductor device 105 described herein. In the example implementation 1200, the non-contiguous epitaxial regions 605 are formed primarily on the ends of the nanostructure channels 315 that are exposed through the source/drain recesses 305 as opposed to being formed primarily on the inner spacers 505 as illustrated in the example implementation 600 in FIGS. 6A and 6B.

As shown in FIG. 12A, in the example implementation 1200 the source/drain recess formation process may differ from the source/drain recess formation process illustrated and described in connection with FIG. 3 in that the source/drain recesses 305 are formed to a z-direction depth in the semiconductor device 105 such that the bottoms of the source/drain recesses 305 do not extend downward (e.g., in the z-direction) into the mesa regions 310 below the bottom-most sacrificial semiconductor layer 120. Instead, and as shown in FIG. 12A, the bottoms of the source/drain recesses 305 may be approximately co-planar with the bottom surface of the bottom-most sacrificial semiconductor layer 120, or may be located at a higher vertical (z-direction) height in the semiconductor device 105 than the bottom surface of the bottom-most sacrificial semiconductor layer 120.

The etching of the source/drain recesses 305 may stop at the bottom surface of the bottom-most sacrificial semiconductor layer 120. In some implementations, the bottom surface of the source/drain recesses 305 may be uneven and/or may have a concave or convex cross-sectional profile.

In some implementations, the source/drain recesses 305 may be etched into the mesa regions 310 below the bottom-most sacrificial semiconductor layer 120, and the portions of the source/drain recesses 305 below the bottom-most sacrificial semiconductor layer 120 may be filled in with a buffer layer (e.g., a silicon buffer layer, a boron-doped silicon buffer layer) so that the top surface of the buffer layer is approximately co-planar with the bottom surface of the bottom-most sacrificial semiconductor layer 120, or is located at a higher vertical (z-direction) height in the semiconductor device 105 than the bottom surface of the bottom-most sacrificial semiconductor layer 120. The buffer layer may be formed by epitaxial growth or may be deposited by CVD and/or another suitable deposition technique.

As further shown in FIG. 12A, the sacrificial semiconductor layers 120 may be replaced with the sacrificial dielectric layers 415 and the inner spacers 505. The sacrificial semiconductor layers 120 may be replaced with the sacrificial dielectric layers 415 in a similar manner as described in connection with FIGS. 4A-4C, and the inner spacers 505 may be formed in a similar manner as described in connection with FIG. 5.

As shown in FIG. 12C, the non-contiguous epitaxial regions 605 and the source/drain regions 610 are formed in the source/drain recesses 305. The non-contiguous epitaxial regions 605 and the source/drain regions 610 may be formed in a similar manner as described in connection with FIGS. 6A and 6B. However, the source/drain regions 610 are formed such that the bottoms of the source/drain regions 610 are approximately co-planar with the bottom surface of the bottom-most sacrificial dielectric layer 415, or are located at a higher vertical (z-direction) height in the semiconductor device 105 than the bottom surface of the bottom-most sacrificial dielectric layer 415. This may reduce the amount and/or likelihood of current leakage from source/drain regions 610, where the current leakage might otherwise occur through the mesa regions 310.

Moreover, and as shown in close-up views in FIG. 12B, the non-contiguous epitaxial regions 605 are formed primarily on the ends of the nanostructure channels 315 that are exposed through the source/drain recesses 305, as opposed to being formed primarily on the inner spacers 505 as illustrated in the example implementation 600 in FIGS. 6A and 6B. In the example implementation 1200, an epitaxial region 605 may continuously span across an end of a nanostructure channel 315 and portions of the inner spacers 505 on vertically opposing sides of the nanostructure channel 315. Thus, the overlap regions 615 occur where the vertical ends of the epitaxial region 605 partially overlap the portions of the inner spacers 505 on vertically opposing sides of the nanostructure channel 315.

Different epitaxial process parameters may be used to achieve the location of formation of the non-contiguous epitaxial regions 605 in the example implementation 1200, compared to the epitaxial process parameters that are used to achieve the location of formation of the non-contiguous epitaxial regions 605 in the example implementation 600 in FIGS. 6A and 6B. For example, different chamber pressures, different deposition temperatures, different gas flow rates, different annealing temperatures, and/or different growth rates, among other examples, may be used to achieve the location of formation of the non-contiguous epitaxial regions 605 in the example implementation 1200 compared to the location of formation of the non-contiguous epitaxial regions 605 in the example implementation 600 in FIGS. 6A and 6B.

As shown in FIG. 12C, the dielectric layer 705 and the capping layer 710 may be formed in a similar manner as described in connection with FIGS. 7A and 7B. Moreover, the replacement gate process for the semiconductor device 105 may be performed in a similar manner as described in connection with FIGS. 8A-8D to replace the dummy gate structures 205 and the sacrificial dielectric layers 415 with the gate dielectric layer 810 and the gate structure 815.

As indicated above, FIGS. 12A-12C are provided as an example. Other examples may differ from what is described with regard to FIGS. 12A-12C.

FIGS. 13A-13C are diagrams of an example implementation 1300 of forming the semiconductor device 105 described herein. In the example implementation 1300, the non-contiguous epitaxial regions 605 are formed so that each epitaxial region 605 spans across less than the entirety of a nanostructure channel 315 and less than entirety of an adjoining inner spacers 505.

As shown in FIG. 13A, in the example implementation 1300 the source/drain recess formation process may differ from the source/drain recess formation process illustrated and described in connection with FIG. 3 in that the source/drain recesses 305 are formed to a z-direction depth in the semiconductor device 105 such that the bottoms of the source/drain recesses 305 do not extend downward (e.g., in the z-direction) into the mesa regions 310 below the bottom-most sacrificial semiconductor layer 120. Instead, and as shown in FIG. 13A, the bottoms of the source/drain recesses 305 may be approximately co-planar with the bottom surface of the bottom-most sacrificial semiconductor layer 120, or may be located at a higher vertical (z-direction) height in the semiconductor device 105 than the bottom surface of the bottom-most sacrificial semiconductor layer 120.

The etching of the source/drain recesses 305 may stop at the bottom surface of the bottom-most sacrificial semiconductor layer 120. In some implementations, the bottom surface of the source/drain recesses 305 may be uneven and/or may have a concave or convex cross-sectional profile.

In some implementations, the source/drain recesses 305 may be etched into the mesa regions 310 below the bottom-most sacrificial semiconductor layer 120, and the portions of the source/drain recesses 305 below the bottom-most sacrificial semiconductor layer 120 may be filled in with a buffer layer (e.g., a silicon buffer layer, a boron-doped silicon buffer layer) so that the top surface of the buffer layer is approximately co-planar with the bottom surface of the bottom-most sacrificial semiconductor layer 120, or is located at a higher vertical (z-direction) height in the semiconductor device 105 than the bottom surface of the bottom-most sacrificial semiconductor layer 120. The buffer layer may be formed by epitaxial growth or may be deposited by CVD and/or another suitable deposition technique.

As further shown in FIG. 13A, the sacrificial semiconductor layers 120 may be replaced with the sacrificial dielectric layers 415 and the inner spacers 505. The sacrificial semiconductor layers 120 may be replaced with the sacrificial dielectric layers 415 in a similar manner as described in connection with FIGS. 4A-4C, and the inner spacers 505 may be formed in a similar manner as described in connection with FIG. 5.

As shown in FIG. 13C, the non-contiguous epitaxial regions 605 and the source/drain regions 610 are formed in the source/drain recesses 305. The non-contiguous epitaxial regions 605 and the source/drain regions 610 may be formed in a similar manner as described in connection with FIGS. 6A and 6B. However, the source/drain regions 610 are formed such that the bottoms of the source/drain regions 610 are approximately co-planar with the bottom surface of the bottom-most sacrificial dielectric layer 415, or are located at a higher vertical (z-direction) height in the semiconductor device 105 than the bottom surface of the bottom-most sacrificial dielectric layer 415. This may reduce the amount and/or likelihood of current leakage from source/drain regions 610, where the current leakage might otherwise occur through the mesa regions 310.

Moreover, and as shown in close-up views in FIG. 13B, the non-contiguous epitaxial regions 605 are formed so that each epitaxial region 605 spans across less than the entirety of a nanostructure channel 315 and less than entirety of an adjoining inner spacers 505, as opposed to being formed primarily on the inner spacers 505 as illustrated in the example implementation 600 in FIGS. 6A and 6B. In the example implementation 1300, an epitaxial region 605 may continuously span across only a portion of a single nanostructure channel 315, and only a portion of an adjoining inner spacer 505. Thus, epitaxial regions 605 are included over the interfaces of adjoining nanostructure channels and inner spacers 505.

Different epitaxial process parameters may be used to achieve the location of formation of the non-contiguous epitaxial regions 605 in the example implementation 1300, compared to the epitaxial process parameters that are used to achieve the location of formation of the non-contiguous epitaxial regions 605 in the example implementation 600 in FIGS. 6A and 6B. For example, different chamber pressures, different deposition temperatures, different gas flow rates, different annealing temperatures, and/or different growth rates, among other examples may be used to achieve the location of formation of the non-contiguous epitaxial regions 605 in the example implementation 1300 compared to the location of formation of the non-contiguous epitaxial regions 605 in the example implementation 600 in FIGS. 6A and 6B.

As shown in FIG. 13C, the dielectric layer 705 and the capping layer 710 may be formed in a similar manner as described in connection with FIGS. 7A and 7B. Moreover, the replacement gate process for the semiconductor device 105 may be performed in a similar manner as described in connection with FIGS. 8A-8D to replace the dummy gate structures 205 and the sacrificial dielectric layers 415 with the gate dielectric layer 810 and the gate structure 815.

As indicated above, FIGS. 13A-13C are provided as an example. Other examples may differ from what is described with regard to FIGS. 13A-13D.

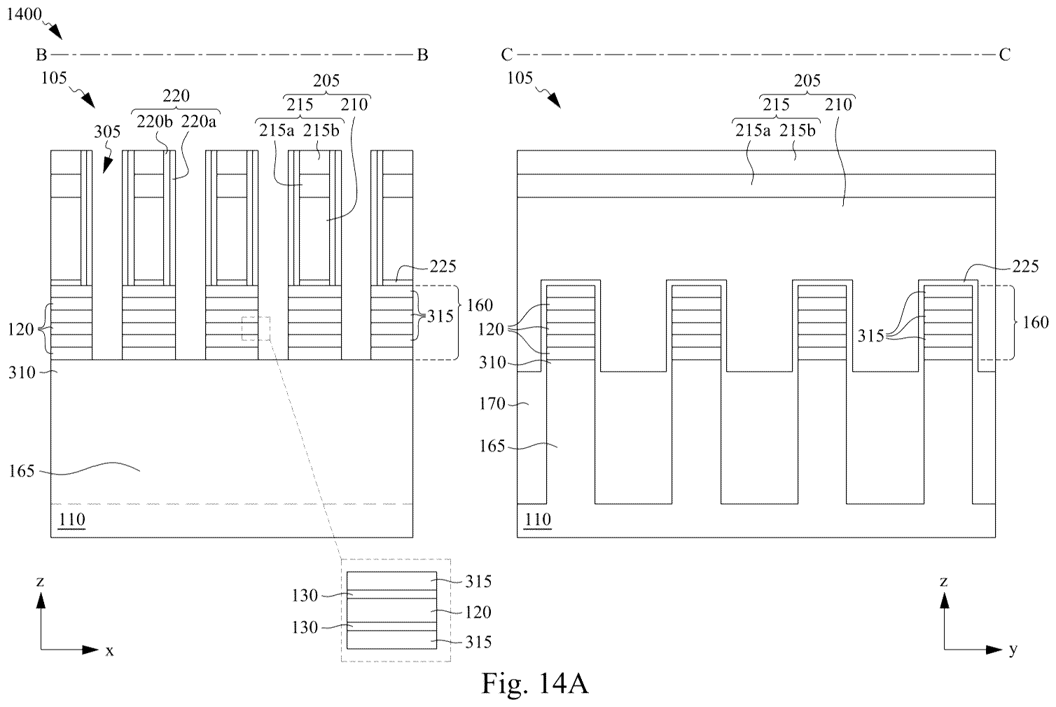

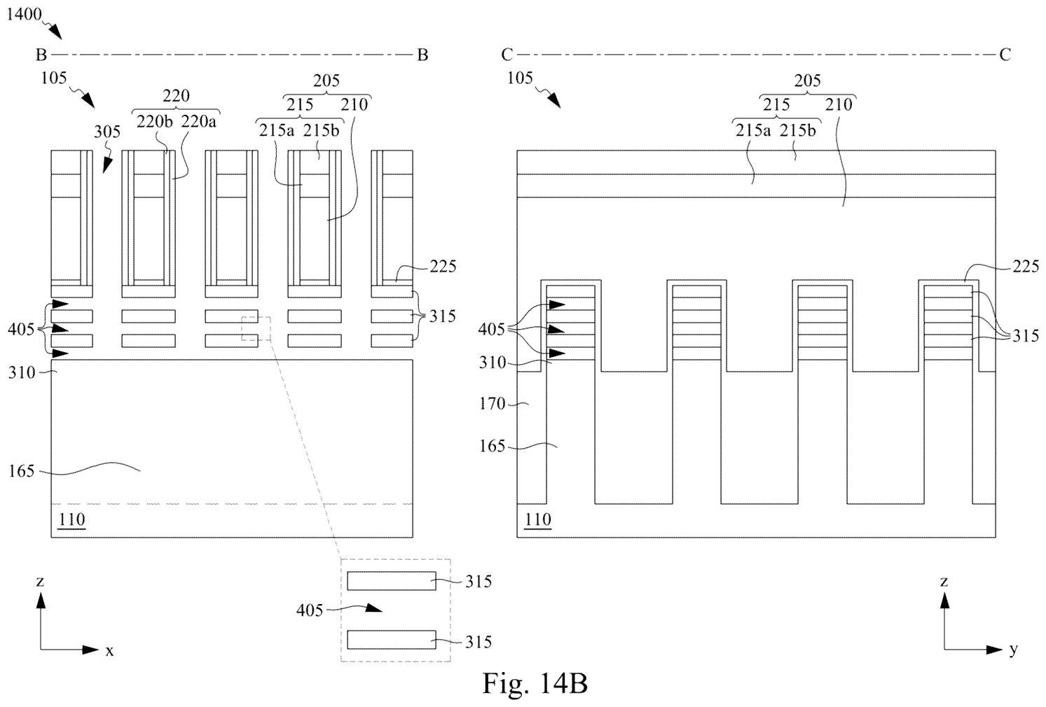

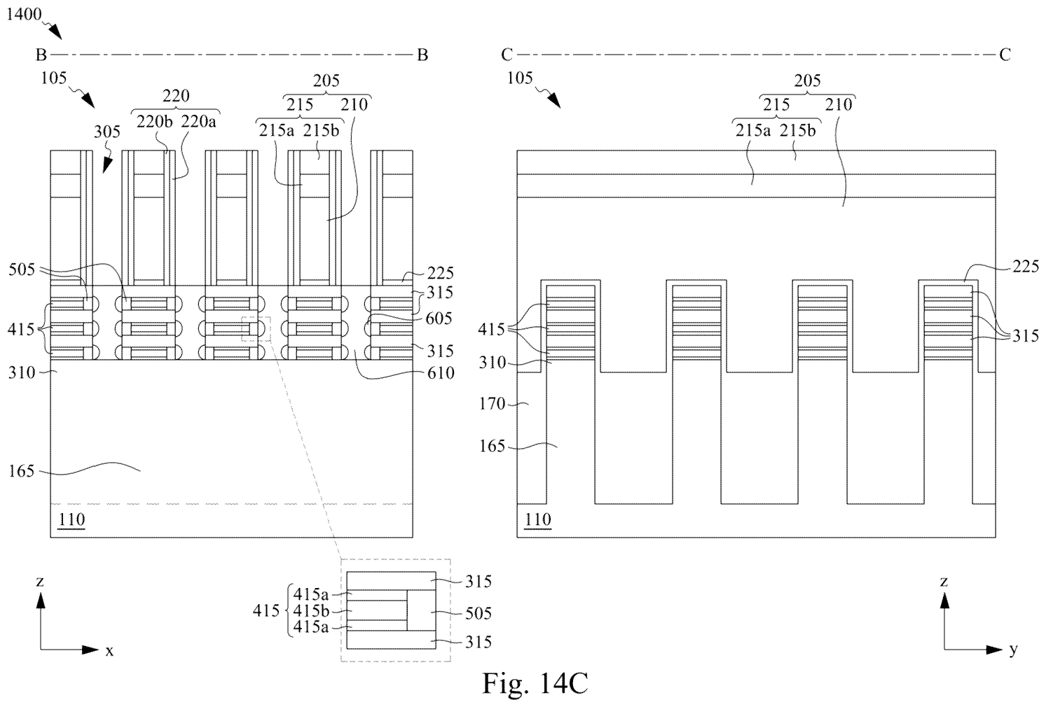

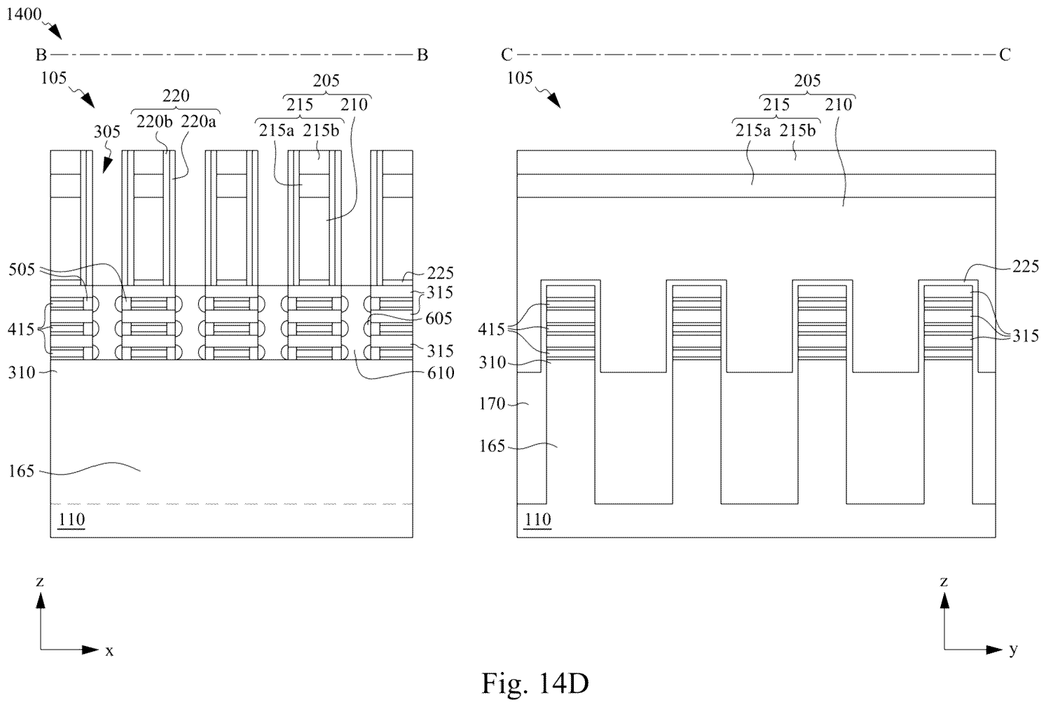

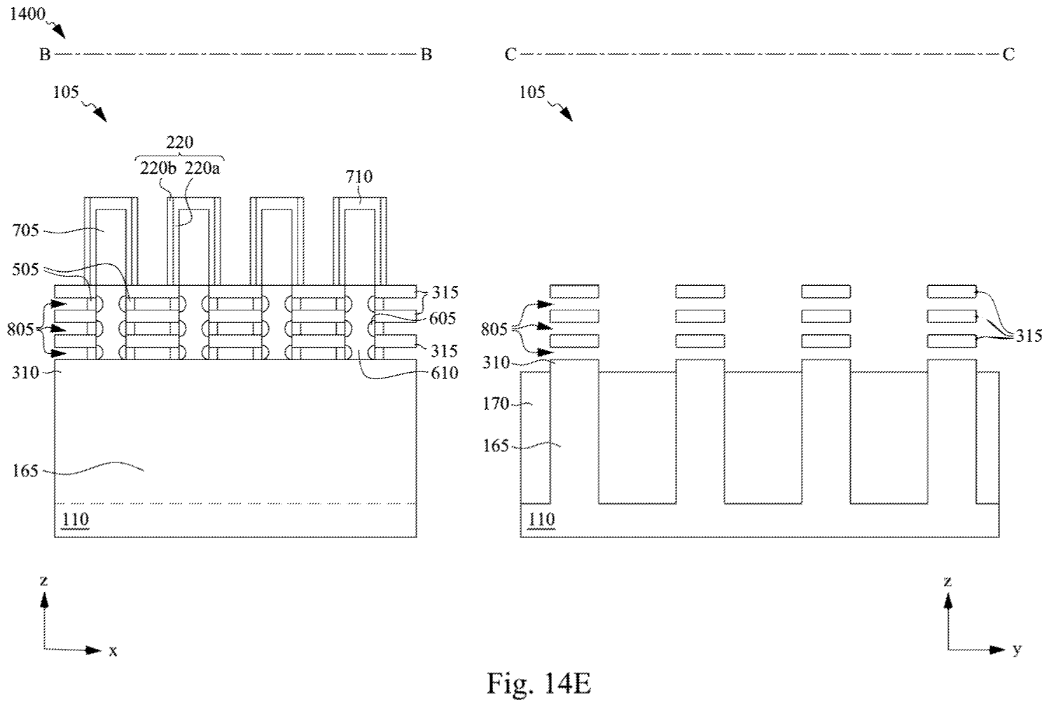

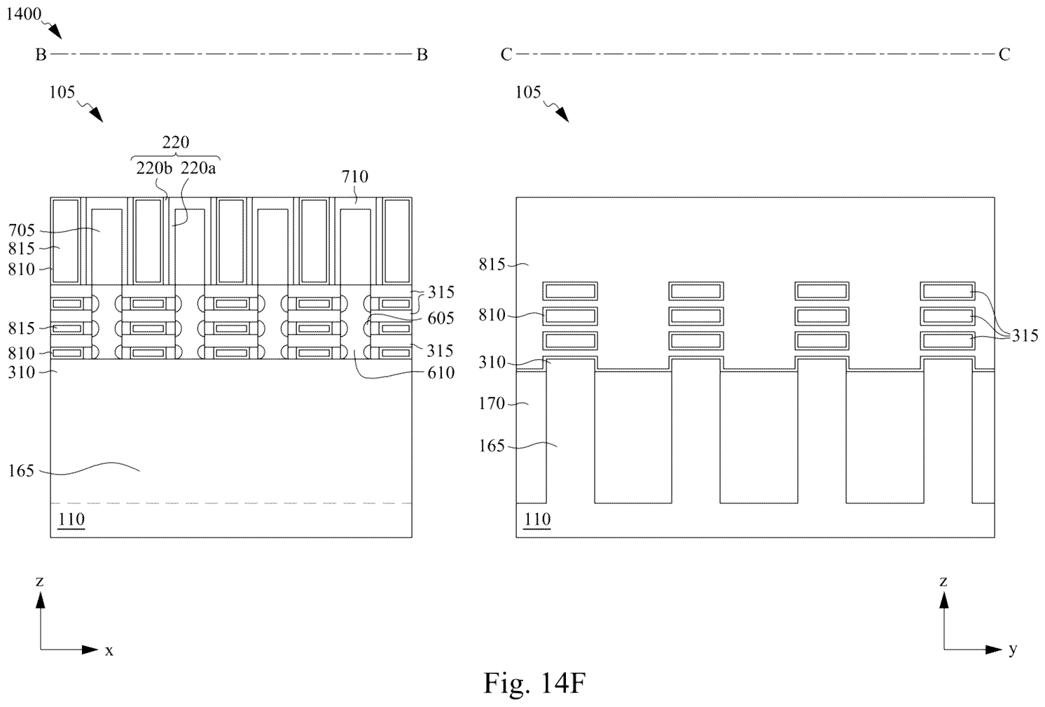

FIGS. 14A-14F are diagrams of an example implementation 1400 of forming the semiconductor device 105 described herein. The example implementation 1400 includes an example of forming a multiple-layer structure for the sacrificial dielectric layers 415.

As shown in FIG. 14A, in the example implementation 1400 the source/drain recess formation process may differ from the source/drain recess formation process illustrated and described in connection with FIG. 3 in that the source/drain recesses 305 are formed to a z-direction depth in the semiconductor device 105 such that the bottoms of the source/drain recesses 305 do not extend downward (e.g., in the z-direction) into the mesa regions 310 below the bottom-most sacrificial semiconductor layer 120. Instead, and as shown in FIG. 14A, the bottoms of the source/drain recesses 305 may be approximately co-planar with the bottom surface of the bottom-most sacrificial semiconductor layer 120, or may be located at a higher vertical (z-direction) height in the semiconductor device 105 than the bottom surface of the bottom-most sacrificial semiconductor layer 120.

As shown in FIG. 14B, the sacrificial semiconductor layers 120 may be removed in a similar manner as described in connection with FIGS. 4A-4C.

As shown in FIG. 14C, the sacrificial semiconductor layers 120 may be replaced with the sacrificial dielectric layers 415 in a similar manner as described in connection with FIGS. 4A-4C, except that a multiple-layer structure is formed for the sacrificial dielectric layers 415. The multiple-layer structure includes a core 415b and a liner 415a. The liner 415a may be included around the core 415b between the core 415b and the nanostructure channels 315. The liner 415a may have a lesser thickness than the core 415b. For example, the liner 415a may have a thickness of approximately 1 nanometer, whereas the thickness of the core 415b may be greater than 1 nanometer. However, other values are within the scope of the present disclosure.

The core 415b may include a low elasticity material such as a low-density silicon oxide (SiOₓ), a porous silicon oxide, another porous extreme low-k dielectric material, and/or another material having a Young's modulus that is less than the Young's modulus of the nanostructure channels 315. The core 415b may be deposited as a flowable film (e.g., as described above in connection with FIGS. 4A-4C) to achieve a low density for the core 415b. The liner 415a includes a high-density dielectric material such as silicon nitride (SiₓN_{y}) or another high-k dielectric material, a high-density silicon oxide (SiOₓ), and/or another high-density material. The liner 415a may be deposited by ALD to achieve a high density and a nanometer thickness for the liner 415a.

The core 415b may provide the low elasticity for the sacrificial dielectric layers 415, which enables the sacrificial dielectric layers 415 to resist absorbing stresses induced in the nanostructure channels 315. The liner 415a provides a higher elasticity than the core 415b and reduces the likelihood of deformation of the nanostructure channels 315. The nanometer thickness of the liner 415a enables the liner 415a to support the nanostructure channels 315 without decreasing (or with minimal decrease to) the stresses exerted on the nanostructure channels 315.

As further shown in FIG. 14C, the inner spacers 505 may be formed in cavities 420 in the ends of the sacrificial dielectric layers 415. The inner spacers 505 may be formed in a similar manner as described in connection with FIG. 5, except that the inner surfaces of the inner spacers 505 are formed on the core 415b and on the liner 415a of the sacrificial dielectric layers 415.

As shown in FIG. 14D, the non-contiguous epitaxial regions 605 and the source/drain regions 610 may be formed in the source/drain recesses 305 after formation of the inner spacers 505. In some implementations, the non-contiguous epitaxial regions 605 are formed on the inner spacers 505 in a similar manner as described in connection with FIGS. 6A and 6B. In some implementations, the non-contiguous epitaxial regions 605 are formed on the ends of the nanostructure channels 315 in a similar manner as described in connection with FIGS. 12A-12C. In some implementations, the non-contiguous epitaxial regions 605 are formed on the ends of the nanostructure channels 315 and on the inner spacers 505 in a similar manner as described in connection with FIGS. 13A-13C. In some implementations, the non-contiguous epitaxial regions 605 are omitted, in a similar manner as described in connection with FIGS. 9A-9D. In some implementations, the source/drain regions 610 may be formed in a similar manner as described in connection with FIGS. 9A-9D.

As shown in FIG. 14E, the dielectric layer 705 and the capping layer 710 may be formed in a similar manner as described in connection with FIGS. 7A and 7B. As further shown in FIG. 14E, the dummy gate structures 205 and the sacrificial dielectric layers 415 may be removed in a similar manner as described in connection with FIGS. 8A-8D, except that the core 415b and the liner 415a of the sacrificial dielectric layers 415 are removed. In some implementations, the core 415b and the liner 415a of the sacrificial dielectric layers 415 are removed together (e.g., in the same etch operation) from the semiconductor device 105. In some implementations, the core 415b is removed in a first etch operation, and the liner 415a is removed in a second etch operation after the core 415b is removed.

As shown in FIG. 14F, the dummy gate structures 205 and the sacrificial dielectric layers 415 may be replaced with the gate dielectric layer 810 and the gate structure 815 in a similar manner as described in connection with FIGS. 8A-8D.

As indicated above, FIGS. 14A-14F are provided as an example. Other examples may differ from what is described with regard to FIGS. 14A-14F.

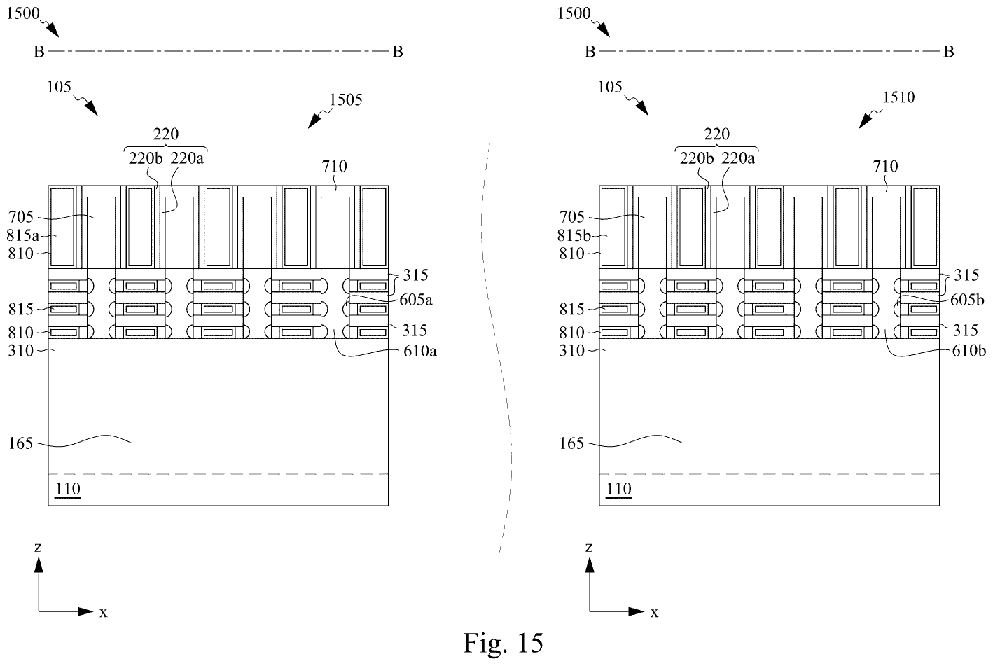

FIG. 15 is a diagram of an example implementation 1500 of the semiconductor device 105 described herein. In the example implementation 1500, the semiconductor device 105 includes one or more PMOS nanostructure transistors 1505 and/or one or more NMOS nanostructure transistors 1510. In some implementations, the semiconductor device 105 includes only PMOS nanostructure transistors 1505. In some implementations, the semiconductor device includes only NMOS nanostructure transistors 1510.

In some implementations, the PMOS nanostructure transistors 1505 may include a p-type gate structure 815a that includes one or more p-type work function metals. In some implementations, the PMOS nanostructure transistors 1505 may include p-type source/drain regions 610a that include a semiconductor material (e.g., silicon (Si), germanium (Ge), silicon germanium (SiGe)), that is doped with one or more p-type dopants such as boron (B) and/or germanium (Ge), among other examples. The dopants of the p-type source/drain regions 610a may be included to increase the electrical performance of the p-type source/drain regions 610a and/or to induce compressive stresses in the nanostructure channels 315 of the PMOS nanostructure transistors 1505.

The non-contiguous epitaxial regions 605a of the PMOS nanostructure transistors 1505 may include a greater dopant concentration of p-type dopants, such as B, than the dopant concentration of p-type dopants included in the p-type source/drain regions 610a. The higher dopant concentration of p-type dopants enables the non-contiguous epitaxial regions 605a to withstand etching during the replacement gate process for the PMOS nanostructure transistors 1505, which enables the non-contiguous epitaxial regions 605a to protect the p-type source/drain regions 610a from being etched during the replacement gate process. In some implementations, the non-contiguous epitaxial regions 605a of the PMOS nanostructure transistors 1505 may include less Ge dopants. The lower dopant concentration of Ge enables the non-contiguous epitaxial regions 605a to better withstand etching during the replacement gate process for the PMOS nanostructure transistors 1505, which enables the non-contiguous epitaxial regions 605a to protect the p-type source/drain regions 610a from being etched during the replacement gate process. In some implementations, Ge doping is omitted from the non-contiguous epitaxial regions 605a of the PMOS nanostructure transistors 1505.

In some implementations, the NMOS nanostructure transistors 1510 may include an n-type gate structure 815b that includes one or more n-type work function metals. In some implementations, the NMOS nanostructure transistors 1510 may include n-type source/drain regions 610b that include a semiconductor material (e.g., silicon (Si), germanium (Ge), silicon germanium (SiGe)), that is doped with one or more n-type dopants such as arsenic (As) and/or phosphorous (P), among other examples. Moreover, the n-type source/drain regions 610b may be doped with carbon (C). The n-type dopants of the n-type source/drain regions 610b may be included to increase the electrical performance of the n-type source/drain regions 610b, and the carbon doping may be included to induce tensile stresses in the nanostructure channels 315 of the NMOS nanostructure transistors 1510. Additionally and/or alternatively, the n-type source/drain regions 610b may include a semiconductor alloy such as silicon phosphorous (SiP) and/or silicon arsenic (SiAs), among other examples.

The non-contiguous epitaxial regions 605b of the NMOS nanostructure transistors 1510 may include a greater dopant concentration of carbon dopants than the dopant concentration of carbon dopants included in the n-type source/drain regions 610b. The higher dopant concentration of carbon dopants enables the non-contiguous epitaxial regions 605b to withstand etching during the replacement gate process for the NMOS nanostructure transistors 1510, which enables the non-contiguous epitaxial regions 605b to protect the n-type source/drain regions 610b from being etched during the replacement gate process. In some implementations, carbon doping is omitted from the non-contiguous epitaxial regions 605b of the NMOS nanostructure transistors 1510.

In some implementations, the non-contiguous epitaxial regions 605b of the NMOS nanostructure transistors 1510 may include less arsenic dopants and/or less phosphorus dopants. The lower dopant concentration of arsenic dopants and/or phosphorus dopants enables the non-contiguous epitaxial regions 605b to better withstand etching during the replacement gate process for the NMOS nanostructure transistors 1510, which enables the non-contiguous epitaxial regions 605b to protect the n-type source/drain regions 610b from being etched during the replacement gate process.

As indicated above, FIG. 15 is provided as an example. Other examples may differ from what is described with regard to FIG. 15.

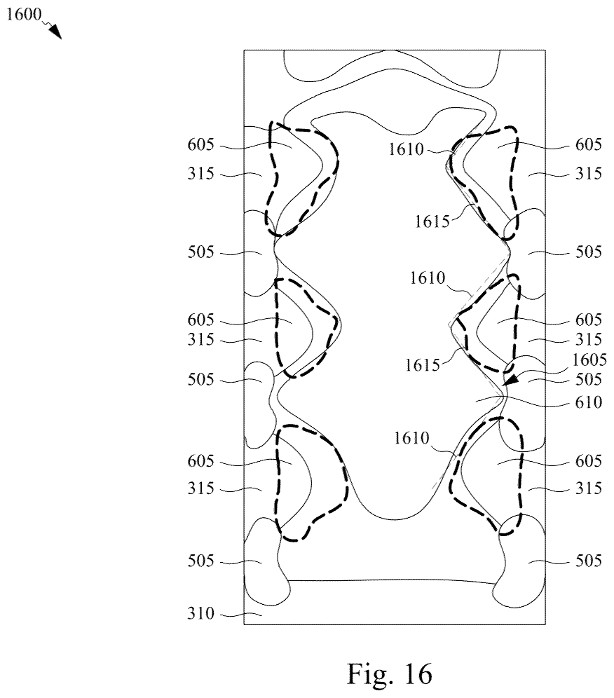

FIG. 16 is a diagram of an example implementation 1600 of the semiconductor device 105 described herein. As shown in FIG. 16, the non-contiguous epitaxial regions 605 have approximately triangular cross-sectional profiles. The triangular cross-sectional profiles of the non-contiguous epitaxial regions 605 may result in a source/drain region 610 having sidewalls 1605 with an approximate zig-zag profile. For example, a sidewall 1605 may include a plurality of segments 1610 and a plurality of segments 1615, where the segments 1610 and 1615 are arranged along the sidewall 1605 in an alternating manner. The segments 1610 may be angled in a first direction, and the segments 1615 may be angled in a second direction. In some implementations, the first direction and the second direction are opposing (or mirrored) directions.

In other implementations, the non-contiguous epitaxial regions 605 may have approximately half-circle cross-sectional profiles or approximately semi-circle cross-sectional profiles. In some implementations, the non-contiguous epitaxial regions 605 may have amorphous cross-sectional profiles.

In some implementations, in an electron microscope image (e.g., in a transmission electron microscopy (TEM) image), the greater dopant concentration in the non-contiguous epitaxial regions 605 compared to the source/drain regions 610 of the semiconductor device 105 may result in the non-contiguous epitaxial regions 605 appearing darker in the microscope image relative to the source/drain regions 610. Thus, the interface between the non-contiguous epitaxial regions 605 and the source/drain regions 610 can be seen in the microscope image.

As indicated above, FIG. 16 is provided as an example. Other examples may differ from what is described with regard to FIG. 16.

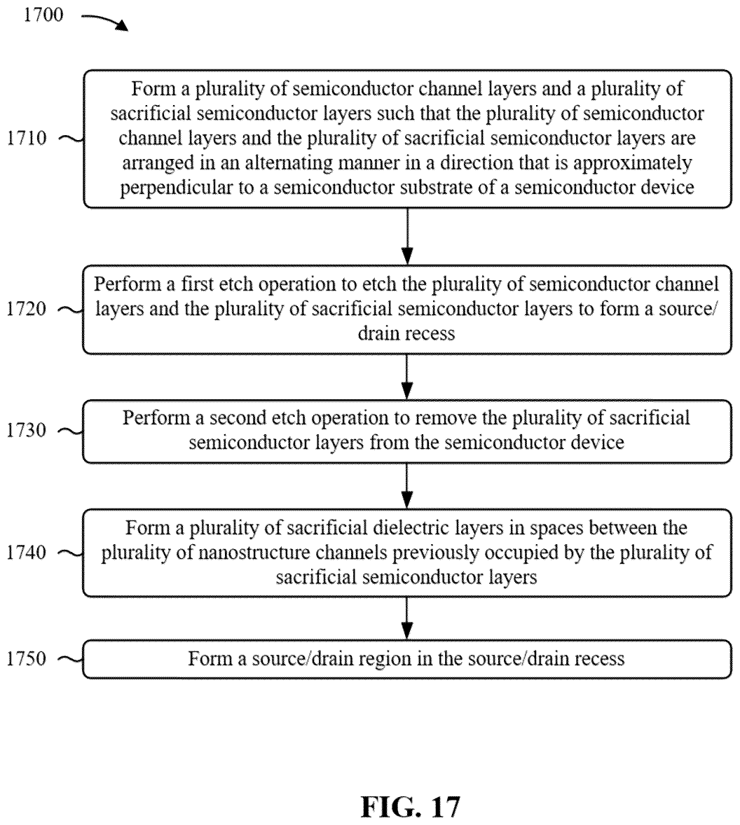

FIG. 17 is a flowchart of an example process 1700 associated with forming a semiconductor device described herein. In some implementations, one or more process blocks of FIG. 17 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 17, process 1700 may include forming a plurality of semiconductor channel layers and a plurality of sacrificial semiconductor layers such that the plurality of semiconductor channel layers and the plurality of sacrificial semiconductor layers are arranged in an alternating manner in a direction that is approximately perpendicular to a semiconductor substrate of a semiconductor device (block 1710). For example, one or more semiconductor processing tools may be used to form a plurality of semiconductor channel layers (e.g., semiconductor channel layers 125) and a plurality of sacrificial semiconductor layers (e.g., sacrificial semiconductor layers 120) such that the plurality of semiconductor channel layers and the plurality of sacrificial semiconductor layers are arranged in an alternating manner in a direction (e.g., z-direction) that is approximately perpendicular to a semiconductor substrate (e.g., a semiconductor substrate 110) of a semiconductor device (e.g., a semiconductor device 105), as described herein.

As further shown in FIG. 17, process 1700 may include performing a first etch operation to etch the plurality of semiconductor channel layers and the plurality of sacrificial semiconductor layers to form a source/drain recess (block 1720). For example, one or more semiconductor processing tools may be used to perform a first etch operation to etch the plurality of semiconductor channel layers and the plurality of sacrificial semiconductor layers to form a source/drain recess (e.g., a source/drain recess 305), as described herein. In some implementations, the source/drain recess defines a plurality of nanostructure channels (e.g., nanostructure channels 315) that are arranged in the direction that is approximately perpendicular to the semiconductor substrate. In some implementations, the plurality of nanostructure channels and the plurality of sacrificial semiconductor layers are arranged in an alternating manner in the direction that is approximately perpendicular to the semiconductor substrate.

As further shown in FIG. 17, process 1700 may include performing a second etch operation to remove the plurality of sacrificial semiconductor layers from the semiconductor device (block 1730). For example, one or more semiconductor processing tools may be used to perform a second etch operation to remove the plurality of sacrificial semiconductor layers from the semiconductor device, as described herein.

As further shown in FIG. 17, process 1700 may include forming a plurality of sacrificial dielectric layers in spaces between the plurality of nanostructure channels previously occupied by the plurality of sacrificial semiconductor layers (block 1740). For example, one or more semiconductor processing tools may be used to form a plurality of sacrificial dielectric layers (e.g., sacrificial dielectric layers 415) in spaces (e.g., spaces 405) between the plurality of nanostructure channels previously occupied by the plurality of sacrificial semiconductor layers, as described herein.

As further shown in FIG. 17, process 1700 may include forming a source/drain region in the source/drain recess (block 1750). For example, one or more semiconductor processing tools may be used to form a source/drain region (e.g., a source/drain region 610, a p-type source/drain region 610a, an n-type source/drain region 610b) in the source/drain recess, as described herein.

Process 1700 may include additional implementations, such as any single implementation or any combination of implementations described below and/or in connection with one or more other processes described elsewhere herein.

In a first implementation, performing the second etch operation to remove the plurality of sacrificial semiconductor layers comprises performing a second etch operation to remove the plurality of sacrificial semiconductor layers through the source/drain recess.

In a second implementation, alone or in combination with the first implementation, forming the plurality of sacrificial dielectric layers includes forming a dielectric layer (e.g., a dielectric layer 410) on sidewalls of the source/drain recess and in the spaces between the plurality of nanostructure channels previously occupied by the plurality of sacrificial semiconductor layers, and performing a third etch operation to trim the dielectric layer such that portions of the dielectric layer remain in the spaces between the plurality of nanostructure channels previously occupied by the plurality of sacrificial semiconductor layers as the plurality of sacrificial dielectric layers.

In a third implementation, alone or in combination with one or more of the first and second implementations, a Young's modulus of a dielectric material of the plurality of sacrificial dielectric layers is less than a Young's modulus of a semiconductor material of the plurality of sacrificial semiconductor layers.

In a fourth implementation, alone or in combination with one or more of the first through third implementations, a Young's modulus of a dielectric material of the plurality of sacrificial dielectric layers is less than a Young's modulus of a semiconductor material of the plurality of nanostructure channels.

In a fifth implementation, alone or in combination with one or more of the first through fourth implementations, the plurality of sacrificial dielectric layers comprise a porous silicon oxide (SiOₓ) material.

In a sixth implementation, alone or in combination with one or more of the first through fifth implementations, forming the plurality of sacrificial dielectric layers comprises depositing a liner (e.g., a liner 415a) of the plurality of sacrificial dielectric layers by ALD, and depositing a porous silicon oxide (SiOₓ) core (e.g., a core 415b) of the plurality of sacrificial dielectric layers as a flowable film.

Although FIG. 17 shows example blocks of process 1700, in some implementations, process 1700 includes additional blocks, fewer blocks, different blocks, or differently arranged blocks than those depicted in FIG. 17. Additionally, or alternatively, two or more of the blocks of process 1700 may be performed in parallel.

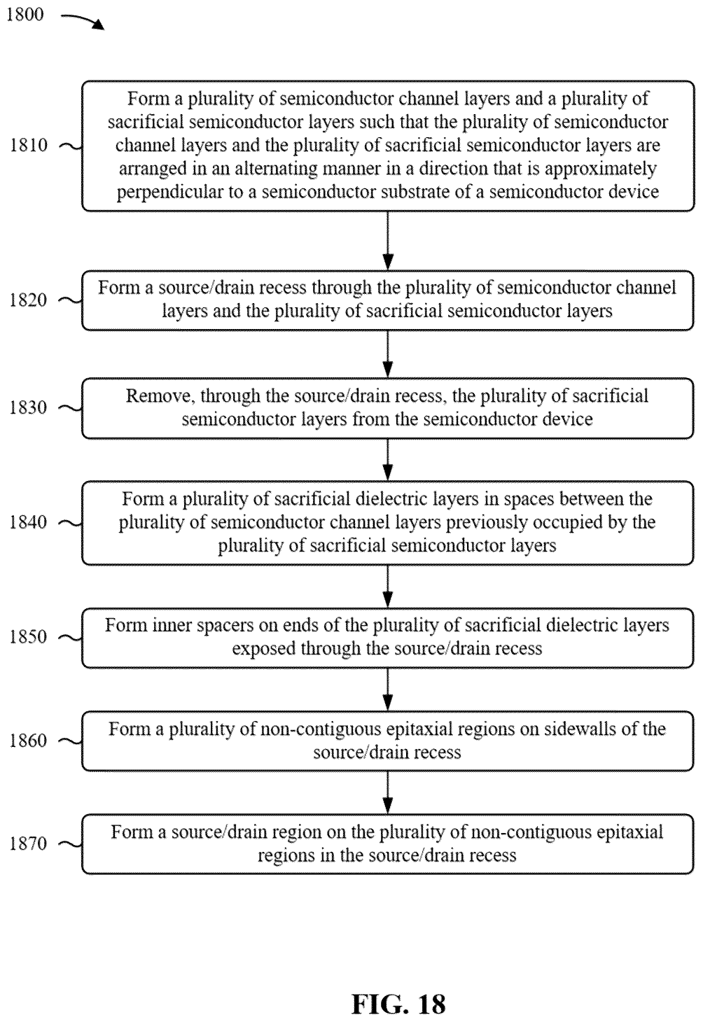

FIG. 18 is a flowchart of an example process 1800 associated with forming a semiconductor device described herein. In some implementations, one or more process blocks of FIG. 18 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 18, process 1800 may include forming a plurality of semiconductor channel layers and a plurality of sacrificial semiconductor layers such that the plurality of semiconductor channel layers and the plurality of sacrificial semiconductor layers are arranged in an alternating manner in a direction that is approximately perpendicular to a semiconductor substrate of a semiconductor device (block 1810). For example, one or more semiconductor processing tools may be used to form a plurality of semiconductor channel layers (e.g., semiconductor channel layers 125) and a plurality of sacrificial semiconductor layers (e.g., sacrificial semiconductor layers 120) such that the plurality of semiconductor channel layers and the plurality of sacrificial semiconductor layers are arranged in an alternating manner in a direction (e.g., a z-direction) that is approximately perpendicular to a semiconductor substrate (e.g., a semiconductor substrate 110) of a semiconductor device (e.g., a semiconductor device 105), as described herein.

As further shown in FIG. 18, process 1800 may include forming a source/drain recess through the plurality of semiconductor channel layers and the plurality of sacrificial semiconductor layers (block 1820). For example, one or more semiconductor processing tools may be used to form a source/drain recess (e.g., a source/drain recess 305) through the plurality of semiconductor channel layers and the plurality of sacrificial semiconductor layers, as described herein.

As further shown in FIG. 18, process 1800 may include removing, through the source/drain recess, the plurality of sacrificial semiconductor layers from the semiconductor device (block 1830). For example, one or more semiconductor processing tools may be used to remove, through the source/drain recess, the plurality of sacrificial semiconductor layers from the semiconductor device, as described herein.

As further shown in FIG. 18, process 1800 may include forming a plurality of sacrificial dielectric layers in spaces between the plurality of semiconductor channel layers previously occupied by the plurality of sacrificial semiconductor layers (block 1840). For example, one or more semiconductor processing tools may be used to form a plurality of sacrificial dielectric layers (e.g., sacrificial dielectric layers 415) in spaces (e.g., spaces 405) between the plurality of semiconductor channel layers previously occupied by the plurality of sacrificial semiconductor layers, as described herein.

As further shown in FIG. 18, process 1800 may include forming inner spacers on ends of the plurality of sacrificial dielectric layers exposed through the source/drain recess (block 1850). For example, one or more semiconductor processing tools may be used to form inner spacers (e.g., inner spacers 505) on ends of the plurality of sacrificial dielectric layers exposed through the source/drain recess, as described herein.

As further shown in FIG. 18, process 1800 may include forming a plurality of non-contiguous epitaxial regions on sidewalls of the source/drain recess (block 1860). For example, one or more semiconductor processing tools may be used to form a plurality of non-contiguous epitaxial regions (e.g., non-contiguous epitaxial regions 605) on sidewalls of the source/drain recess, as described herein.

As further shown in FIG. 18, process 1800 may include forming a source/drain region on the plurality of non-contiguous epitaxial regions in the source/drain recess (block 1870). For example, one or more semiconductor processing tools may be used to form a source/drain region (e.g., a source/drain region 610, a p-type source/drain region 610a, an n-type source/drain region 610b) on the plurality of non-contiguous epitaxial regions in the source/drain recess, as described herein.

Process 1800 may include additional implementations, such as any single implementation or any combination of implementations described below and/or in connection with one or more other processes described elsewhere herein.

In a first implementation, forming the plurality of non-contiguous epitaxial regions includes forming the plurality of non-contiguous epitaxial regions on the inner spacers.

In a second implementation, alone or in combination with the first implementation, forming the plurality of non-contiguous epitaxial regions includes forming the plurality of non-contiguous epitaxial regions on ends of the semiconductor channel layers exposed in the source/drain recess.

In a third implementation, alone or in combination with one or more of the first and second implementations, process 1800 includes forming a bottom isolation spacer (e.g., an isolation spacer 1105) at a bottom of the source/drain recess, and forming the source/drain region on the bottom isolation spacer in the source/drain recess.

In a fourth implementation, alone or in combination with one or more of the first through third implementations, a top surface of the bottom isolation spacer is higher in the semiconductor device than bottom-most inner spacers of the inner spacers in the source/drain recess.

In a fifth implementation, alone or in combination with one or more of the first through fourth implementations, the source/drain region is included in a p-type transistor structure (e.g., a PMOS nanostructure transistor 1505) of the semiconductor device, and the plurality of non-contiguous epitaxial regions include a semiconductor material doped with a p-type dopant, such as B.

In a sixth implementation, alone or in combination with one or more of the first through fifth implementations, the source/drain region is included in an n-type transistor structure (e.g., an NMOS nanostructure transistor 1510) of the semiconductor device, and the plurality of non-contiguous epitaxial regions comprise a semiconductor material doped with carbon (C).

Although FIG. 18 shows example blocks of process 1800, in some implementations, process 1800 includes additional blocks, fewer blocks, different blocks, or differently arranged blocks than those depicted in FIG. 18. Additionally, or alternatively, two or more of the blocks of process 1800 may be performed in parallel.

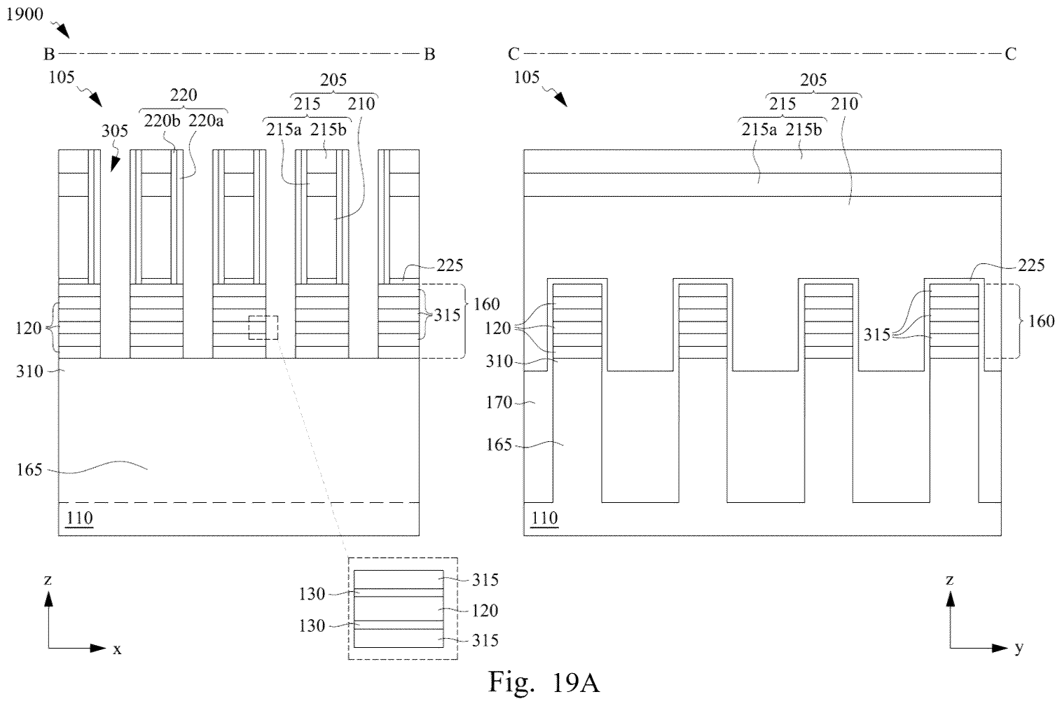

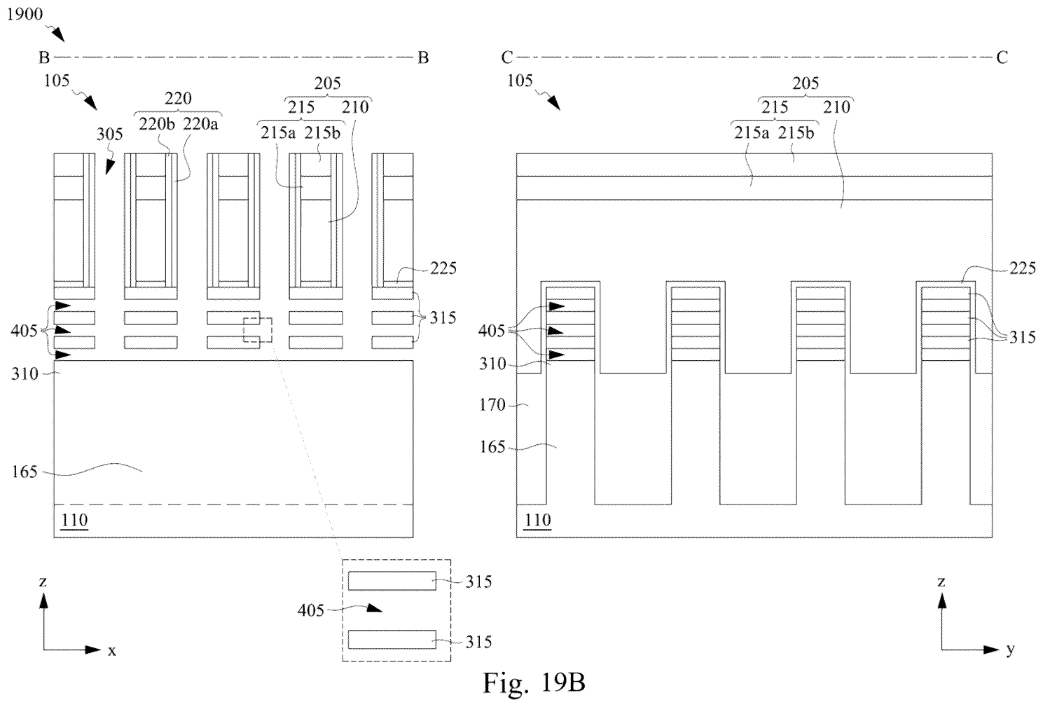

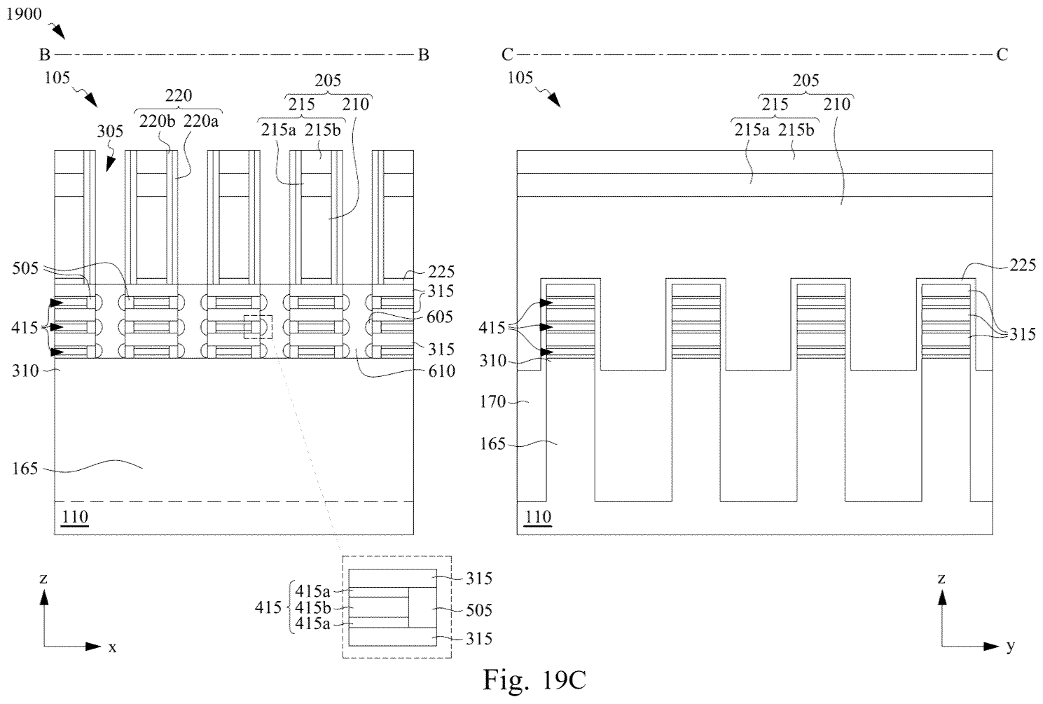

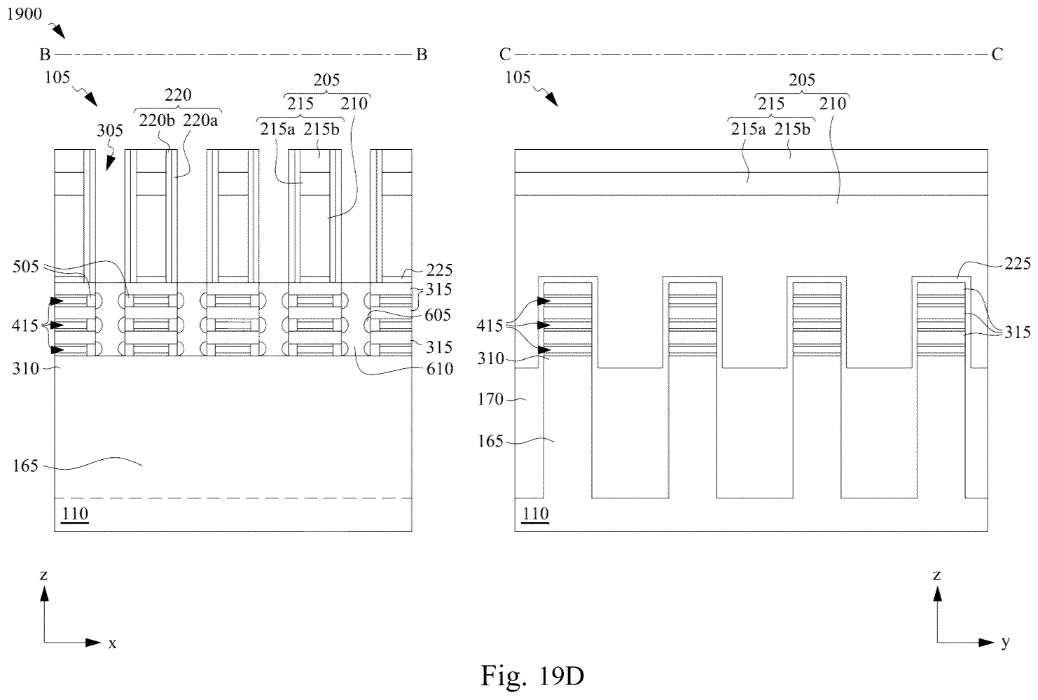

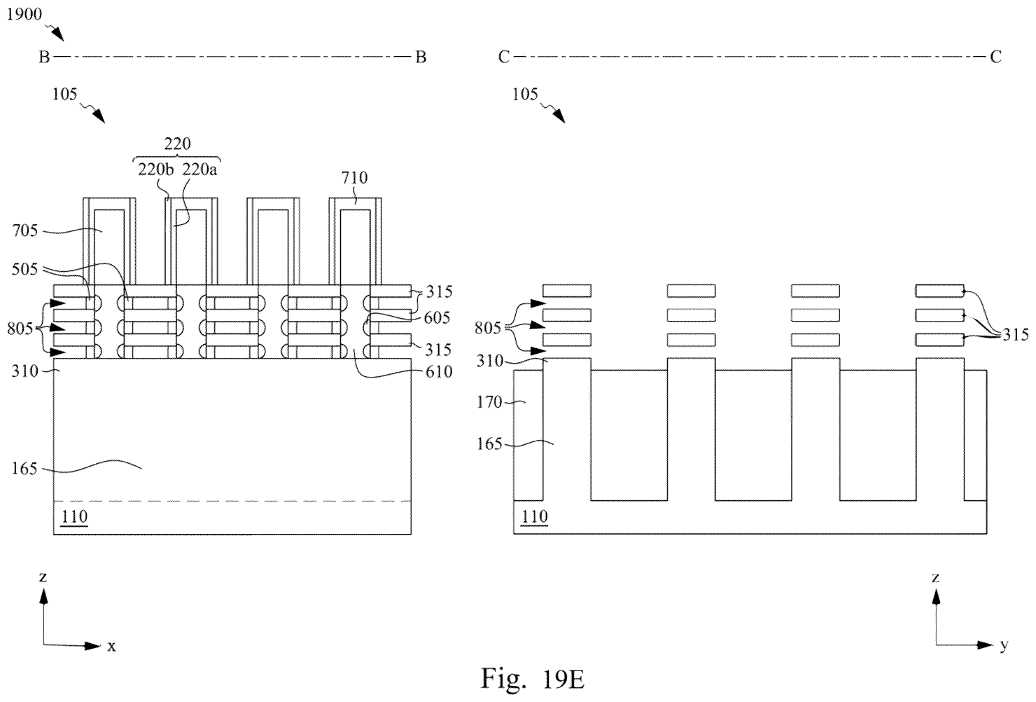

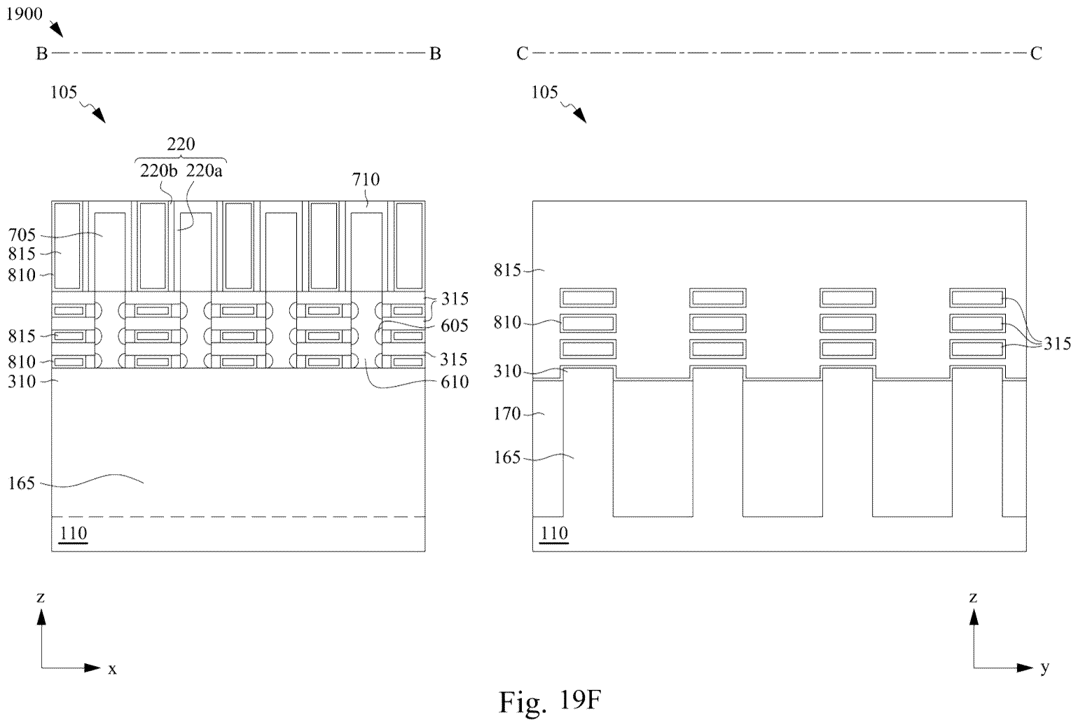

FIGS. 19A-19F are diagrams of an example implementation 1900 of forming the semiconductor device 105 described herein. The example implementation 1900 includes an example of forming a multiple-layer structure for the sacrificial dielectric layers 415. The example implementation 1900 is similar to the example 1400 illustrated in FIGS. 14A-14F, except that the core 415b of the sacrificial dielectric layers 415 is implemented as air spacers. Thus, the dielectric constant of the core 415b of the sacrificial dielectric layers 415 may have a dielectric constant of approximately 1.0.

As indicated above, FIGS. 19A-19F are provided as an example. Other examples may differ from what is described with regard to FIGS. 19A-19F.

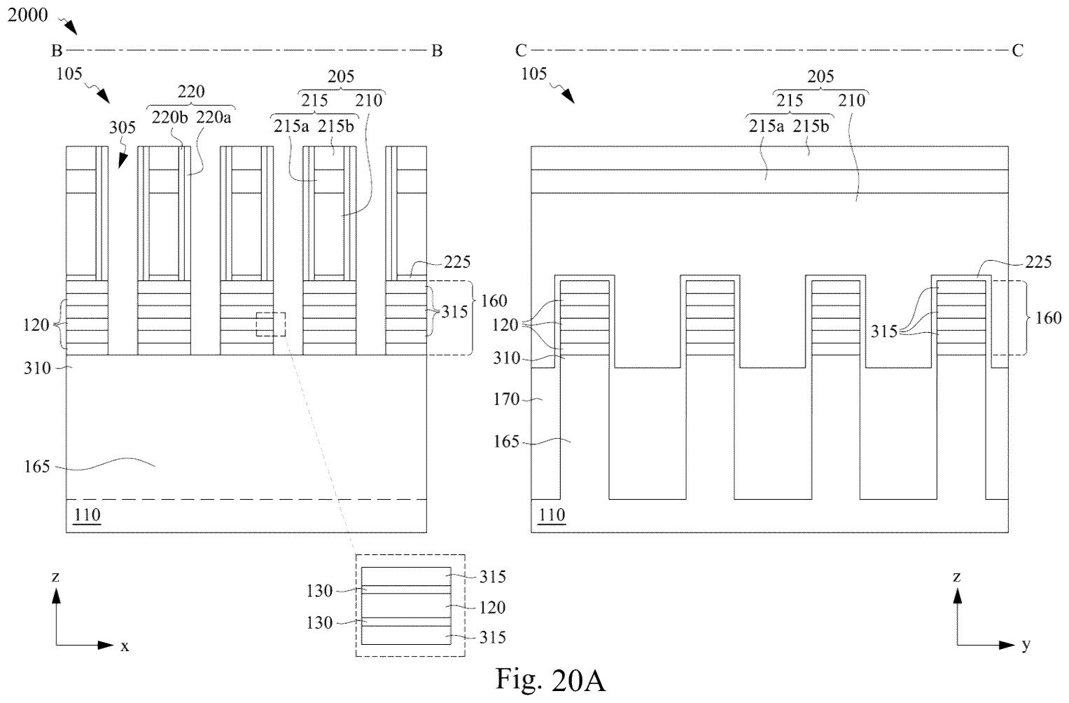

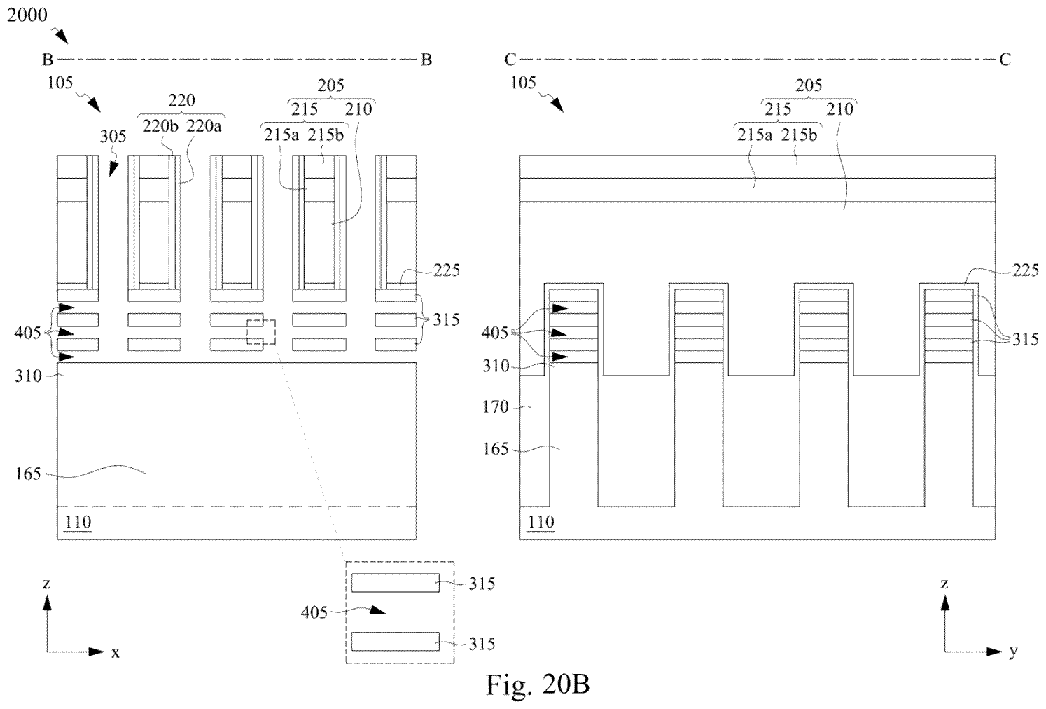

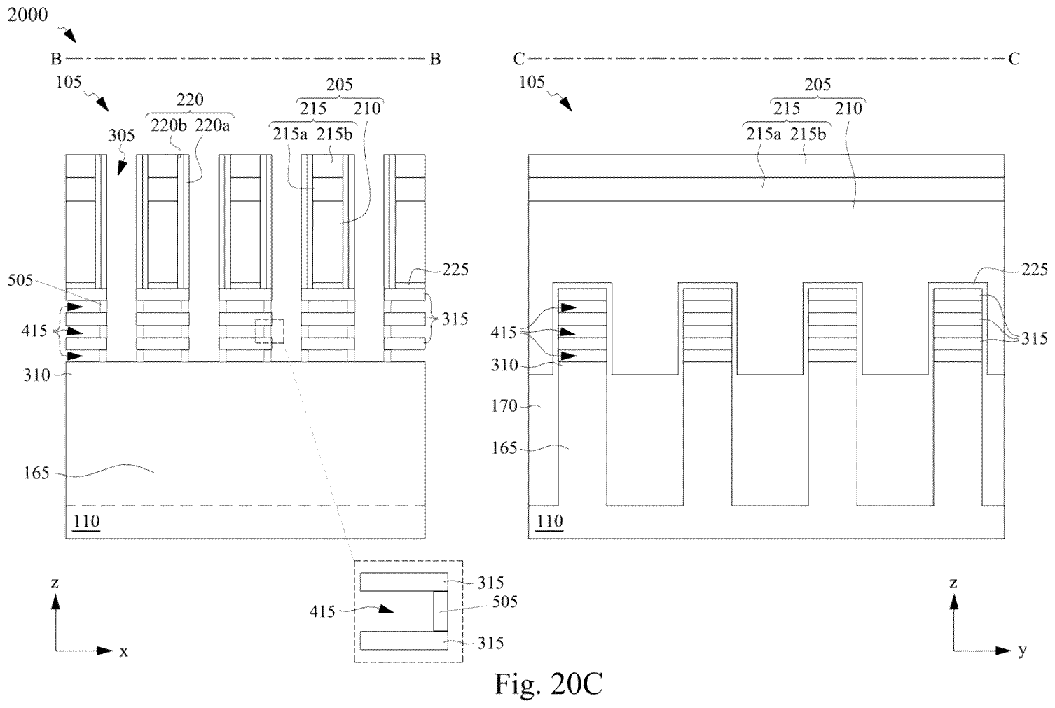

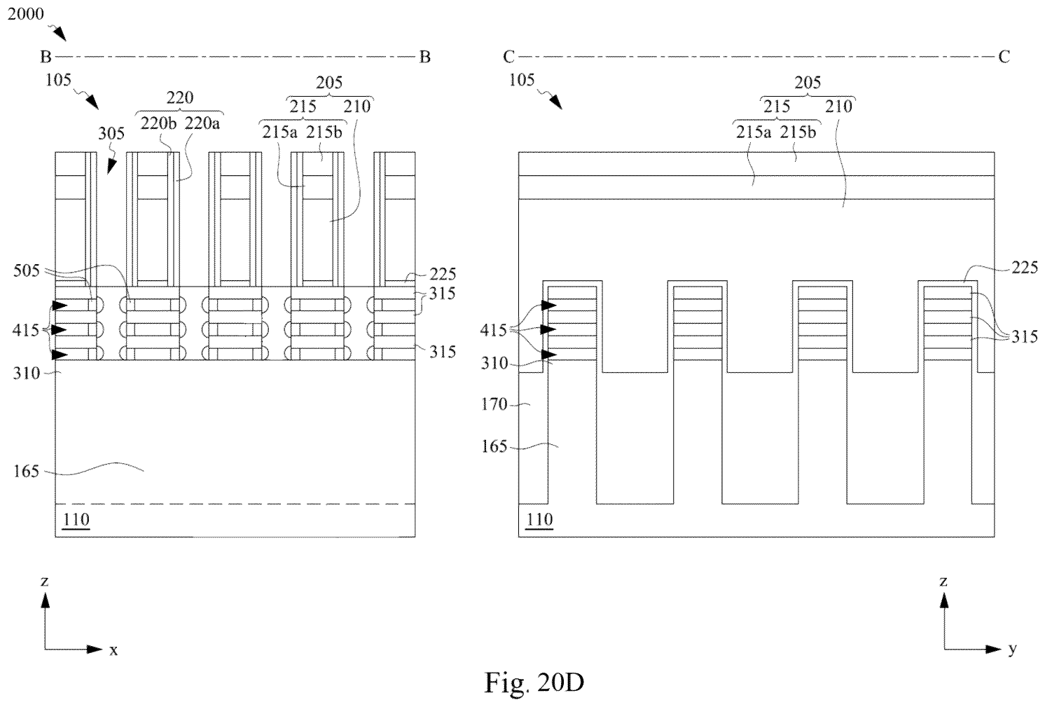

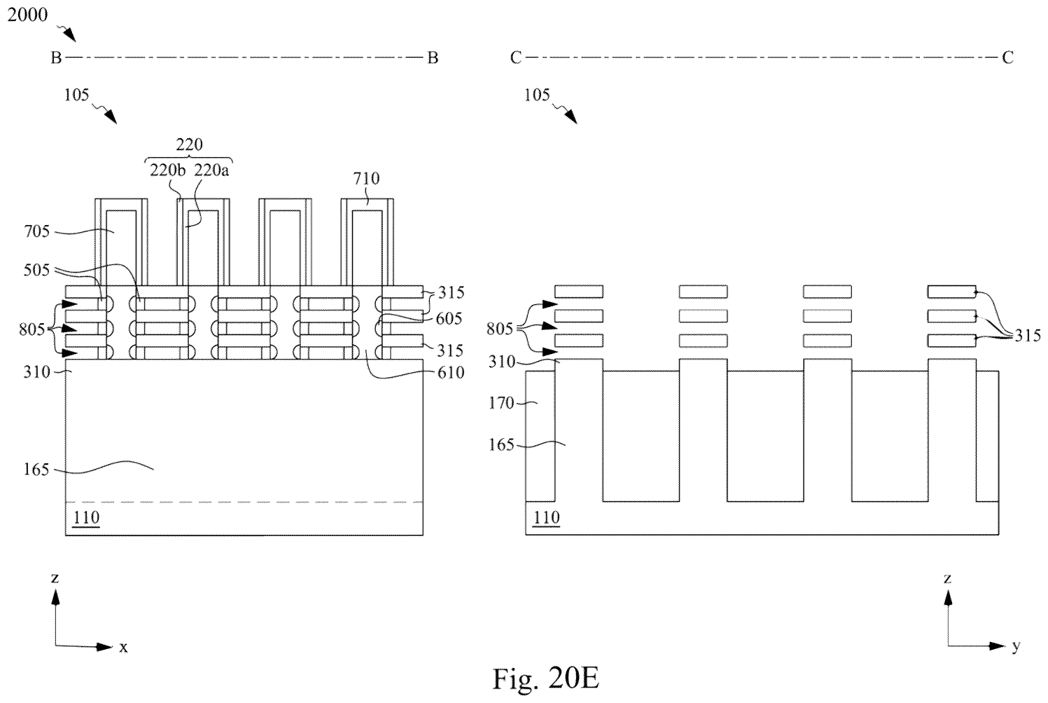

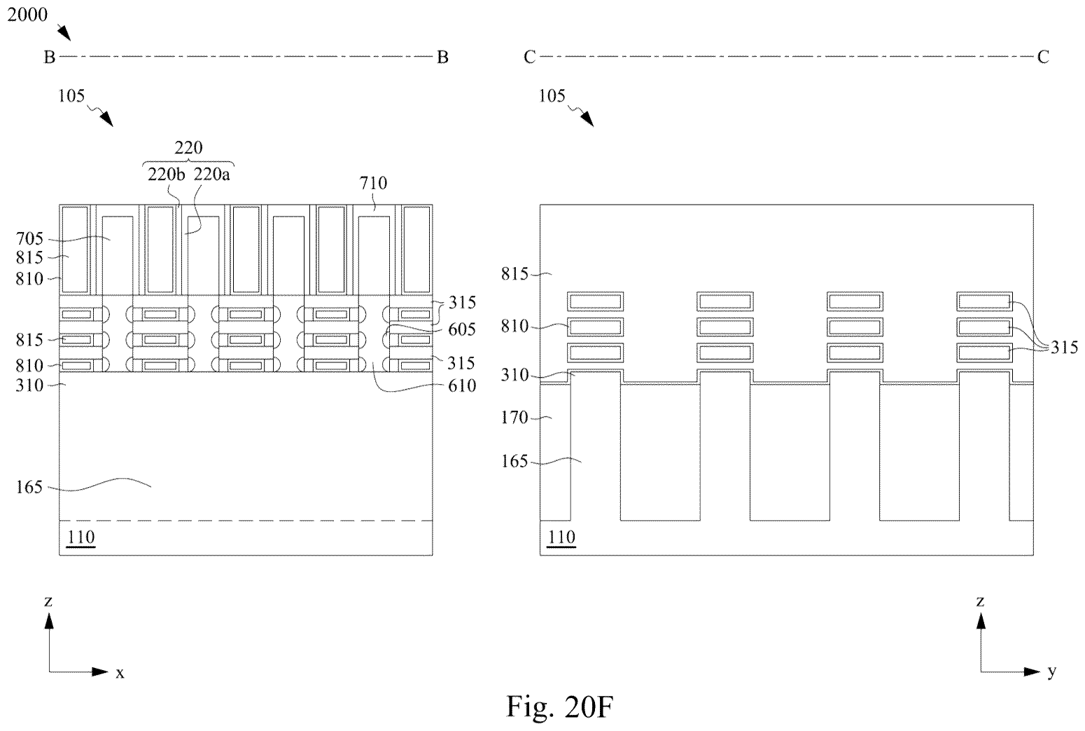

FIGS. 20A-20F are diagrams of an example implementation 2000 of forming the semiconductor device 105 described herein. The example implementation 2000 is similar to the example 900 illustrated in FIGS. 10A-10D, except that the sacrificial dielectric layers 415 are implemented as air spacers. Thus, the dielectric constant of the sacrificial dielectric layers 415 may have a dielectric constant of approximately 1.0.

As indicated above, FIGS. 20A-20F are provided as an example. Other examples may differ from what is described with regard to FIGS. 20A-20F.

In this way, sacrificial semiconductor layers are removed from a layer stack of a semiconductor device prior to formation of inner spacers and source/drain regions of a nanostructure transistor of the semiconductor device. The sacrificial semiconductor layers may be removed along with intermixing layers that may have formed due to intermixing between the materials of the sacrificial semiconductor layers and semiconductor channel layers, and the sacrificial semiconductor layers and intermixing layers may be replaced with sacrificial dielectric layers. The sacrificial dielectric layers may then be etched to form cavities in which the inner spacers are formed. The sacrificial dielectric layers provide greater etch selectivity between the sacrificial dielectric layers and the semiconductor channel layers, compared to the selectivity between the sacrificial semiconductor layers and the semiconductor channel layers, which enables increased control over etching of the cavities to be achieved. Additionally and/or alternatively, the dielectric material of the sacrificial dielectric layers may have lower elasticity than the material of the sacrificial semiconductor layers.

As described in greater detail above, some implementations described herein provide a method. The method includes forming a plurality of semiconductor channel layers and a plurality of sacrificial semiconductor layers such that the plurality of semiconductor channel layers and the plurality of sacrificial semiconductor layers are arranged in an alternating manner in a direction that is approximately perpendicular to a semiconductor substrate of a semiconductor device. The method includes performing a first etch operation to etch the plurality of semiconductor channel layers and the plurality of sacrificial semiconductor layers to form a source/drain recess, where the source/drain recess defines a plurality of nanostructure channels that are arranged in the direction that is approximately perpendicular to the semiconductor substrate, where the plurality of nanostructure channels and the plurality of sacrificial semiconductor layers are arranged in an alternating manner in the direction that is approximately perpendicular to the semiconductor substrate. The method includes performing a second etch operation to remove the plurality of sacrificial semiconductor layers from the semiconductor device. The method includes forming a plurality of sacrificial dielectric layers in spaces between the plurality of nanostructure channels previously occupied by the plurality of sacrificial semiconductor layers. The method includes forming a source/drain region in the source/drain recess.

As described in greater detail above, some implementations described herein provide a semiconductor device. The semiconductor device includes a plurality of nanostructure channels arranged in a direction that is approximately perpendicular to a semiconductor substrate of the semiconductor device. The semiconductor device includes a gate structure wrapping around the plurality of nanostructure channels. The semiconductor device includes a source/drain region adjacent to a side of the gate structure and adjacent to ends of the plurality of nanostructure channels. The semiconductor device includes a plurality of inner spacers between the source/drain region and the gate structure. The semiconductor device includes a plurality of non-contiguous epitaxial regions between the source/drain region and at least one of the plurality of nanostructure channels or the plurality of inner spacers.

As described in greater detail above, some implementations described herein provide a method. The method includes forming a plurality of semiconductor channel layers and a plurality of sacrificial semiconductor layers such that the plurality of semiconductor channel layers and the plurality of sacrificial semiconductor layers are arranged in an alternating manner in a direction that is approximately perpendicular to a semiconductor substrate of a semiconductor device. The method includes forming a source/drain recess through the plurality of semiconductor channel layers and the plurality of sacrificial semiconductor layers. The method includes removing, through the source/drain recess, the plurality of sacrificial semiconductor layers from the semiconductor device. The method includes forming a plurality of sacrificial dielectric layers in spaces between the plurality of semiconductor channel layers previously occupied by the plurality of sacrificial semiconductor layers. The method includes forming inner spacers on ends of the plurality of sacrificial dielectric layers exposed through the source/drain recess. The method includes forming a plurality of non-contiguous epitaxial regions on sidewalls of the source/drain recess. The method includes forming a source/drain region on the plurality of non-contiguous epitaxial regions in the source/drain recess.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of semiconductor channel layers and a plurality of sacrificial semiconductor layers such that the plurality of semiconductor channel layers and the plurality of sacrificial semiconductor layers are arranged in an alternating manner in a direction that is approximately perpendicular to a semiconductor substrate of a semiconductor device;
performing a first etch operation to etch the plurality of semiconductor channel layers and the plurality of sacrificial semiconductor layers to form a source/drain recess,
wherein the source/drain recess defines a plurality of nanostructure channels that are arranged in the direction that is approximately perpendicular to the semiconductor substrate,
wherein the plurality of nanostructure channels and the plurality of sacrificial semiconductor layers are arranged in an alternating manner in the direction that is approximately perpendicular to the semiconductor substrate; and
performing a second etch operation to remove the plurality of sacrificial semiconductor layers from the semiconductor device;
forming a plurality of sacrificial dielectric layers in spaces between the plurality of nanostructure channels previously occupied by the plurality of sacrificial semiconductor layers; and
forming a source/drain region in the source/drain recess.

2. The method of claim 1, wherein performing the second etch operation to remove the plurality of sacrificial semiconductor layers comprises:
performing a second etch operation to remove the plurality of sacrificial semiconductor layers through the source/drain recess.

3. The method of claim 1, wherein forming the plurality of sacrificial dielectric layers comprises:
forming a dielectric layer on sidewalls of the source/drain recess and in the spaces between the plurality of nanostructure channels previously occupied by the plurality of sacrificial semiconductor layers; and
performing a third etch operation to trim the dielectric layer such that portions of the dielectric layer remain in the spaces between the plurality of nanostructure channels previously occupied by the plurality of sacrificial semiconductor layers as the plurality of sacrificial dielectric layers.

4. The method of claim 1, wherein a Young's modulus of a dielectric material of the plurality of sacrificial dielectric layers is less than a Young's modulus of a semiconductor material of the plurality of sacrificial semiconductor layers.

5. The method of claim 1, wherein a Young's modulus of a dielectric material of the plurality of sacrificial dielectric layers is less than a Young's modulus of a semiconductor material of the plurality of nanostructure channels.

6. The method of claim 1, wherein the plurality of sacrificial dielectric layers comprise a porous silicon oxide (SiOₓ) material.

7. The method of claim 1, wherein forming the plurality of sacrificial dielectric layers comprises:
depositing a liner of the plurality of sacrificial dielectric layers by atomic layer deposition (ALD); and
depositing a porous silicon oxide core of the plurality of sacrificial dielectric layers as a flowable film.

8. A semiconductor device, comprising:
a plurality of nanostructure channels arranged in a direction that is approximately perpendicular to a semiconductor substrate of the semiconductor device;
a gate structure wrapping around the plurality of nanostructure channels;
a source/drain region adjacent to a side of the gate structure and adjacent to ends of the plurality of nanostructure channels;
a plurality of inner spacers between the source/drain region and the gate structure; and
a plurality of non-contiguous epitaxial regions between the source/drain region and at least one of:
the plurality of nanostructure channels, or
the plurality of inner spacers.

9. The semiconductor device of claim 8, wherein an epitaxial region of the plurality of non-contiguous epitaxial regions continuously spans across:
an inner spacer of the plurality of inner spacers,
a portion of an end of a first nanostructure channel, of the plurality of nanostructure channels, vertically adjacent to the inner spacer, and
a portion of an end of a second nanostructure channel, of the plurality of nanostructure channels, vertically adjacent to the inner spacer.

10. The semiconductor device of claim 8, wherein an epitaxial region of the plurality of non-contiguous epitaxial regions continuously spans across:
an end of a nanostructure channel of the plurality of nanostructure channels,
a portion of a first inner spacer vertically adjacent to the nanostructure channel, and
a portion of a second inner spacer vertically adjacent to the nanostructure channel.

11. The semiconductor device of claim 8, wherein an epitaxial region of the plurality of non-contiguous epitaxial regions continuously spans across:
a portion of a single inner spacer of the plurality of inner spacers, and
a portion of an end of a single nanostructure channel, of the plurality of nanostructure channels, vertically adjacent to the inner spacer.

12. The semiconductor device of claim 8, wherein another epitaxial region of the plurality of non-contiguous epitaxial regions continuously spans across:
a portion of another single inner spacer, of the plurality of inner spacers, vertically adjacent to the nanostructure channel, and
another portion of the end of the nanostructure channel.

13. The semiconductor device of claim 8, wherein a bottom surface of the source/drain region and bottom surfaces of a subset of the inner spacers located at a bottom of the source/drain region are approximately co-planar.

14. A method, comprising:
forming a plurality of semiconductor channel layers and a plurality of sacrificial semiconductor layers such that the plurality of semiconductor channel layers and the plurality of sacrificial semiconductor layers are arranged in an alternating manner in a direction that is approximately perpendicular to a semiconductor substrate of a semiconductor device;
forming a source/drain recess through the plurality of semiconductor channel layers and the plurality of sacrificial semiconductor layers;
removing, through the source/drain recess, the plurality of sacrificial semiconductor layers from the semiconductor device;
forming a plurality of sacrificial dielectric layers in spaces between the plurality of semiconductor channel layers previously occupied by the plurality of sacrificial semiconductor layers;
forming inner spacers on ends of the plurality of sacrificial dielectric layers exposed through the source/drain recess;
forming a plurality of non-contiguous epitaxial regions on sidewalls of the source/drain recess; and
forming a source/drain region on the plurality of non-contiguous epitaxial regions in the source/drain recess.

15. The method of claim 14, wherein forming the plurality of non-contiguous epitaxial regions comprises:
forming the plurality of non-contiguous epitaxial regions on the inner spacers.

16. The method of claim 14, wherein forming the plurality of non-contiguous epitaxial regions comprises:
forming the plurality of non-contiguous epitaxial regions on ends of the plurality of semiconductor channel layers exposed in the source/drain recess.

17. The method of claim 14, further comprising:
forming a bottom isolation spacer (1105) at a bottom of the source/drain recess,
wherein forming the source/drain region comprises:
forming the source/drain region on the bottom isolation spacer in the source/drain recess.

18. The method of claim 17, wherein a top surface of the bottom isolation spacer is higher in the semiconductor device than bottom-most inner spacers of the inner spacers in the source/drain recess.

19. The method of claim 14, wherein the source/drain region is included in a p-type transistor structure of the semiconductor device; and
wherein the plurality of non-contiguous epitaxial regions comprise a semiconductor material doped with a p-type dopant.

20. The method of claim 14, wherein the source/drain region is included in an n-type transistor structure of the semiconductor device; and
wherein the plurality of non-contiguous epitaxial regions comprise a semiconductor material doped with carbon (C).
